(19) United States
(12) Patent Application Publication
(10) Pub. No.: US 2016/0293858 A1
(43) Pub. Date: Oct. 6, 2016

(54) OPTOELECTRIC DEVICES FABRICATED WITH DEFECT TOLERANT SEMICONDUCTORS

(71) Applicants: Massachusetts Institute of Technology, Cambridge, MA (US); National Renewable Energy Laboratory, Golden, CO (US)

(72) Inventors: Riley Eric Brandt, Cambridge, MA (US); Rachel Chava Kurchin, Cambridge, MA (US); Anthony Buonassisi, Cambridge, MA (US); Vladan Stevanovic, Golden, CO (US); David Ginley, Evergreen, CO (US)

(73) Assignees: Massachusetts Institute of Technology, Cambridge, MA (US); National Renewable Energy Laboratory, Golden, CO (US)

(21) Appl. No.: 15/089,443

(22) Filed: Apr. 1, 2016

Related U.S. Application Data
(60) Provisional application No. 62/141,662, filed on Apr. 1, 2015.

(51) Int. Cl. H01L 51/00; H01L 31/032; H01L 51/42

(52) U.S. Cl. CPC H01L 51/0077; H01L 51/4213; H01L 31/032; H01L 51/0047; H01L 2031/0344

(57) ABSTRACT

Using fundamental electronic structure properties as an indicative of defect tolerance, a broad class of semiconductors containing partially oxidized cations can be identified, as well as several specific instances that can share these properties. These defect tolerant semiconductors can make a high-performance optoelectric device, for example, photovoltaic cells.

### CLAIM OF PRIORITY

This application claims the benefit of prior U.S. Provisional Application No. 62/141,662 filed on Apr. 1, 2015, which is incorporated by reference in its entirety.

### STATEMENT REGARDING FEDERALLY SPONSORED RESEARCH OR DEVELOPMENT

This invention was made with Government support under Contract No. DE-AC36-08GO28308 awarded by the Department of Energy. The Government has certain rights to the invention.

### TECHNICAL FIELD

This invention relates to optoelectronic materials.

### BACKGROUND

Many semiconductors have been studied over the last century for their possible use in photovoltaics (PVs), light-emitting diodes (LEDs), computing devices, sensors, and detectors. Of these, only a select few have achieved sufficient optoelectronic performance to transition into industrial manufacturing, and their identification and development has been slow and mostly empirical. Recently, high-throughput computation and a deeper understanding of the physics-based requirements for high performance have created the potential for an accelerated identification of functional materials with manufacturing potential. For example, materials screening criteria have been proposed to better focus the search for novel candidate PV materials; they include the optical bandgap energy and abruptness of absorption onset, in addition to boundary conditions of elemental abundance and manufacturing cost. See, W. Shockley, H. J. Queisser, Detailed Balance Limit of Efficiency of p-n Junction Solar Cells, J. Appl. Phys. 32 (1961) 510-519, M. B. Prince, Silicon Solar Energy Converters, J. Appl. Phys. 26 (1955) 534-540, L. Yu, A. Zunger, Identification of Potential Photovoltaic Absorbers Based on First-Principles Spectroscopic Screening of Materials, Phys. Rev. Lett. 108 (2012) 068701, L. Yu, R. S. Kokenyesi, D. A. Keszler, A. Zunger, Inverse Design of High Absorption Thin-Film Photovoltaic Materials, Adv. Energy Mater. 3 (2013) 43-48, C. Wadia, A. P. Alivisatos, D. M. Kammen, Materials Availability Expands the Opportunity for Large-Scale Photovoltaics Deployment, Environ. Sci. Technol. 43 (2009) 2072-2077, D. M. Powell, M. T. Winkler, H. J. Choi, C. B. Simmons, D. B. Needleman, T. Buonassisi, Crystalline silicon photovoltaics: a cost analysis framework for determining technology pathways to reach baseload electricity costs, Energy Environ. Sci. 5 (2012) 5874-5883, and T. Surek, Crystal growth and materials research in photovoltaics: progress and challenges, J. Cryst. Growth. 275 (2005) 292-304, each of which is incorporated by reference in its entirety.

However, many materials have met these criteria and yet have not achieved industrially relevant conversion efficiencies (in excess of 10-15%) due to low minority carrier lifetimes or diffusion lengths, e.g., in the case of Cu₂ZnSn(S,Se)₄, SnS, and others. See, I. L. Repins, H. Moutinho, S. G. Choi, A. Kanevce, D. Kuciauskas, P. Dippo, et al., Indications of short minority-carrier lifetime in kesterite solar cells, J. Appl. Phys. 114 (2013) 084507, N. M. Mangan, R. E. Brandt, V. Steinmann, R. Jaramillo, J. V. Li, J. R. Poindexter, et al., A path to 10% efficiency for tin sulfide devices, in: Photovolt. Spec. Conf. PVSC 2014 IEEE 40th, 2014: pp. 2373-2378, and T. Unold, H. W. Schock, Nonconventional (Non-Silicon-Based) Photovoltaic Materials, Annu. Rev. Mater. Res. 41 (2011) 297-321, each of which is incorporated by reference in its entirety.

Photovoltaic (PV) devices have emerged based on methyl-ammonium lead iodide (MAPbI₃) and closely related halides (herein referred to as MAPbX₃). MAPbI₃ is a semiconductor which has demonstrated exceptional minority carrier lifetimes of 280 ns (in the mixed iodide-chloride composition) and diffusion lengths up to 175 microns, comparable to the best single-crystal semiconductors. See, S. D. Stranks, G. E. Eperon, G. Grancini, C. Menelaou, M. J. P. Alcocer, T. Leijtens, et al., Electron-Hole Diffusion Lengths Exceeding 1 Micrometer in an Organometal Trihalide Perovskite Absorber, Science. 342 (2013) 341-344, and Q. Dong, Y. Fang, Y. Shao, P. Mulligan, J. Qiu, L. Cao, et al., Electron-hole diffusion lengths >175 m in solution grown CH3NH3PbI3 single crystals, Science. 347 (2015) 967-970, each of which is incorporated by reference in its entirety. This, in addition to meeting the criteria above, has resulted in a dramatic realization of photovoltaic conversion efficiencies up to 20.1% in 2015, from around <4% in 2009. See, N. J. Jeon, J. H. Noh, W. S. Yang, Y. C. Kim, S. Ryu, J. Seo, et al., Compositional engineering of perovskite materials for high-performance solar cells, Nature. 517 (2015) 476-480, National Renewable Energy Laboratory, Best Research-Cell Efficiencies, Best Res. Cell Effic. (n.d.), and A. Kojima, K. Teshima, Y. Shirai, T. Miyasaka, Organometal Halide Perovskites as Visible-Light Sensitizers for Photovoltaic Cells, J. Am. Chem. Soc. 131 (2009) 6050-6051, each of which is incorporated by reference in its entirety.

### SUMMARY

A device can include an absorber layer comprising a composition including a partially oxidized cation containing a lone 6s² or 5s² pair of electrons and a halide anion or chalcogenide anion or combination thereof. In certain embodiments, device can further include an electron transport layer. In certain embodiments, the electron transport layer can include phenyl-C61-butyric acid methyl ester (PCBM). In certain embodiments, the device can further include a substrate layer. In certain embodiments, the substrate layer can include at least one of glass, quartz, gold, or molybdenum oxide.

A composition for an absorber in a device can include a partially oxidized cation containing a lone 6s² or 5s² pair of electrons; and a halide anion or chalcogenide anion or combination thereof.

A method of identifying a material for an optoelectric device can include selecting a partially oxidized cation containing a lone 6s2 or 5s2 pair of electrons; and combining the cation with a halide salt to form an absorber material.

In certain embodiments, the partially oxidized cation can be at least one of In⁺, Sn²⁺, Sb³⁺, Pb²⁺, Tl⁺ or Bi³⁺.

In certain embodiments, the halide anion or chalcogenide anion can be at least one of I⁻, Br⁻, Se²⁻, or S²⁻.

In certain embodiments, the composition can be a ternary bismuth halide.

In certain embodiments, the composition can further include an additional cation comprising at least one of ammonium, methylammonium, formamidimium, or phosphonium.

In certain embodiments, the ternary bismuth halide can be methylammonium bismuth iodide.

In certain embodiments, the composition can be a bismuth halide.

In certain embodiments, the bismuth halide can be bismuth triiodide.

In certain embodiments, the device can further include an alloy including an alkali metal halide.

In certain embodiments, the composition can be a binary halide.

In certain embodiments, the binary halide can be BiI₃, SbI₃, SnI₂, or InI.

In certain embodiments, the composition can be a binary chalcogenide.

In certain embodiments, the binary chalcogenide is Bi₂S₃, Sb₂S₃, or Sb₂Se₃.

In certain embodiments, the composition can be a bismuth chalcohalide.

In certain embodiments, the bismuth chalcohalide can be BiOI, BiSI, BiSeI, BiSBr, or BiSeBr.

In certain embodiments, the composition can be an antimony chalcohalide.

In certain embodiments, the antimony chalcohalide can be SbSI or SbSeI.

In certain embodiments, the composition can be a ternary alkali bismuth chalcogenide.

In certain embodiments, the ternary alkali bismuth chalcogenide can be LiBiS₂, NaBiS₂, KBiS₂, CsBiS₂, or NaBiSe₂.

In certain embodiments, the composition can be a ternary alkali antimony chalcogenides.

In certain embodiments, the composition can be a ternary indium halide or a ternary tin halide.

In certain embodiments, the composition can be In₃SnI₅, InAlI₄, CdInBr₃, or CaInBr₃.

In certain embodiments, the composition can be a ternary alkali bismuth halide.

In certain embodiments, the ternary alkali bismuth halide can be Cs₃Bi₂I₉, Rb₃Bi₂I₉, or K₃Bi₂I₉.

In certain embodiments, the composition can be a ternary alkali antimony halide.

In certain embodiments, the ternary alkali antimony halide can be Cs₃Sb₂I₉.

In certain embodiments, the composition can be a hybrid inorganic-organic bismuth halide, a hybrid inorganic-organic antimony halide, or a hybrid inorganic-organic indium halide.

In certain embodiments, the composition can further include ammonium, methylammonium, formamidimium, or phosphonium.

In certain embodiments, the composition can include an octahedral halide.

In certain embodiments, the composition can further include an alloy including an alkali metal halide.

In certain embodiments, the alkali metal halide can be NaI, KI, or CsI.

Other aspects, embodiments, and features will be apparent from the following description, the drawings, and the claims.

### BRIEF DESCRIPTION OF THE DRAWINGS

FIG. 1A shows crystal structure of cubic (high T) phase MAPbI₃, including the MA cation at the cage center. FIG. 1B shows bonding/antibonding orbitals in MAPbI₃ demonstrating the formation of energy bands relative to isolated p and s atomic orbital energies. FIG. 1C shows density of states (DOS) of MAPbI₃ separated into cation and anion s and p orbital contributions.

FIG. 2 shows screening criteria for high-performance PV materials.

FIG. 3 shows ternary plots demonstrating the partial density of states of the valence band maximum by orbital type, for a wide range of randomly selected materials.

FIGS. 4A-4C show density of states plotted for three materials identified here, including InI (FIG. 4A), SbSI (FIG. 4B), and BiSI (FIG. 4C).

FIGS. 5A-5F show structure of methylammonium bismuth iodide (MBI). FIG. 5A shows comparison of the diffraction pattern of MBI thin film and powder with the calculated diffraction pattern from a C 2/c space group. FIG. 5B shows MBI with a unit cell indicated by the dashed lines. FIG. 5C shows (010) view of the MBI lattice with a unit cell indicated by the dashed lines. FIG. 5D shows cross-sectional TEM image of solution-assisted conversion MBI. Morphology of solution-assisted conversion MBI thin film measured by AFM (FIG. 5E) and SEM (FIG. 5F).

FIGS. 6A-6D show air-stability of MBI, measured from mid-July to mid-August in Cambridge, Mass., USA. FIG. 6A shows photographs of MBI and MAPbI₃ on quartz over time in ambient air. FIGS. 6B and 6C show normalized XRD patterns of MBI over time with air exposure. FIG. 6D shows the relative change in the normalized intensity of the diffraction peaks of MBI (Day 25 vs. Day 1). The change in phase of MAPbI₃ is given in FIG. 21A.

FIG. 7A shows photoluminescence (PL) and absorption coefficient of solution-assisted conversion MBI before and after pyridine treatment. FIG. 7B shows a Tauc plot for the indirect bandgap and FIG. 7C shows a Tauc plot for direct higher energy transition in MBI.

FIG. 8 shows partial density of states (DOS) of MBI calculated through DFT.

FIG. 9 shows normalized photoluminescence (PL) decay of MBI. τₑ is the characteristic PL decay time and τₘₒₙₒ the decay time constant of the monoexponential tail of vapor-assisted conversion MBI.

FIGS. 10A-10C show crystal structure and electronic structure of BiI₃ (R3̅). FIG. 19A shows four unit cells showing the octahedrally coordinated Bi atoms. FIG. 10B shows a single layer plane showing ⅓ vacant cation sites. FIG. 10C shows dispersion relation showing energy vs. momentum throughout the Brillouin zone. FIG. 10D partial density of states by atomic orbital.

FIG. 11A shows XRD spectra as a function of substrate temperature (including gold substrate), and for solution processed films on glass, showing preferred orientations. FIG. 11B is a representative micrograph of a film deposited on a glass substrate near 170° C. FIG. 11C is a representative micrograph of a film deposited on a glass substrate near 110° C. FIG. 11D shows micrograph of solution processed film showing smaller grains. Scale bars represent 5 μm for all micrographs.

FIG. 12A shows Tauc plot of absorption coefficient calculated from PVT and solution processed BiI₃, where (ahv)^{1/2} is linearly extrapolated to the band edge assuming an indirect gap. FIG. 12B shows normalized photoluminescence spectra for both types of thin films and the single crystal.

FIGS. 13A-13B show TCSPC decay curves for IRF, thin film PVT (T_{growth}=110±10° C.), solution processed, and single crystal BiI₃. Fitted raw data is shown in FIG. 12A. In FIG. 12B, the data has been fit by convolution with the instrument response function, Thin-film samples are fit with monoexponential decays, while the single crystal data is fit with a biexponential model; time constants shown inset.

FIG. 14 shows illustration of the synthesis of MBI by solution-assisted conversion.

FIG. 15 shows fluence-dependence of MBI PL decay.

FIGS. 16A-16B show analysis of Rutherford Backscattering Spectroscopy (RBS) measurements of thin film MBI. FIG. 16A shows RBS measurements of MBI thin films. FIG. 16B shows X-ray fluorescence (XRF) measurements of the same sample comparing spectra from within the spot characterized by RBS and outside the measurement spot. Inset is a photograph of the RBS sample, clearly showing the measurement spot.

FIGS. 17A-17B shows finding the space group of methylammonium bismuth iodide (MBI). Fit of the powder diffraction pattern of MBI with P6₃/mmc space group (FIG. 17A) and C 2/c space group (FIG. 17B).

FIG. 18 shows grazing incidence XRD pattern of solution-assisted conversion MBI fitted by the Le Bail method. The FWHM of the fitted peaks was 0.284°. The positions of some of the diffraction peaks of Bi₂O₃ and BiOI are shown.

FIGS. 19A-19B show AFM measurements of solution-assisted conversion MBI thin films. FIG. 19A shows MBI synthesized using 10 mg·mL⁻¹ MAI in isopropanol with an rms roughness of 65 nm. The in-plane resistivity is 0.3 MΩ·cm. FIG. 19B shows MBI synthesized using 40 mg·mL⁻¹ MAI in isopropanol with an rms roughness of 44 nm and in-plane resistivity of 0.5 MΩ·cm.

FIG. 20 shows a photograph of solution-assisted conversion MBI taken on the same day as its deposition.

FIGS. 21A-21C show the air-stability of solution synthesized thin films. FIG. 21A shows X-ray diffraction patterns of MAPbI₃ after 1, 13 and 25 days of air exposure with (61±4)% relative humidity and (21.8±0.7° C. temperature. The asterisks indicate PbI₂ peaks. Fitting the diffraction pattern of solution-assisted conversion MBI exposed to air for 25 days with MBI and Bi₂O₃ (FIG. 21B) and MBI and BiOI (FIG. 21C).

FIGS. 22A-22B show air-stability of solution-assisted conversion MBI and MAPbI₃. Photoluminescence measurements of MBI (FIG. 22A) and MAPbI₃ (FIG. 22B) over time with ambient air exposure.

FIGS. 23A-23F show the phase stability of MBI. FIG. 23A shows net mass change of MBI and MAPbI₃ powder with temperature measured by thermographic analysis (TGA). Fitted XPS measurements of the O 1s is peak of solution-assisted conversion MBI stored in nitrogen (FIG. 23B), stored in nitrogen and ion etched in the instrument (FIG. 23C), and stored in air (FIG. 23D). MAPbI₃ stored in nitrogen (FIG. 23E) and stored in air (FIG. 23F).

FIGS. 24A-24B show X-ray photoelectron spectroscopy (XPS) measurements. The spectra for solution-assisted conversion MBI (FIG. 24A) and MAPbI₃ are given (FIG. 24B).

FIGS. 25A-25C show X-ray photoelectron spectroscopy measurements of solution-assisted conversion MBI exposed to ambient air for a month. Spectra showing Bi 4f (FIG. 25A), I 3d (FIG. 25B) and O 1s is peaks (FIG. 25C).

FIG. 26 shows normalized PL decays of MBI with different lengths of air exposure to investigate the influence of air exposure on PL decay time.

FIGS. 27A-27F show convolution between the instrument response function (IRF) of the TCSPC system at 600 nm and monoexponential decay functions with time constants of (a) 0.1 ns (FIG. 27A), 0.2 ns (FIG. 27B), 0.3 ns (FIG. 27C), 0.4 ns (FIG. 27D), 0.75 ns (FIG. 27E) and 6 ns (FIG. 27F).

FIG. 28 shows grazing incidence XRD pattern of vapor-assisted conversion MBI fitted by the Le Bail method.

FIG. 29 shows lowest energy orientation of methylammonium cations in MBI.

FIG. 30 shows normalized TCSPC traces for thin-film BiI₃ deposited by physical vapor transport, plotted alongside the instrument response function.

FIG. 31 shows normalized TCSPC traces for single crysal BiI₃ samples, plotted alongside the instrument response function.

FIG. 32A shows a schematic of a device including an absorber layer. FIG. 32B shows a schematic of a device including an absorber layer and an electron transport layer. FIG. 32C shows a schematic of a device including an absorber layer and a substrate layer.

### DETAILED DESCRIPTION

The emergence of methyl-ammonium lead halide (MAPbX₃) perovskites motivates the identification of unique properties giving rise to exceptional bulk transport properties, and identifying future materials with similar properties. One of the most compelling questions engendered by MAPbX₃ as an optoelectronic material is the degree to which it is unique, and whether its success can lead to the identification of materials with improved stability and lower toxicity, yet similar high performance. Clearly, as in previous design criteria the high optical absorption coefficient is important, but also essential are the long carrier diffusion lengths observed in MAPbX₃, enabled by high minority-carrier lifetime (τ) and mobility (μ). See, S. D. Stranks, G. E. Eperon, G. Grancini, C. Menelaou, M. J. P. Alcocer, T. Leijtens, et al., Electron-Hole Diffusion Lengths Exceeding 1 Micrometer in an Organometal Trihalide Perovskite Absorber, Science. 342 (2013) 341-344, M. A. Green, A. Ho-Baillie, H. J. Snaith, The emergence of perovskite solar cells, Nat. Photonics. 8 (2014) 506-514, and C. C. Stoumpos, C. D. Malliakas, M. G. Kanatzidis, Semiconducting Tin and Lead Iodide Perovskites with Organic Cations: Phase Transitions, High Mobilities, and Near-Infrared Photoluminescent Properties, Inorg. Chem. 52 (2013) 9019-9038, each of which is incorporated by reference in its entirety. The importance of τ and μ for device performance has been established for the most highly performing PV materials, including silicon, cadmium telluride, copper indium gallium diselenide, and gallium arsenide. See, J. Mattheis, J. Werner, U. Rau, Finite mobility effects on the radiative efficiency limit of pn-junction solar cells, Phys. Rev. B. 77 (2008) 085203, J. R. Davis, Jr., A. Rohatgi, R. H. Hopkins, P. D. Blais, P. Rai-Choudhury, J. R. McCormick, et al., Impurities in silicon solar cells, IEEE Trans. Electron Devices. 27 (1980) 677-687, H. R. Moutinho, R. G. Dhere, M. M. Al-Jassim, C. Ballif, D. H. Levi, A. B. Swartzlander, et al., Study of CdTe/CdS solar cells using CSS CdTe deposited at low temperature, in: Photovolt. Spec. Conf. PVSC 2000 IEEE 28th, 2000: pp. 646-649, L. Kranz, C. Gretener, J. Perrenoud, D. Jaeger, S. S. A. Gerstl, R. Schmitt, et al., Tailoring Impurity Distribution in Polycrystalline CdTe Solar Cells for Enhanced Minority Carrier Lifetime, Adv. Energy Mater. 4 (2014) 1301400, I. L. Repins, W. K. Metzger, C. L. Perkins, J. V. Li, M. A. Contreras, Measured minority-carrier lifetime and CIGS device performance, in: Photovolt. Spec. Conf. PVSC 2009 IEEE 34th, 2009: pp. 000978-000983, and O. D. Miller, E. Yablonovitch, S. R. Kurtz, Strong Internal and External Luminescence as Solar Cells Approach the Shockley #x2013; Queisser Limit, IEEE J. Photovolt. 2 (2012) 303-311, each of which is incorporated by reference in its entirety.

Oddly, these more direct transport parameters, τ and μ, are not traditionally considered essential screening criteria for novel candidate PV materials. This may be partially a consequence of the difficulty in measuring and/or calculating these parameters. The direct measurement of minority carrier τ and μ requires ultrafast electronic or optical sensors to capture transients (see, E. A. Schiff, Hole mobilities and the physics of amorphous silicon solar cells, J. Non-Cryst. Solids. 352 (2006) 1087-1092, W. K. Metzger, D. Albin, D. Levi, P. Sheldon, X. Li, B. M. Keyes, et al., Time-resolved photoluminescence studies of CdTe solar cells, J. Appl. Phys. 94 (2003) 3549-3555, D. Walter, F. Rosenits, F. Kopp, S. Reber, B. Berger, W. Warta, Determining the Minority Carrier Lifetime in Epitaxial Silicon Layers by Micro-Wave-Detected Photoconductivity Measurements, in: 25th Eur. Photovolt. Sol. Energy Conf., Valencia, Spain, 2010: pp. 2078-2083, and T. Tiedje, C. R. Wronski, B. Abeles, J. M. Cebulka, Electron transport in hydrogenated amorphous silicon: drift mobility and junction capacitance, Sol. Cells. 2 (1980) 301-318, each of which is incorporated by reference in its entirety), or strong steady-state signals (see, R. A. Sinton, A. Cuevas, M. Stuckings, Quasi-steady-state photoconductance, a new method for solar cell material and device characterization, in: 25th Photovolt. Spec. Conf., IEEE, Washington, D. C., 1996: pp. 457-460, and J. K. Katahara, H. W. Hillhouse, Quasi-Fermi level splitting and sub-bandgap absorptivity from semiconductor photoluminescence, J. Appl. Phys. 116 (2014) 173504, each of which is incorporated by reference in its entirety), and must be performed with PV-device-relevant illumination conditions, electrical fields, and transport directions. Calculating τ and μ from first principles is even more challenging, given the lack of well-established and high-throughput methods to directly calculate electron-phonon interactions and/or trap capture cross sections. While it is possible to obtain some information about carrier mobility from effective masses, and maximum radiative lifetime from the band structure, these are known to be insufficient and can be misleading when point and structural defects limit these transport properties. See, J. Mattheis, J. Werner, U. Rau, Finite mobility effects on the radiative efficiency limit of pn-junction solar cells, Phys. Rev. B. 77 (2008) 085203, which is incorporated by reference in its entirety.

Recombination models disclosed herein can identify the underlying electronic structure parameters of MAPbX₃ that are likely to underpin the high experimentally observed τ and μ, including: dielectric constant, effective mass, band bonding character, and band dispersion (i.e., band extrema relative to vacancy levels). How these parameters can be computationally accessible can be illustrated using established variants of density functional theory (DFT). By using the basic properties of MAPbX₃ to define a set of search criteria, other novel materials can be identified with “defect-tolerant” transport properties, starting with the database at MaterialsProject.org. See, A. Jain, S. P. Ong, G. Hautier, W. Chen, W. D. Richards, S. Dacek, et al., Commentary: The Materials Project: A materials genome approach to accelerating materials innovation, APL Mater. 1 (2013) 011002, which is incorporated by reference in its entirety. This may yield materials with similar performance, but enhanced stability and lower toxicity.

The “defect tolerance” can emerge from fundamental electronic structure properties, including the orbital character of the conduction and valence band extrema, the effective masses, and the static dielectric constant. MaterialsProject.org searches and detailed electronic-structure calculations can be used to demonstrate these properties in other materials than MAPbX₃. This framework of materials discovery can be applied more broadly, to accelerate discovery of new semiconductors based on emerging understanding of recent successes.

Many semiconductors have been studied over the last century for their possible use in photovoltaics (PVs), light-emitting diodes (LEDs), and radiation- or photo-detectors, referred herein as optoelectronic devices. These semiconductors have historically been identified and developed empirically, and only a select few have achieved sufficient optoelectronic performance to transition into industrial manufacturing. This is because, in many optoelectronic devices, performance is governed by minority carrier transport properties (i.e., the mobility and lifetime of minority carriers). These minority carrier transport properties are limited by the presence of crystalline defects—point and structural defects. Thus, the semiconductors used in these optoelectronic devices must be highly processed to remove defects, which slows their development and increases costs.

Disclosed herein are potential high-performance optoelectronic materials and methods to identify, fabricate, and utilize those materials. The present disclosure pertains to several classes of optoelectronic materials that are “defect tolerant;” minority carrier transport is less hindered by defects in these materials. Thus, the materials have a significantly higher probability of making high-performance optoelectronic devices, and can be processed more cheaply.

One class of defect tolerant semiconductors recently identified in prior art is methyl-ammonium lead iodide (MAPbI₃), which has recently been developed into high-performing solar cells with conversion efficiencies >20% as well as LEDs and photodetectors.

The method disclosed herein utilizes the fundamental electronic structure properties that give this material its tolerance to defects, and in turn, its high performance. The fundamental electric structure properties include a partially oxidized cation containing a lone 6s² or 5s² pair of electrons. These cations can be combined with and a halide anion or chalcogenide anion. The method is based on using these fundamental electronic structure properties to perform high-throughput computational screening of materials, in turn identifying other promising defect tolerant semiconductors.

Using this method, multiple classes of semiconductors were identified, which are defect tolerant, and which would have applications in high-performance optoelectronic devices. These are semiconductors formed from at least one of the following cations in their partial oxidation states (In⁺, Sn²⁺, Sb³⁺, Pb²⁺, Tl⁺, Bi³⁺), as well as at least one of the following anions (I⁻, Br⁻, Se²⁻, S²⁻). In particular, these semiconductors can be used in photovoltaic cells.

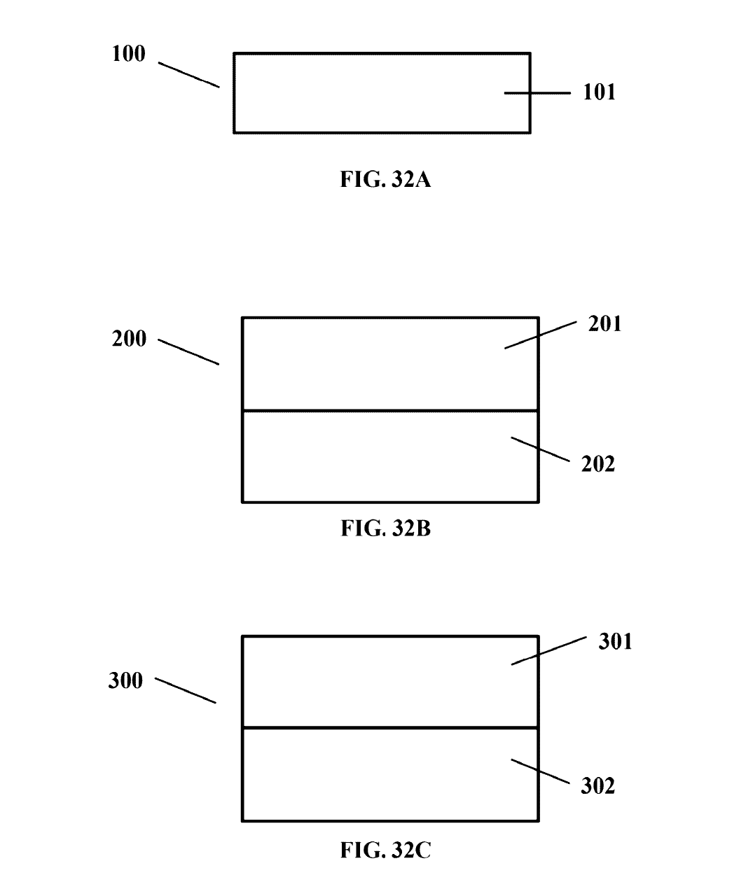

A can include an absorber layer 101 (FIG. 32A). In certain embodiments, a device 200 can an absorber layer 201 and an electron transport layer 202 (FIG. 32B). In certain embodiments, the electron transport layer can include phenyl-C61-butyric acid methyl ester (PCBM). In certain embodiments, a device 300 can include an absorber layer 301 and a substrate layer 302 (FIG. 32C). In certain embodiments, the substrate layer can include at least one of glass, quartz, gold, or molybdenum oxide. A photovoltaic device can include a first electrode, a second electrode, a substrate, an electron transporting layer, and an absorber layer. In certain embodiments, a photovoltaic device is a photovoltaic cell. Photovoltaic cells can include a photoactive material, which absorbs and converts light to electrical energy.

In certain embodiments, an absorber layer can include a composition including a partially oxidized cation containing a lone 6s² or 5s² pair of electrons; and a halide anion or chalcogenide anion.

A composition for an absorber in an optoelectronic device can include a material comprising at least one of In⁺, Sn²⁺, Sb³⁺, Pb²⁺, Tl⁺ or Bi³⁺, and at least one of I⁻, Br⁻, Se²⁻ or S²⁻.

The composition including any of the materials listed below can be used in optoelectronic devices such as photovoltaic cells as defect tolerant semiconductors.

Binary chalcogenides (Bi₂S₃, Sb₂S₃, Sb₂Se₃, SnS, SnSe, SnTe, In₂S, In₂Se, In₂Te, Tl₂S)

Binary halides (BiI₃, SbI₃, SnI₂, InI, BiBr₃, BiCl₃, SbBr₃, SbCl₃, SnBr₂, SnCl₂, InBr, InCl, TlI, TlBr, TlCl)

Bismuth/antimony chalcohalides (BiOI, BiSI, BiSeI, SbSI, SbSeI, BiSBr, BiSeBr, related materials)

Ternary alkali bismuth/antimony chalcogenides (LiBiS₂, NaBiS₂, KBiS₂, CsBiS₂, NaBiSe₂, related materials)

Ternary chalcohalides (BiOCl, BiSCl, BiSeCl, SbOCl, SbSCl, SbSeCl, SbSBr, SbSeBr)

Ternary indium or tin halides (In₃SnI₅, InAlI₄, CdInBr₃, CaInBr₃, KSnSb, related materials)

Ternary alkali chalcogenides (LiBiSe₂, NaSbS₂, NaSbSe₂, KSbS₂)

Ternary alkali bismuth/antimony halides (Cs₃Bi₂I₉, Rb₃Bi₂I₉, K₃Bi₂I₉, Cs₃Sb₂I₉, related halides)

Hybrid inorganic-organic bismuth, antimony, or indium halides (e.g., (MA)₃Bi₂I₉, (FA)₃Bi₂I₉)

These materials can be formed by combining an organic or molecular cation (such as ammonium, methylammonium, formamidimium, phosphonium, etc.) with anions formed from bismuth/antimony halide octahedra, such as Bi₂I₉³⁻.

Furthermore, this list of materials can include alloys formed from the compounds listed above, as well as alloys with alkali metal halides (e.g., NaI, KI, CsI), for example (In,K)I.

In a preferred embodiment, a composition for an absorber in an optoelectronic device can include a bismuth halide, an indium halide, a ternary bismuth halide, or an alkali bismuth sulfide. In certain preferred embodiment, the bismuth halide can be BiI₃. In certain preferred embodiment, the indium halide can be InI. In certain preferred embodiment, the ternary bismuth halide can be Cs₃Bi₂I₉, Rb₃Bi₂I₉, K₃Bi₂I₉, (MA)₃Bi₂I₉, or (FA)₃Bi₂I₉. In certain preferred embodiment, the alkali bismuth sulfide can be LiBiS₂, NaBiS₂, KBiS₂, or CsBiS₂.

These materials can be used to fabricate polycrystalline, thin-film optoelectronic devices, which can be patterned. The absorber materials listed above can be deposited by several synthesis routes. The first method is solution-phase deposition, wherein a solvent is used to dissolve the elemental or compound precursors. The solvent can be deposited on a substrate by spin-coating, or by spreading via tape casting or a doctor blade. The solvent is then evaporated through a mild anneal to form a polycrystalline thin film. A second synthesis method is via sublimation. In this case, the source elements or compounds can be heated in a low-pressure ambient to evaporate or sublimate, and then re-condense on a substrate. This can occur in a horizontal tube furnace, a vertical thermal evaporator, or a close-space sublimation furnace. A third synthesis route is via chemical vapor deposition, whereby the precursor elements are supplied in the vapor phase bound in a metallorganic or similar precursor molecule. These precursors then react on the substrate to sequentially deposit the compound of interest.

These materials have several commercial applications, the most immediate of which is in thin-film photovoltaic modules. Photovoltaics remain too expensive due to high capital costs and materials costs in manufacturing. Being able to process semiconductors at lower temperatures and faster would lead to lower variable costs per photovoltaic cell, as well as higher throughput to reduce the average fixed cost.

### I. Redefining Search Criteria for Defect-Tolerant Semiconductors

This section discusses the emerging explanations for high performance in MAPbI₃ and closely related materials, focusing on the unique aspects that make their performance exceptional: specifically their long non-radiative minority carrier lifetime, even in the presence of defects. A “defect tolerant” material is expected to either (a) form relatively few intrinsic or structural defects under high-throughput, low-temperature processing conditions, and/or more importantly (b) the extrinsic, intrinsic, or structural defects that do form have a very minimal effect on μ and τ. Herein how a material can achieve this defect tolerance is discussed. This method utilizes a discovery that the underlying electronic structure properties may not be unique to MAPbX₃, but rather be shared in a broader class of compounds.

### I.A. Explanations for High Performance in Methylammonium Lead Iodide and Related Materials

Many authors have proposed explanations for the success of MAPbX₃ as a photovoltaic material. These include its large absorption coefficient, long electron and hole diffusion lengths, low exciton binding energies, low effective masses and high mobilities, and the presence of only shallow defects in the bandgap. See, S. D. Stranks, G. E. Eperon, G. Grancini, C. Menelaou, M. J. P. Alcocer, T. Leijtens, et al., Electron-Hole Diffusion Lengths Exceeding 1 Micrometer in an Organometal Trihalide Perovskite Absorber, Science. 342 (2013) 341-344, M. A. Green, A. Ho-Baillie, H. J. Snaith, The emergence of perovskite solar cells, Nat. Photonics. 8 (2014) 506-514, C. C. Stoumpos, C. D. Malliakas, M. G. Kanatzidis, Semiconducting Tin and Lead Iodide Perovskites with Organic Cations: Phase Transitions, High Mobilities, and Near-Infrared Photoluminescent Properties, Inorg. Chem. 52 (2013) 9019-9038, W.-J. Yin, T. Shi, Y. Yan, Unusual defect physics in CH3NH3PbI3 perovskite solar cell absorber, Appl. Phys. Lett. 104 (2014) 063903, and W.-J. Yin, T. Shi, Y. Yan, Unique Properties of Halide Perovskites as Possible Origins of the Superior Solar Cell Performance, Adv. Mater. 26 (2014) 4653-4658, each of which is incorporated by reference in its entirety. The existence of only shallow defects, and the disperse valence band, have both been tied to the presence of filled Pb 6s orbitals, deriving from the partial oxidation of Pb relative to its Pb⁴⁺ oxidation state. This orbital character has been identified by several authors, and explains both the shallow binding energy of defects and the atypical dependence of bandgap on strain or temperature in MAPbI₃. See, Y. Yamada, T. Nakamura, M. Endo, A. Wakamiya, Y. Kanemitsu, Near-band-edge optical responses of solution-processed organic?inorganic hybrid perovskite CH3NH3PbI3 on mesoporous TiO2 electrodes, Appl. Phys. Express. 7 (2014) 032302, A. Walsh, Principles of Chemical Bonding and Band Gap Engineering in Hybrid Organic-Inorganic Halide Perovskites, J. Phys. Chem. C. 119 (2015) 5755-5760, and M. H. Du, Efficient carrier transport in halide perovskites: theoretical perspectives, J. Mater. Chem. A. 2 (2014) 9091-9098, each of which is incorporated by reference in its entirety. This model for explaining the defect-tolerance and shallow defects has direct analogy to those developed earlier for CuInSe₂ and Cu₃N, where instead the Cu⁺ cation contributes Cu 3d states to the valence band. See, A. Walsh, Principles of Chemical Bonding and Band Gap Engineering in Hybrid Organic-Inorganic Halide Perovskites, J. Phys. Chem. C. 119 (2015) 5755-5760, and M. H. Du, Efficient carrier transport in halide perovskites: theoretical perspectives, J. Mater. Chem. A. 2 (2014) 9091-9098, each of which is incorporated by reference in its entirety.

In addition, device-level observations support the claims that MAPbI₃ has excellent transport properties, including long carrier diffusion lengths significantly exceeding 1 micron, and recently, up to 175 microns in single crystals. See, S. D. Stranks, G. E. Eperon, G. Grancini, C. Menelaou, M. J. P. Alcocer, T. Leijtens, et al., Electron-Hole Diffusion Lengths Exceeding 1 Micrometer in an Organometal Trihalide Perovskite Absorber, Science. 342 (2013) 341-344, Q. Dong, Y. Fang, Y. Shao, P. Mulligan, J. Qiu, L. Cao, et al., Electron-hole diffusion lengths >175 m in solution grown CH3NH3PbI3 single crystals, Science. 347 (2015) 967-970, and D. Shi, V. Adinolfi, R. Comin, M. Yuan, E. Alarousu, A. Buin, et al., Low trap-state density and long carrier diffusion in organolead trihalide perovskite single crystals, Science. 347 (2015) 519-522, each of which is incorporated by reference in its entirety. Low non-radiative minority carrier recombination rates are also supported by measurements of high photoluminescence quantum yield (PLQY), long carrier lifetimes, and the high open-circuit voltage (V_{OC}) demonstrated by many devices. See, K. Tvingstedt, O. Malinkiewicz, A. Baumann, C. Deibel, H. J. Snaith, V. Dyakonov, et al., Radiative efficiency of lead iodide based perovskite solar cells, Sci. Rep. 4 (2014), and C. Wehrenfennig, G. E. Eperon, M. B. Johnston, H. J. Snaith, L. M. Herz, High Charge Carrier Mobilities and Lifetimes in Organolead Trihalide Perovskites, Adv. Mater. 26 (2014) 1584-1589, each of which is incorporated by reference in its entirety. These properties are made more exceptional by the way in which MAPbI₃ is processed: low temperature solution processing results in equal or better performance to vacuum synthesis, which runs contrary to the higher purity, higher temperature, and more equipment-intensive fabrication strategies used to obtain high performance in conventional crystalline semiconductor materials.

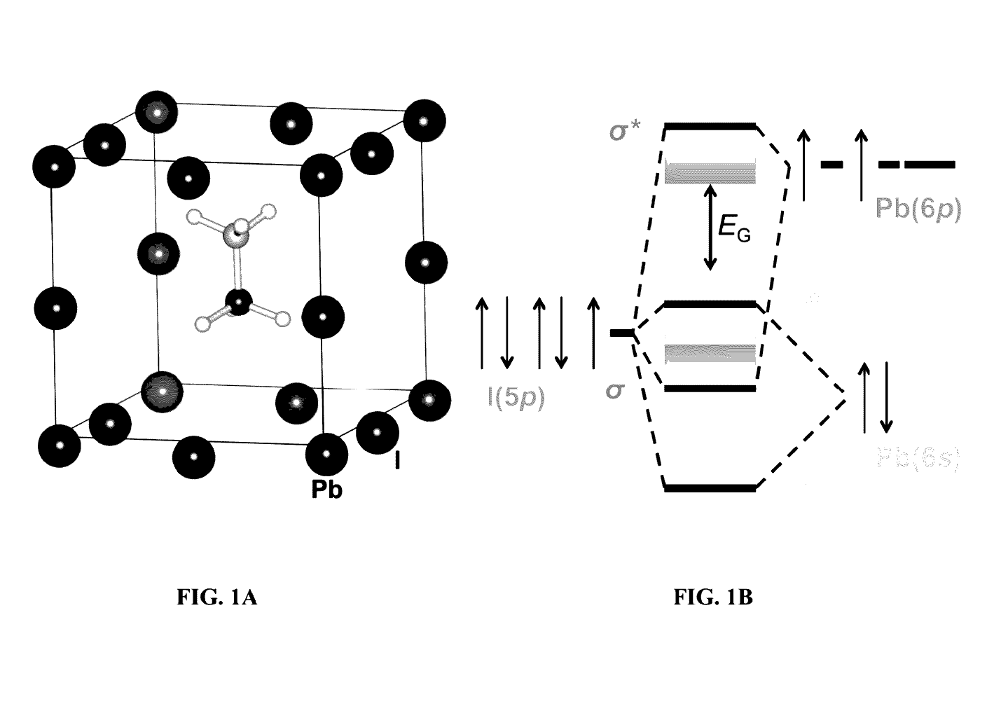

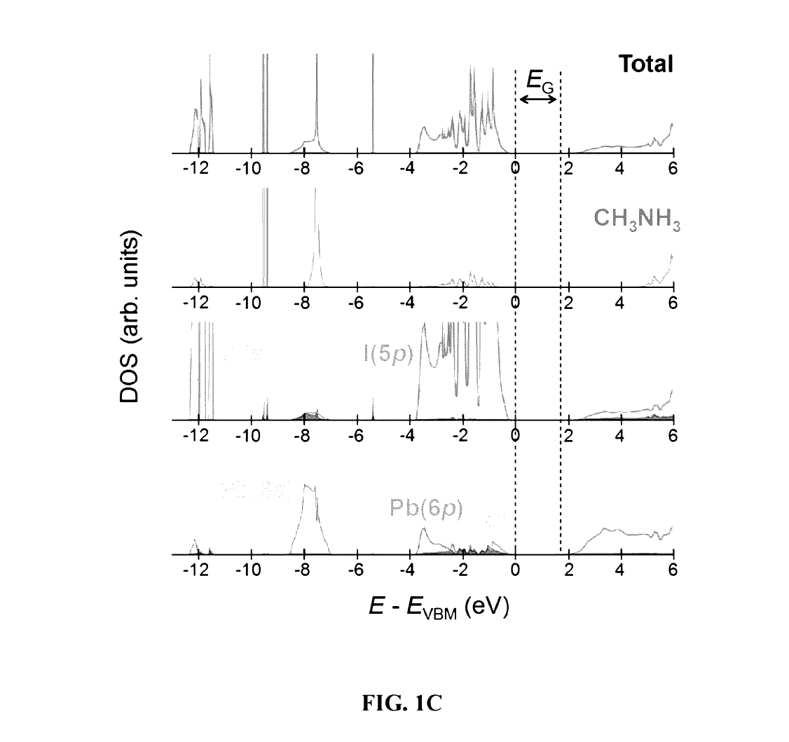

Here density functional theory (DFT) was applied to MAPbI₃. In the model pioneered by Zhang, Lany, Zakutayev et at (see, S. B. Zhang, S.-H. Wei, A. Zunger, H. Katayama-Yoshida, Defect physics of the CuInSe 2 chalcopyrite semiconductor, Phys. Rev. B. 57 (1998) 9642, and A. Zakutayev, C. M. Caskey, A. N. Fioretti, D. S. Ginley, J. Vidal, V. Stevanović, et al., Defect Tolerant Semiconductors for Solar Energy Conversion, J. Phys. Chem. Lett. 5 (2014) 1117-1125, each of which is incorporated by reference in its entirety), defect tolerance emerges from having bonding orbitals at the conduction band minimum (CBM), and antibonding orbitals at the valence band maximum (VBM). This band structure is markedly different than that in most semiconductors, where the valence band is composed predominantly of bonding states, while the conduction band is composed of wave functions with dominant antibonding character. The defect tolerance that emerges from such an electronic structure is easily described using atomic vacancies as examples. Namely, if predominantly antibonding orbitals occur at the VBM and bonding at the CBM, the dangling (broken) bonds that are formed upon creating the vacancy (of any kind) will likely appear as resonances inside the bands, leaving the bandgap free of deep states that can act as carrier traps. As shown in FIG. 1 for the valence band of MAPbI₃, this is a consequence of the position of valence atomic orbitals relative to the bonding and antibonding bands formed due to interactions. Analogous arguments are also valid for other types of intrinsic defects, such as interstitials and/or antisites, as well as for structural defects such as grain boundaries, which consist of many dangling bonds. Extrinsic impurities can, however, still introduce deep traps inside the bandgap depending on the position of their atomic orbitals relative to the energy bands of the host material. In FIGS. 1A-1B, the DOS is computed using density functional theory including the effects of spin-orbit interactions, with the band-gap adjusted to the value reported in E. M. Miller, Y. Zhao, C. C. Mercado, S. K. Saha, J. M. Luther, K. Zhu, et al., Substrate-controlled band positions in CH₃NH₃PbI₃ perovskite films, Phys Chem Chem Phys. 16 (2014) 22122-22130, which is incorporated by reference in its entirety. (1.85 eV computed using the many body GW method with spin-orbit included). The MA+ cation does not introduce states at the band edge.

These situations, in particular the antibonding character of the VBM, can frequently be found in metal-nonmetal systems with partially oxidized cations such as binary group-III halides or group-IV chalcogenides in 1:1 stoichiometry (e.g. TlBr, SnTe). Due to the partial oxidation of Pb, the MAPbI₃ compound also exhibits similar electronic structure features. See, T. Umebayashi, K. Asai, T. Kondo, A. Nakao, Electronic structures of lead iodide based low-dimensional crystals, Phys. Rev. B. 67 (2003) 155405, which is incorporated by reference in its entirety. As shown in FIGS. 1A-1B there are three types of interactions that contribute to the valence band in MAPbI₃. The first results from the overlap of Pb(6p)-I(5p) atomic orbitals leading to the creation of the deeper portion of the valence band, which is predominantly of I(5p) character, and the bottom part of the conduction band, which is composed mostly of Pb(6p) atomic orbitals. This interaction is responsible for chemical bonding as it implies charge transfer from the Pb(6p) to the I(5p) orbitals. In addition, Pb(6s)-I(5p) interaction leads to the creation of two bands: a deeper valence band (bonding), and the antibonding maximum of the valence band. Finally, only one of the I(5p) orbitals is oriented along the Pb—I bond, which is a favorable direction to interact with Pb(6s) and Pb(6p). The other two, oriented orthogonally, can only interact with the 5p orbitals from other iodine atoms forming the middle of the valence band as shown in FIGS. 1A-1B.

As a result of these interactions, the electronic bandgap is formed between the antibonding top of the valence band originating from the Pb(6s)-I(5p) interactions and the antibonding conduction band minimum resulting from the Pb(6p)-I(5p) interactions. Bonding-type defect-tolerance arguments can therefore only be applied to the defects that would tend to create valence band-derived states such as cation (Pb or MA) vacancies. On the other hand, if anion (iodine) vacancies form, the resulting dangling bonds will appear as resonances inside the conduction band only if the bandwidth and the dispersion of the conduction band are such that the CBM falls well below the energy of the Pb(6p) atomic orbitals. In the case of Pb, contrary to Sn and Ge compounds for example, this condition is more likely due to relativistic spin-orbit interaction effects that increase the width of the Pb(6p) conduction band by ˜2 eV based on the calculations. See, P. Umari, E. Mosconi, F. De Angelis, Relativistic Solar Cells, Sci. Rep. 4 (2014) 4467, which is incorporated by reference in its entirety. Thus, the fact that vacancy-type defects in MAPbI₃ are resonant in the bands is attributed to: (a) the presence of antibonding orbitals within the valence band that push the VBM energy up, and (b) relativistic effects which push the CBM energy down.

In summary, an emerging conclusion from both experimental measurements and first principles calculations is that MAPbX₃ benefits from an inherently defect-tolerant electronic structure.

### I.B. Modeling Electronic Transport in the Presence of Defects

To provide physical context for the claims above, and to translate them into electronic structure design criteria, transport models in defective materials is used: in particular, models for defect-assisted μ and τ. These are semiconductor models (distinct from the Langevin recombination model, which is inappropriate for MAPbI₃). See, C. Wehrenfennig, G. E. Eperon, M. B. Johnston, H. J. Snaith, L. M. Herz, High Charge Carrier Mobilities and Lifetimes in Organolead Trihalide Perovskites, Adv. Mater. 26 (2014) 1584-1589, which is incorporated by reference in its entirety.

Defect-limited, monomolecular, or trap-assisted non-radiative recombination, U_{SRH}, is modeled by Shockley-Read-Hall (SRH) recombination statistics:

$${U}_{SRH} = \frac{np - {n}_{i}^{2}}{{τ}_{0 , h} ( n + {n}_{1} ) + {τ}_{0 , e} ( p + {p}_{1} )} , \qquad Eq . 1$$

where n, p, and nᵢ are the electron, hole, and intrinsic carrier concentrations, respectively. See, S. M. Sze, K. N. Kwok, Physics of Semiconductor Devices, 3rd ed., John Wiley & Sons, Hoboken, N.J., 2007, which is incorporated by reference in its entirety. The low-injection electron and hole lifetimes τ_{0,e} and τ_{0,h}, which is to be maximized, are:

$${τ}_{0 , h} = \frac{1}{{N}_{t} {σ}_{t , h} {v}_{th , h}} and {τ}_{0 , e} = \frac{1}{{N}_{t} {σ}_{t , e} {v}_{th , e}} , \qquad Eq . 2$$

where Nₜ is the trap density, σₜ is the capture cross section for electrons or holes, and νₜₕ is the drift velocity of carriers. At low injection conditions, the hole and electron lifetimes tend toward τₕ=τ_{0,h} and τₑ=τ_{0,e}, respectively; at high injection conditions, both hole and electron lifetimes tend toward τₕ=τₑ=τ_{0,h}+τ_{0,e}. The terms n₁ and p₁ reflect the occupancy of trap states, where Eₜ is the energy level of the trap state and Eᵢ the Fermi level in the intrinsic material (near mid-gap):

$${n}_{1} = {n}_{i} exp ( \frac{{E}_{t} - {E}_{i}}{kT} ) and {p}_{1} = {n}_{i} exp ( \frac{{E}_{t} - {E}_{i}}{kT} ) . \qquad Eq . 3$$

From this model, three conditions are necessary to limit SRH (trap-assisted) recombination: defect energy levels far from mid-gap, as these exponentially impact lifetime; low trap density Nₜ; and low capture cross-sections σ. Operating in high-injection conditions is helpful (where photogenerated carrier concentrations greatly exceed background doping densities), especially when strongly injection-dependent defects limit lifetime. Eₜ and Nₜ may be calculated from first principles, however this calculation is computationally expensive, so more fundamental electronic properties accessible by high-throughput screening were searched.

The First and Most Important Property is the Relative Static Permittivity, or Dielectric Constant Eᵣ.

A higher dielectric constant indicates a greater ability to screen charge, and may arise from electronic or ionic contributions, as well as the methylammonium molecular dipoles in the lattice. See, J. M. Frost, K. T. Butler, F. Brivio, C. H. Hendon, M. van Schilfgaarde, A. Walsh, Atomistic origins of high-performance in hybrid halide perovskite solar cells, Nano Lett. 14 (2014) 2584-2590, which is incorporated by reference in its entirety.

This screening means that the capture cross-section of a charged defect will be influenced by the dielectric constant. Assuming a Coulombic model for capture cross section, a capture event will occur when the electrostatic potential energy from a charged defect exceeds the thermal energy, kT, which occurs at a specific radius (see, R. H. Bube, Photoelectronic Properties of Semiconductors, Cambridge University Press, 1992, which is incorporated by reference in its entirety), therefore:

$${σ}_{t} = \frac{q}{16 {π ( {ɛ}_{r} {ε}_{0} k T )}^{2}} , \qquad Eq . 4$$

where q is the elementary charge, and ∈₀ is the vacuum permittivity. MAPbI₃ has demonstrated a large static dielectric constant of 60-70 or higher, due to electronic, ionic, and molecular dipole contributions from the organic cation. See, M. A. Green, A. Ho-Baillie, H. J. Snaith, The emergence of perovskite solar cells, Nat. Photonics. 8 (2014) 506-514, Q. Lin, A. Armin, R. C. R. Nagiri, P. L. Burn, P. Meredith, Electro-optics of perovskite solar cells, Nat. Photonics. 9 (2015) 106-112, E. J. Juarez-Perez, R. S. Sanchez, L. Badia, G. Garcia-Belmonte, Y. S. Kang, I. Mora-Sero, et al., Photoinduced Giant Dielectric Constant in Lead Halide Perovskite Solar Cells, J. Phys. Chem. Lett. 5 (2014) 2390-2394, and F. Brivio, A. B. Walker, A. Walsh, Structural and electronic properties of hybrid perovskites for high-efficiency thin-film photovoltaics from first-principles, APL Mater. 1 (2013) 042111, each of which is incorporated by reference in its entirety. This charge screening is very beneficial, given the inverse square dependence of carrier capture cross-section, and in turn recombination rate, on the dielectric constant.

In addition, for a simple “hydrogenic” defect under Effective Mass Theory, the energy level of the defect sits deeper in the gap for lower dielectric constants (see S. M. Sze, K. N. Kwok, Physics of Semiconductor Devices, 3rd ed., John Wiley & Sons, Hoboken, N.J., 2007, which is incorporated by reference in its entirety), i.e. the binding energy of a donor relative to the conduction band, E_{C} is:

$${E}_{t} - {E}_{C} = \frac{{m}_{e}^{*}}{{ɛ}_{r}^{2}} \frac{{q}^{4}}{2 {( 4 {πɛ}_{0} ℏ )}^{2}} , \qquad Eq . 5$$

where m^{*}ₑ is the effective mass of an electron, and h is the reduced Planck constant. Similar charge screening behavior has been used to explain the low binding energy of excitons in MAPbI₃ and shallow effective mass-like states. See, J. M. Frost, K. T. Butler, F. Brivio, C. H. Hendon, M. van Schilfgaarde, A. Walsh, Atomistic origins of high-performance in hybrid halide perovskite solar cells, Nano Lett. 14 (2014) 2584-2590, and J. Kim, S.-H. Lee, J. H. Lee, K.-H. Hong, The Role of Intrinsic Defects in Methylammonium Lead Iodide Perovskite, J. Phys. Chem. Lett. 5 (2014) 1312-1317, each of which is incorporated by reference in its entirety.

More important, however, is the energy level of non effective-mass like traps formed by vacancies and structural defects. As discussed above, band structures containing antibonding orbitals in the VBM, bonding in the CBM, and/or high dispersion within a band can lead to shallower defects, as defect energy levels are resonant with the conduction or valence bands. A second model proposed to explain the lack of deep trap states is that MAPbI₃ is more ionic than other semiconductors, resulting in shallower or fewer defect states associated with dangling bonds. Analogous arguments have been made to explain defect tolerance in GaN[51] and (Cd,Zn)Te. See, J. Kim, S.-H. Lee, J. H. Lee, K.-H. Hong, The Role of Intrinsic Defects in Methylammonium Lead Iodide Perovskite, J. Phys. Chem. Lett. 5 (2014) 1312-1317, and M. Carmody, S. Mallick, J. Margetis, R. Kodama, T. Biegala, D. Xu, et al., Single-crystal II-VI on Si single-junction and tandem solar cells, Appl. Phys. Lett. 96 (2010) 153502, each of which is incorporated by reference in its entirety.

The Second Critical Transport Property is the Minority-Carrier Mobility, which is influenced by the effective masses of free carriers and by the frequency of scattering events.

The lower the effective mass, or the more disperse the band edges, the higher the mobility. However, in typical polycrystalline materials at room temperature, the mobility will not reach this intrinsic limit due to several forms of scattering.

One way in which the mobility will be limited is by charged defect scattering, either at ionized impurities or grain boundaries. Again, a high dielectric constant reduces the spatial extent and the potential barrier of a charged defect, lowering its propensity to scatter free carriers. For ionized impurities, the mobility is given by:

$${μ}_{H , ii} = {r}_{H , ii} {\frac{128 \sqrt{2 π} {( {ɛ}_{r} {ɛ}_{0} )}^{2} {( kT )}^{3 \text{/} 2}}{\sqrt{{m}^{*} {N}_{t} {Z}^{2} {e}^{3}}} [ ln ( 1 + b ) - \frac{b}{1 + b} ]}^{- 1} , \qquad Eq . 6$$

where r_{H,ii} is the Hall coefficient for ionized impurity scattering, Z is the charge on the ionized site, Nₜ is the trap density, b=24 m*kT/h²β_{S}², and β_{S} is the inverse screening length. See, Y. S. Lee, M. T. Winkler, S. C. Siah, R. Brandt, T. Buonassisi, Hall mobility of cuprous oxide thin films deposited by reactive direct-current magnetron sputtering, Appl. Phys. Lett. 98 (2011) 192115, which is incorporated by reference in its entirety. Thus, to reduce the impact of ionized impurities on mobility, it is again ideal to have a high dielectric constant, low effective mass, and low trap density. Grain boundary scattering is also reduced for larger dielectric constants, and when the defect levels associated with grain boundaries become shallower. See, J. Y. W. Seto, The electrical properties of polycrystalline silicon films, J. Appl. Phys. 46 (1975) 5247, which is incorporated by reference in its entirety.

Alternatively, the mobility limit may come from phonon scattering. The phonon-limited mobility is generally smaller in softer materials, given their higher concentration of phonons at a given temperature—the bulk modulus, B, and phonon-limited mobility μₚₕ are correlated (see, J. Yan, P. Gorai, B. Ortiz, S. Miller, S. A. Barnett, T. Mason, et al., Material descriptors for predicting thermoelectric performance, Energy Env. Sci. 8 (2014) 983-994, which is incorporated by reference in its entirety), where A₀ is a constant:

μₚₕ=A₀B(m*)^{-2.5}. Eq. 7

MAPbI₃ is a relatively soft material, with a bulk modulus predicted to be 22.2 GPa for the cubic phase. See, J. Feng, Mechanical properties of hybrid organic-inorganic CH3NH3BX3 (B=Sn, Pb; X=Br, I) perovskites for solar cell absorbers, APL Mater. 2 (2014) 081801, which is incorporated by reference in its entirety. This may explain why its mobility, measured around 10 cm²/V/s (see C. Wehrenfennig, G. E. Eperon, M. B. Johnston, H. J. Snaith, L. M. Herz, High Charge Carrier Mobilities and Lifetimes in Organolead Trihalide Perovskites, Adv. Mater. 26 (2014) 1584-1589, which is incorporated by reference in its entirety), is not large relative to III-V and group IV semiconductors. Claims of “high” mobilities may be relative to dyes and organic absorber materials from which much of the perovskite PV work derived. Thus, similar to the absorption coefficient of MAPbI₃, its mobility is necessary but insufficient to explain its high performance.

To compare these proposed performance criteria for PV, the ratio of the diffusion length to the absorption length in an absorber material must be maximized in order to produce high photocurrent in a PV device, as in this non-dimensional figure of merit (see, J. J. Krich, B. I. Halperin, A. Aspuru-Guzik, Nonradiative lifetimes in intermediate band photovoltaics—Absence of lifetime recovery, J. Appl. Phys. 112 (2012) 013707, which is incorporated by reference in its entirety):

$$v = \frac{{k}_{B} T}{q} {μτα}^{2} . \qquad Eq . 8$$

While historical PV screening approaches have focused on maximizing α; here instead τ is maximized. Given that the mobility and absorption coefficient are good, but not exceptional for MAPbI₃, it can be the minority carrier lifetime of MAPbI₃ that is most strongly responsible for its exceptional performance.

Finally, it is worth mentioning that beyond point and structural defects, a disordered crystal structure can limit the conversion efficiency by introducing defect states near the band edges (Urbach tail). MAPbI₃ demonstrates a very small Urbach tail energy. See, S. De Wolf, J. Holovsky, S.-J. Moon, P. Löper, B. Niesen, M. Ledinsky, et al., Organometallic Halide Perovskites: Sharp Optical Absorption Edge and Its Relation to Photovoltaic Performance, J. Phys. Chem. Lett. 5 (2014) 1035-1039, which is incorporated by reference in its entirety. This may be due to its low melting temperature, such that the material develops more crystalline order at lower processing temperatures (high homologous temperatures). See, M. A. Green, A. Ho-Baillie, H. J. Snaith, The emergence of perovskite solar cells, Nat. Photonics. 8 (2014) 506-514, which is incorporated by reference in its entirety.

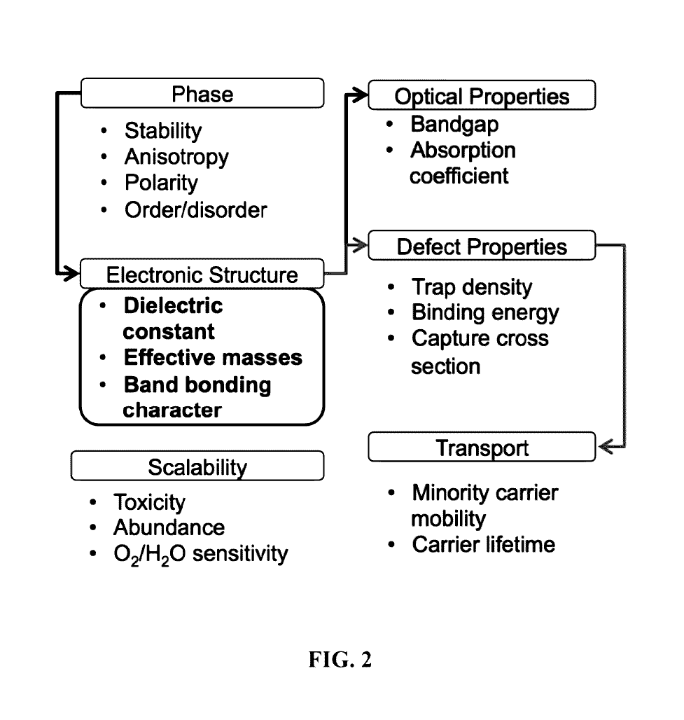

The priorities for high-performance PV absorbers are summarized in in FIG. 2, focusing on the properties that enable excellent bulk transport in the presence of defects. Optical properties and scalability concerns have previously been emphasized in screening. While they are important, they are insufficient to achieve high performance. In contrast, this disclosure focus specifically on electronic structure properties that have a direct impact on transport, highlighted in bold.

### I.C. Toward Ideal Electronic Structure: The Importance of Partially Oxidized, Heavy Post Transition Metals.

Materials that contain a lone 6s² or 5s² pair of electrons (that do not participate in bonding) have the potential to share the high dielectric constant, low effective masses, and VB antibonding character that lead to defect tolerant transport properties. As a broad class, these are compounds formed from partially oxidized post-transition metals including In, Sn, Sb, Tl, Pb, and Bi. In the case of MAPbI₃, the partially oxidized Pb atom in its Pb²⁺ charge state lends these beneficial properties—a large, polarizable cation leads to high Born effective charge and therefore large dielectric constants (see, M. H. Du, Efficient carrier transport in halide perovskites: theoretical perspectives, J. Mater. Chem. A. 2 (2014) 9091-9098, which is incorporated by reference in its entirety), as well as a conduction band with greater bandwidth due to spin-orbit coupling, while filled 6s orbitals lead to a disperse valence band (low effective mass) (see, W.-J. Yin, T. Shi, Y. Yan, Unique Properties of Halide Perovskites as Possible Origins of the Superior Solar Cell Performance, Adv. Mater. 26 (2014) 4653-4658, which is incorporated by reference in its entirety) and antibonding orbital character in the valence band maximum.

Other partially oxidized post-transition metals including In⁺, Sn²⁺, Sb³⁺, Tl⁺, Pb²⁺, and Bi³⁺ share these properties, and are present in a wide variety of materials. This N-2 oxidation state is more commonly observed for compounds of Tl, Pb, and Bi, due to relativistic effects leading to tighter binding of the remaining s electrons; however, lighter cations may also be stabilized in these oxidation states. Given their many beneficial properties, these cations appear increasingly in many optoelectronic applications: PbS and lead halide perovskites in PV; TlBr, PbI₂, and BiI₃ in X-ray detectors and scintillators; Sn²⁺-based TCOs; and Pb and Bi-based ferroelectrics, photoferroelectrics, piezoelectrics, and thermoelectrics. See, P. J. Sellin, Thick film compound semiconductors for X-ray imaging applications, Nucl. Instrum. Methods Phys. Res. Sect. A. 563 (2006) 1-8, G. Hautier, A. Miglio, G. Ceder, G.-M. Rignanese, X. Gonze, Identification and design principles of low hole effective mass p-type transparent conducting oxides, Nat. Commun. 4 (2013) 2292, R. Nechache, C. Harnagea, S. Licoccia, E. Traversa, A. Ruediger, A. Pignolet, et al., Photovoltaic properties of Bi2FeCrO6 epitaxial thin films, Appl. Phys. Lett. 98 (2011) 202902, and J. Rödel, W. Jo, K. T. P. Seifert, E.-M. Anton, T. Granzow, D. Damjanovic, Perspective on the Development of Lead-free Piezoceramics, J. Am. Ceram. Soc. 92 (2009) 1153-1177, each of which is incorporated by reference in its entirety. For the thallous halides, analogous 6s²6p⁰ orbital explanations for low effective mass, antibonding VBM states, and a high dielectric constant were offered several years before similar work on MAPbX₃. See, A.-V. Mudring, Thallium Halides—New Aspects of the Stereochemical Activity of Electron Lone Pairs of Heavier Main-Group Elements, Eur. J. Inorg. Chem. 2007 (2007) 882-890, and M.-H. Du, D. J. Singh, Enhanced Born charge and proximity to ferroelectricity in thallium halides, Phys. Rev. B. 81 (2010) 144114, each of which is incorporated by reference in its entirety.

To identify promising materials in this class, a script is developed to search through all materials in the Materials Project.org (MP) database. See, A. Jain, S. P. Ong, G. Hautier, W. Chen, W. D. Richards, S. Dacek, et al., Commentary: The Materials Project: A materials genome approach to accelerating materials innovation, APL Mater. 1 (2013) 011002, which is incorporated by reference in its entirety. This is implemented using the Materials Project API and the pymatgen library, to access information on calculated crystal and electronic structure for all compounds in the database. See, S. P. Ong, W. D. Richards, A. Jain, G. Hautier, M. Kocher, S. Cholia, et al., Python Materials Genomics (pymatgen): A robust, open-source python library for materials analysis, Comput. Mater. Sci. 68 (2013) 314-319, which is incorporated by reference in its entirety. This search examines approximately 27,000 non-metallic inorganic compounds with full band structures calculated, and extracts information on crystallographic point group, stability, band structure, and in particular the fractional density of states by element and orbital. To screen for the properties described above, the s-orbital fraction in the top 1 eV of the valence band density of states was calculated. This metric is a rough filter, and may mistakenly identify materials with band-inversion, as well as many metal hydrides and Au⁻ compounds, wherein the anion species contributes a filled s orbital at the valence band edge.

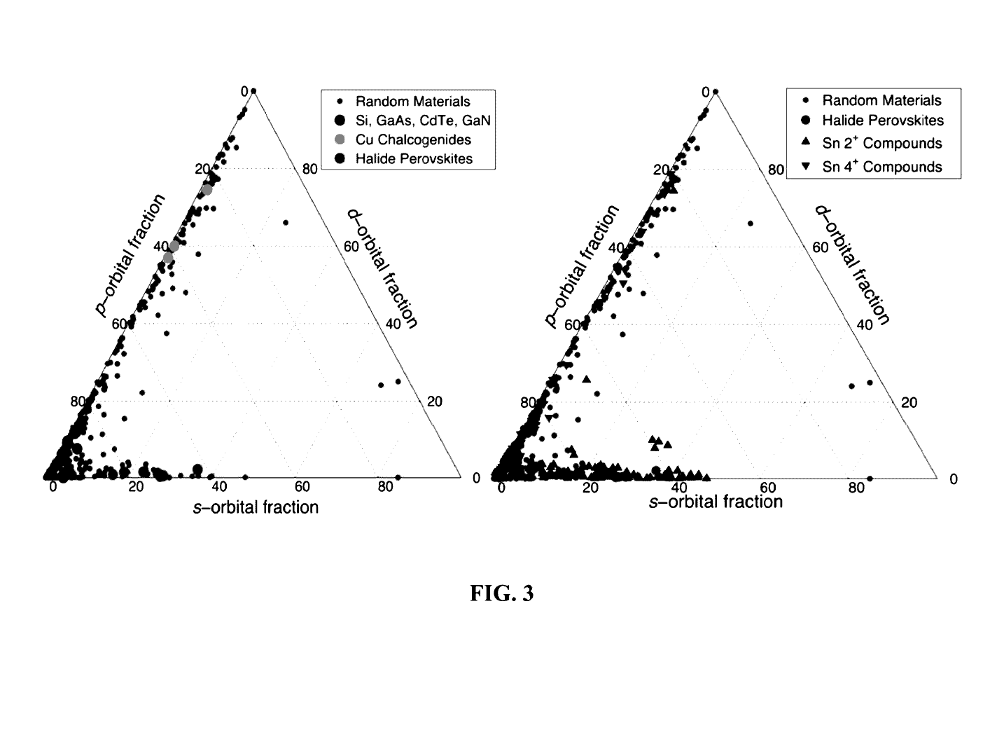

In FIG. 3, a random subset of the materials identified in this broad search was compared, and the stark differences were found in VBM density of states character for different classes of materials. Overlayed on the left are the conventional zincblende and wurtzite semiconductors for PV, as well as Cu-chalcogenides showing higher d-orbital fraction, and the halide perovskites with higher s-orbital fraction. On the right, Sn-containing compounds demonstrate a distinct split along two axes, with Sn²⁺ compounds demonstrating similar character to the halide perovskites. Conventional tetrahedrally coordinated III-V and II-VI compounds all demonstrate almost exclusive p orbital character at the valence band maximum, as do the majority of compounds. Other defect tolerant Cu-chalcogenide semiconductors, such as CuInSe₂, demonstrate a large d-orbital character in the valence band due to full 3d cation orbitals. Meanwhile, the inorganic I-II-VII₃ family of perovskites sit along the bottom axis, reflecting their larger s-orbital fraction in the valence band density of states. However, they are not unique in this property. In addition, a random fraction (30%) of the Materials Project Sn-cation compounds is plotted on these axes as well, separating them by those with Sn²⁺ and Sn⁴⁺ cations. The Sn²⁺ cation-compounds cluster in the same region as the halide perovskites, while Sn⁴⁺ compounds resemble the vast majority of semiconductors with anion p-orbital or transition metal cation d-orbital character.

Finding good candidate semiconductors with the N-2 oxidation state is not straightforward, for several reasons. Firstly, the use of more electronegative anions (oxygen, fluorine, and chlorine) tends to fully oxidize these cations. By pairing them with sulfur, selenium, iodine, and bromine, or by including a less electronegative cation such as an alkali metal, it is possible to stabilize the lower oxidation state. Secondly, the lone s orbitals are often stereochemically active (see A. Walsh, D. J. Payne, R. G. Egdell, G. W. Watson, Stereochemistry of post-transition metal oxides: revision of the classical lone pair model, Chem. Soc. Rev. 40 (2011) 4455, which is incorporated by reference in its entirety), leading to lower symmetry point groups, and a higher likelihood of indirect gaps. For example, for Sn compounds from the Materials Project database, 29% of those with Sn²⁺ are found to have indirect bandgaps, while for Sn⁴⁺, 47% have direct bandgaps. Anisotropic crystal structures may also lead to anisotropic transport properties and surface potentials (see, V. Stevanović, K. Hartman, R. Jaramillo, S. Ramanathan, T. Buonassisi, P. Graf, Variations of ionization potential and electron affinity as a function of surface orientation: The case of orthorhombic SnS, Appl. Phys. Lett. 104 (2014) 211603, which is incorporated by reference in its entirety), which may adversely influence device performance. Lastly, these cations may convert to the higher oxidation states inadvertantly, when exposed to oxidizers such as oxygen or moisture. In CsSnI₃ and MASnI₃, this Sn⁴⁺ formation results in metallic behavior with very high carrier concentrations. See, A. Walsh, Principles of Chemical Bonding and Band Gap Engineering in Hybrid Organic-Inorganic Halide Perovskites, J. Phys. Chem. C. 119 (2015) 5755-576, and I. Chung, J.-H. Song, J. Im, J. Androulakis, C. D. Malliakas, H. Li, et al., CsSnI3: Semiconductor or metal? High electrical conductivity and strong near-infrared photoluminescence from a single material. High hole mobility and phase-transitions, J. Am. Chem. Soc. 134 (2012) 8579-8587, each of which is incorporated by reference in its entirety.

Lastly, all of the materials identified in the MaterialsProject.org search are inorganic, recognizing the important role that the asymmetric, molecular cations such as methylammonium play in achieving large dielectric constants in these materials. Converting the inorganic materials identified herein into hybrid organic-inorganic analogues can lead to improved defect tolerance, but the presence of MA or other molecular cations is not the most important criteria in achieving defect-tolerance. Thus, replacement of Pb in MAPbX₃ with transition metal cations may not yield high-performing semiconductors.

### II. Outlook: Identifying Other Promising Materials Classes with Excellent Transport Properties

By filtering the materials data drawn from the Materials Project database, several interesting classes that may share the beneficial properties identified above are investigated. This search first identifies the class of halide perovskites (CsPbI₃, CsSnI₃, RbPbBr₃, etc.), while prior optoelectronic screening efforts have not identified these as promising materials.

In the list below, Pb²⁺ and Tl⁺-containing compounds were excluded based on toxicity; there are many promising optoelectronic materials containing these atoms. Unfortunately, the beneficial properties of Pb²⁺ and Tl⁺ are also connected to their toxicity, as they mimic the large ionic sizes of Ca²⁺ and K⁺ in the human body. This excludes the binary lead and thallium halides and chalcogenides such as TlBr, as well as a number of ternary chalcohalides or chalcogenides such as TlBiS₂.

In addition, this search is limited to materials existing in the MaterialsProject.org database. New materials may be discovered or designed using the present framework, for example the recently discovered Bi₂FeCrO₆ perovskite, which achieves an unusually small bandgap for a complex oxide ferroelectric and promising photovoltaic performance. See, R. Nechache, C. Harnagea, S. Li, L. Cardenas, W. Huang, J. Chakrabartty, et al., Bandgap tuning of multiferroic oxide solar cells, Nat. Photonics. 9 (2015) 61-67, which is incorporated by reference in its entirety.

The electronic structure was computed from first principles for several classes of materials, which were identified through the broad computational survey. These classes are described below:

1.) Binary Chalcogenides and Halides (BiI₃, Bi₂S₃, SbI₃, Sb₂S₃, SnI₂, InI, Etc.):
There are many binary iodides, sulfides, and selenides formed with ns²np⁰ cations, several of which have bandgaps in the range of interest for PV. Those with bandgaps 1.7 eV and greater, such as BiI₃, PbI₂, and TlBr, have been demonstrated successfully in X-ray detecting and scintillator applications, with high μτ products. See, P. J. Sellin, Thick film compound semiconductors for X-ray imaging applications, Nucl. Instrum. Methods Phys. Res. Sect. A. 563 (2006) 1-8, A.-V. Mudring, Thallium Halides—New Aspects of the Stereochemical Activity of Electron Lone Pairs of Heavier Main-Group Elements, Eur. J. Inorg. Chem. 2007 (2007) 882-890, and A. T. Lintereur, W. Qiu, J. C. Nino, J. Baciak, Characterization of bismuth tri-iodide single crystals for wide band-gap semiconductor radiation detectors, Nucl. Instrum. Methods Phys. Res. Sect. A. 652 (2011) 166-169, each of which is incorporated by reference in its entirety.

2.) Binary Halides, Sulfides, and Selenides Stabilized in Cubic Structures Like NaCl and CsCl:
Given the anisotropic transport properties that result from stereochemically active lone pairs in materials like SnS, more promising materials may result by stabilizing them in higher symmetry phases. Recently, it was demonstrated that SnS and SnSe may be stabilized in the NaCl structure by alloying with CaS. See, J. Vidal, S. Lany, J. Francis, R. Kokenyesi, J. Tate, Structural and electronic modification of photovoltaic SnS by alloying, J. Appl. Phys. 115 (2014) 113507, which is incorporated by reference in its entirety. Similarly, TlI may be stabilized in the CsCl phase by alloying, suggesting a possible similar route with InI. See, E. A. Secco, A. Sharma, Structure stabilization: Locking-in fast cation conductivity phase in TlI, J. Phys. Chem. Solids. 56 (1995) 251-254, which is incorporated by reference in its entirety.

3.) Chalcohalides (BiOI, BiSI, BiSeI, SbSI, SbSeI, BiSBr, BiSeBr, Etc.):
The ns²np⁰ chalcohalides (V-VI-VII compounds) range over visible to UV bandgaps, and many demonstrate ferroelectric behavior at lower temperatures as well. Both Sb- and Bi-containing varieties have demonstrated photoconductive or photovoltaic effects. SbSI and SbSeI have recently been identified for their potential applications as photoferroelectrics, however those in the paraelectric phase may still demonstrate large Born effective charge, and a large static dielectric constant. See, R. Nitsche, W. J. Merz, Photoconduction in ternary V-VI-VII compounds, J. Phys. Chem. Solids. 13 (1960) 154-155, N. T. Hahn, A. J. E. Rettie, S. K. Beal, R. R. Fullon, C. B. Mullins, n-BiSI Thin Films: Selenium Doping and Solar Cell Behavior, J. Phys. Chem. C. 116 (2012) 24878-24886, N. T. Hahn, J. L. Self, C. B. Mullins, BiSI Micro-Rod Thin Films: Efficient Solar Absorber Electrodes?, J. Phys. Chem. Lett. 3 (2012) 1571-1576, X. Zhang, L. Zhang, T. Xie, D. Wang, Low-Temperature Synthesis and High Visible-Light-Induced Photocatalytic Activity of BiOI/TiO₂ Heterostructures, J. Phys. Chem. C. 113 (2009) 7371-7378, K. Zhao, X. Zhang, L. Zhang, The first BiOI-based solar cells, Electrochem. Commun. 11 (2009) 612-615, and K. T. Butler, J. M. Frost, A. Walsh, Ferroelectric materials for solar energy conversion: photoferroics revisited, Energy Environ. Sci. 8 (2015) 838-848, each of which is incorporated by reference in its entirety.

4.) Ternary Alkali Chalcogenides (LiBiS₂, NaBiS₂, KBiS₂, RbBiS₂, CsBiS₂, Etc.):
Similar to the formation of I-III-VI₂ analogues of the zincblende II-VI compounds, one may form I-III-VI₂ rocksalt compounds based on the PbS and PbSe rocksalt phases. See, B. V. Gabrel'yan, A. A. Lavrentiev, I. Y. Nikiforov, V. V. Sobolev, Electronic energy structure of MBiS2 (M=Li, Na, K) calculated with allowance for the difference between the M-S and Bi—S bond lengths, J. Struct. Chem. 49 (2008) 788-794, S. Kang, Y. Hong, Y. Jeon, A Facile Synthesis and Characterization of Sodium Bismuth Sulfide (NaBiS₂) under Hydrothermal Condition, Bull. Korean Chem. Soc. 35 (2014) 1887-1890, and T. J. McCarthy, S. P. Ngeyi, J. H. Liao, D. C. DeGroot, T. Hogan, C. R. Kannewurf, et al., Molten salt synthesis and properties of three new solid-state ternary bismuth chalcogenides, .beta.-CsBiS2, .gamma.-CsBiS2, and K2Bi8Se13, Chem. Mater. 5 (1993) 331-340, each of which is incorporated by reference in its entirety. These include Pb-free chalcogenides with an octahedrally-coordinated Bi³⁺ cation.

5.) Ternary Halides: (In₃SnI₅, InAlI₄, Etc.):
In⁺ and Tl⁺ may be stabilized by several non-coordinating molecular anions such as AlI₄⁻. See, T. Timofte, A.-V. Mudring, Indium(I) Tetraiodoaluminate, InAlI4, Z. Für Anorg. Allg. Chem. 634 (2008) 622-623, which is incorporated by reference in its entirety. In addition, multiple cations can be stabilized in their lower oxidation states together, as in Sn²⁺ and In⁺ in the case of In₃SnI₅.

6.) In+-II-VII₃ Ternary Halides (CdInBr₃, CaInBr₃, Etc.):
In is also stabilized in a number of In-II-VII₃ compounds, which appear to have bandgaps outside of the range for PV, but which may exhibit similar defect tolerant properties.

7.) Bismides and Antimonides (e.g., KSnSb):
Sn²⁺ and other partially-oxidized cations are stabilized in several bismides and antimonides, most of which have bandgaps too small for PV absorbers.

8.) Octahedrally-Coordinated Metal Halides (Cs₃Bi₂I₉, Rb₃Bi₂I₉, K₃Bi₂I₉, Cs₃Sb₂I₉, Etc.):
Bi³⁺ and Sb³⁺ form III₂X₉³⁻ anions that consist of edge or face-sharing octahedra, bonding with alkali metals to form a variety of materials with different bandgaps, crystal structures, and ferroelectric phase transitions. See, S. V. Mel'nikova, A. I. Zaitsev, Ferroelectric phase transition in Cs3Bi2I9, Phys. Solid State. 39 (1997) 1652-1654, E. Y. Peresh, V. I. Sidei, N. I. Gaborets, O. V. Zubaka, I. P. Stercho, I. E. Barchii, Influence of the average atomic number of the A2TeC6 and A3B2C9 (A=K, Rb, Cs, Tl(I); B=Sb, Bi; C=Br, I) compounds on their melting point and band gap, Inorg. Mater. 50 (2014) 101-106, R. Jakubas, L. Sobczyk, Phase transitions in alkylammonium halogenoantimonates and bismuthates, Phase Transit. 20 (1990) 163-193, and L.-M. Wu, X.-T. Wu, L. Chen, Structural overview and structure—property relationships of iodoplumbate and iodobismuthate, Coord. Chem. Rev. 253 (2009) 2787-2804, each of which is incorporated by reference in its entirety.

9.) Cs-Containing Compounds Substituting 1+Molecular Cations (e.g., (MA)₃Bi₂I₉, (Fa)₃Bi₂I₉, Etc.):
Lastly, a variety of Cs-containing materials are identified, which can be converted to hybrid materials by the substitution of the Cs with an alkylammonium or other molecular cation. See, R. Jakubas, L. Sobczyk, Phase transitions in alkylammonium halogenoantimonates and bismuthates, Phase Transit. 20 (1990), and T. Plackowski, D. Wlosewicz, P. E. Tomaszewski, J. Baran, M. K. Marchewka, Specific heat of (NH2(CH3)2)3Bi2I9, Acta Phys. Pol. A. 87 (1995) 635-641, each of which is incorporated by reference in its entirety. A simple example is the family containing (MA)₃Bi₂I₉ or (FA)₃Bi₂I₉. A number of other molecular cations can be substituted as well based on size, analogous to the substitution explored in MAPbX₃, to tune the bandgap or to form lower-dimensional structures. See, G. Kieslich, S. Sun, A. K. Cheetham, Solid-state principles applied to organic—inorganic perovskites: new tricks for an old dog, Chem Sci. 5 (2014) 4712-4715, and M. R. Filip, G. E. Eperon, H. J. Snaith, F. Giustino, Steric engineering of metal-halide perovskites with tunable optical band gaps, Nat. Commun. 5 (2014) 5757, each of which is incorporated by reference in its entirety.

As an illustration, first principles (DFT) calculations was performed on some of the above-listed materials to probe whether these materials have low effective masses and high static dielectric constants, in addition to containing cation antibonding orbitals in the VB, and compare these results to those of MAPbI₃. These DFT results are summarized in Table 1, including the bandgap (E_{G}), relative valence band (E_{V}) and conduction band energies (E_{C}), effective masses m* for holes and electrons from the DOS, the band degeneracy at the CBM and VBM extrema, and the ionic dielectric constant. DFT calculations are performed with spin-orbit coupling; the band extrema energies are compared with and without spin-orbit coupling to demonstrate the relativistic effects. DFT is known to consistently under-predict the bandgap, thus, the electronic component of the dielectric constant is not presented. Instead, only the ionic dielectric constant computed from density functional perturbation theory is presented. In addition, the band gap values, both the minimum and the direct gap, are given to provide an indication of the type of optical transition at the lowest energy gap. The larger the difference between the minimal and the direct gap, the weaker the absorption onset is. More information on these calculations is supplied in the methods section.

TABLE 1
DFT-computed band structures, band dispersion (with spin-orbit coupling, SO), effective masses, and ionic dielectric constants for
several compounds of interest, as compared to tEG he (MA)BX₃ family of perovskites.

| | Space Group | E_{G} [eV] | E_{G} direct | E_{G} (DFT + | E_{V} (DFT + | E_{C} (DFT + | | | | | Ionic |
|---|---|---|---|---|---|---|---|---|---|---|---|
| | (International | (DFT + | [eV] | SO) − E_{G} | SO) − E_{V} | SO) − E_{C} | | | VBM band | CBM band | dielectric |
| Formula | S.G. number) | SO) | (DFT + SO) | (DzFT) | (DFT) | (DFT) | m*_{h, DOS} | m*_{e, DOS} | degeneracy | degeneracy | constant |
| InI | Cmcm (63) | 1.29 | 1.29 | −0.09 | 0.08 | −0.01 | 0.25 | 0.15 | 2 | 2 | 33.51 |
| SnI₂ | C12/m1 (12) | 1.58 | 1.74 | −0.18 | 0.10 | −0.08 | 1.49 | 0.35 | 4 | 2 | 28.84 |
| SbI₃ | R3̅H (148) | 1.88 | 1.96 | −0.26 | 0.18 | −0.08 | 9.57 | 2.12 | 1 | 1 | 8.32 |
| SbI₃ | P12₁/c1 (14) | 1.86 | 1.93 | −0.25 | 0.18 | −0.07 | 8.88 | 1.72 | 2 | 1 | 8.43 |
| BiI₃ | R3̅H (148) | 1.73 | 1.82 | −0.78 | 0.23 | −0.55 | 10.39 | 1.85 | 1 | 1 | 5.70 |
| BiI₃ | P3̅1m (162) | 1.66 | 1.72 | −0.81 | 0.23 | −0.57 | 9.34 | 0.79 | 1 | 2 | 5.78 |
| Sb₂S₃ | Pnma (62) | 1.28 | 1.30 | −0.02 | −0.01 | −0.03 | 3.89 | 0.88 | 2 | 3 | 44.94 |
| Bi₂S₃ | Pnma (62) | 1.14 | 1.14 | −0.24 | −0.17 | −0.41 | 2.86 | 0.49 | 2 | 1 | 400.33 |
| BiOI | P4/nmmS (129) | 1.38 | 1.49 | −0.13 | 0.00 | −0.14 | 3.75 | 0.37 | 9 | 1 | 46.32 |
| BiSI | Pnam (62) | 1.18 | 1.32 | −0.69 | 0.05 | −0.64 | 4.79 | 0.53 | 2 | 1 | 29.59 |
| BiSeI | Pnma (62) | 0.91 | 1.03 | −0.68 | 0.04 | −0.65 | 5.89 | 0.25 | 2 | 1 | 26.83 |
| BiSBr | Pnam (62) | 1.32 | 1.35 | −0.53 | −0.11 | −0.64 | 6.21 | 0.24 | 2 | 1 | 30.10 |
| SbSI | P2₁2₁2₁ (19) | 1.28 | 1.46 | −0.23 | 0.11 | −0.11 | 2.84 | 0.91 | 2 | 2 | 31.59 |
| SbSI | Pna2₁ (33) | 1.45 | 1.60 | −0.17 | 0.11 | −0.06 | 2.06 | 1.31 | 2 | 2 | 69.72 |
| SbSI | Pnam (62) | 1.45 | 1.60 | −0.17 | 0.11 | −0.06 | 2.06 | 1.25 | 4 | 2 | 69.38 |
| SbSeI | Pnma (62) | 1.16 | 1.29 | −0.20 | 0.10 | −0.10 | 4.37 | 0.59 | 2 | 2 | 43.94 |
| RbBiS₂ | R3̅mH (166) | 1.12 | 1.47 | −0.22 | −0.04 | −0.27 | 10.96 | 0.20 | 1 | 2 | 37.94 |
| InAlI₄ | P12₁/m1 (11) | 2.87 | 2.87 | −0.15 | 0.12 | −0.03 | 1.49 | 3.90 | 2 | 2 | 19.59 |
| CaInBr₃ | Cmcm (63) | 3.12 | 3.28 | −0.04 | 0.02 | −0.02 | 1.43 | 0.27 | 1 | 2 | 69.26 |
| KSnSb | P6₃mc (186) | 0.18 | 0.38 | −0.08 | 0.12 | 0.04 | 0.25 | 0.04 | 0.5 | 4 | 2.92 |
| Cs₃Sb₂I₉ | P3̅m1 (164) | 1.40 | 1.41 | −0.14 | 0.20 | 0.05 | 2.19 | 0.25 | 1 | 7 | 13.06 |
| Cs₃Sb₂I₉ | P6₃/mmc (194) | 1.79 | 1.91 | −0.10 | 0.16 | 0.06 | 3.73 | 0.50 | 2 | 2 | 9.68 |
| Cs₃Bi₂I₉ | P6₃/mmc (194) | 1.90 | 2.04 | −0.46 | 0.24 | −0.22 | 4.63 | 1.79 | 2 | 3 | 9.63 |
| (MA)GeI₃ | Pm3̅m (221) | 0.82 | 0.82 | −0.18 | 0.11 | −0.06 | 0.43 | 0.51 | 2 | 2 | 6.89 |
| (MA)SnI₃ | Pm3̅m (221) | 0.12 | 0.12 | −0.29 | 0.05 | −0.24 | 0.12 | 0.65 | 1 | 1 | 25.57 |
| (MA)PbI₃ | Pm3̅m (221) | 0.31 | 0.31 | −1.12 | 0.13 | −1.00 | 0.10 | 0.16 | 1 | 1 | 20.07 |

It is important to draw attention to several conclusions from this table. Firstly, many of these materials are relatively ionic, like MAPbI₃, making it difficult to achieve smaller bandgaps (note again that the bandgaps presented here are underestimated, and many will be >2 eV in reality). Secondly, anisotropic crystal structures with stereochemically active lone pairs often lead to higher hole effective masses. Thirdly, most of the materials presented here demonstrate large ionic dielectric constants, independent of whether they have a polar space group. It is clear that MAPbI₃ offers an unusual mix of ionicity, high dielectric constant, low effective masses, and a lower bandgap for PV; few semiconductors can claim excellent performance across all categories.

Another conclusion consistent with prior observations is that compounds formed with 6p block cations show a significantly larger contribution of spin-orbit coupling in the conduction band, vs. those formed from the 5p block. While Pb and Tl compounds are not included here, the Bi compounds show a much stronger spin-orbit contribution than do the In, Sn, and Sb compounds. This may suggest that the Bi-containing compounds are most suitable for achieving similarly shallow anion vacancy levels as in MAPbI₃.

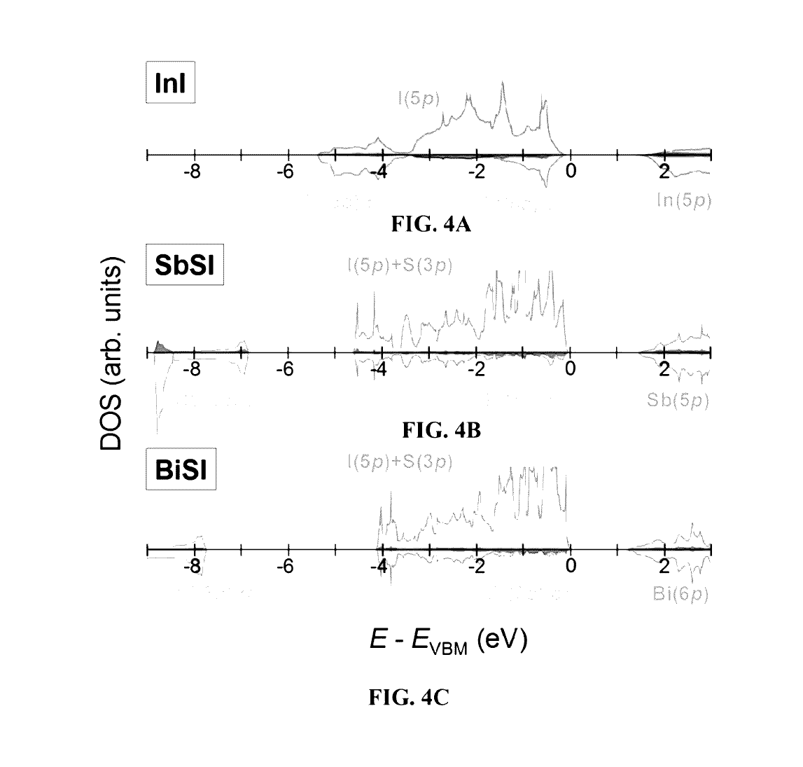

To illustrate the similarities in band-structure to MAPbI₃, the band orbital diagrams and density of states are presented in FIGS. 4A-4D for a handful of materials. The partial densities of states are separated into their atomic orbital contributions, with anions on the positive y-axis and cations on the negative axis. The cation s states separate into bonding a (lower energy) and antibonding σ* (higher energy) orbitals. As anticipated, they all demonstrate the same cation antibonding s-orbital contributions at the valence band maximum.

### III. Summary

Search criteria for the discovery of semiconductors for optoelectronic applications can include a strategy that builds upon the recent success of methyl-ammonium lead iodide as a PV material, which achieves excellent device efficiencies in the presence of defects.

While calculating defect-limited minority carrier mobility and lifetime is challenging, more fundamental electronic structure properties can be indicative of defect tolerance, demonstrated by models for defect-assisted recombination and scattering. These models are consistent with emerging experimental and theoretical observations of MAPbX₃, as well as other semiconductor systems, which share defect tolerance. Most importantly, MAPbX₃ is not unique in these properties, and a broad class of semiconductors containing partially oxidized cations is identified, as well as several specific instances that may share these properties. To demonstrate this, the MaterialsProject.org database of materials is searched through, and a set of criteria is established for future identification of promising defect-tolerant semiconductors.

Many fields would benefit from the development of semiconductors of a wide range of bandgaps that can achieve low non-radiative recombination rates and good transport—green LEDs, thin-film PV, and photodetectors, to name a few. This framework can provide a new direction for materials discovery in these fields, and in doing so, bring under-studied semiconductors to the fore to help build the next generation of energy-generating, light-emitting, sensing, and computing devices.

### Examples

### Screening Methods

All density functional theory (DFT) and related calculations are performed using VASP computer code. See, G. Kresse, J. Furthmüller, Efficient iterative schemes for total-energy calculations using a plane-wave basis set, Phys. Rev. B. 54 (1996) 11169-11186, which is incorporated by reference in its entirety. The GGA-PBE functional form of the exchange-correlation functional (see J. P. Perdew, K. Burke, M. Ernzerhof, Generalized Gradient Approximation Made Simple, Phys. Rev. Lett. 77 (1996) 3865-3868, which is incorporated by reference in its entirety) has been employed here, together with the projector-augmented wave (PAW) formalism. See, P. E. Blöchl, Projector augmented-wave method, Phys. Rev. B. 50 (1994) 17953-17979, which is incorporated by reference in its entirety. Full atomic, volume and cell shape relaxations are performed at the GGA-PBE level using the numerical setup, including k-point sampling and various cutoffs, following Stevanović et al (2012). See, V. Stevanović, S. Lany, X. Zhang, A. Zunger, Correcting density functional theory for accurate predictions of compound enthalpies of formation: Fitted elemental-phase reference energies, Phys. Rev. B. 85 (2012) 115104, which is incorporated by reference in its entirety. For the various electronic structure properties reported in Table 1, such as bandgaps, spin-orbit interaction contributions to band edges, DOS effective masses and band degeneracies; the denser k-point grid is used. For compatibility between different calculations, the number of k-points per atom was kept fixed at Natoms*Nkpts=6000, which leads to the convergence of relevant electronic structure properties. See, J. Yan, P. Gorai, B. Ortiz, S. Miller, S. A. Barnett, T. Mason, et al., Material descriptors for predicting thermoelectric performance, Energy Env. Sci. 8 (2014) 983-994, which is incorporated by reference in its entirety. The spin-orbit (SO) interaction is included at the level of first order perturbation to the DFT results. Ionic dielectric tensors are computed from the interatomic force constants obtained using density functional perturbation theory. See, X. Wu, D. Vanderbilt, D. R. Hamann, Systematic treatment of displacements, strains, and electric fields in density-functional perturbation theory, Phys. Rev. B. 72 (2005) 035105, which is incorporated by reference in its entirety. The dielectric constants reported in Table 1 are computed as one third of the trace (Tr(∈)/3) of the dielectric tensors.

### Methylammonium Bismuth Iodide (MBI) as a Lead-Free, Stable Hybrid Organic-Inorganic Solar Absorber

Methylammonium lead halide (MAPbX₃) perovskites exhibit exceptional carrier transport properties. But their commercial deployment as solar absorbers is currently limited by their intrinsic instability in the presence of humidity and their lead content. Guided by the theoretical predictions disclosed above, the potential of methylammonium bismuth iodide (MBI) is explored as a solar absorber through detailed materials characterization. Phase-pure MBI is synthesized by solution and vapor processing. In contrast to MAPbX₃, MBI is air-stable, forming a surface layer that does not increase the recombination rate. MBI luminesces at room temperature, with the vapor processed films exhibiting superior PL decay times that are promising for photovoltaic applications. The thermodynamic, electronic and structural features of MBI that are amenable to these properties are also found with other hybrid ternary bismuth halide compounds. MBI demostrates a lead-free and stable alternative to MAPbX₃ that has a similar electronic structure and nanosecond lifetimes.

Hybrid organic-inorganic materials, namely methylammonium lead halide perovskites, have recently generated considerable interest for optoelectronic applications. See, S. D. Stranks, H. J. Snaith, Nat. Nanotechnol. 2015, 10, 391-402, which is incorporated by reference in its entirety. The efficiency of photovoltaics based on hybrid lead perovskites now exceeds 20%. See, W. S. Yang, J. H. Noh, N. J. Jeon, Y. C. Kim, S. Ryu, J. Seo, S. Il Seok, Science. 2015, 348, 1234-1237, which is incorporated by reference in its entirety. An important reason for this is the long charge carrier lifetimes. See, S. D. Stranks, G. E. Eperon, G. Grancini, C. Menelaou, M. J. P. Alcocer, T. Leijtens, L. M. Herz, A. Petrozza, H. J. Snaith, Science 2013, 342, 341-345, which is incorporated by reference in its entirety. However, these perovskites readily decompose in the presence of humid air. Improvements in the intrinsic stability of perovskites have been demonstrated by using long alkylammonium chains. See, I. C. Smith, E. T. Hoke, D. Solis-Ibarra, M. D. McGehee, H. I. Karunadasa, Angew. Chem. Int. Ed. 2014, 53, 11232-11235; Angew. Chem. 2014, 126, 11414-11417, D. H. Cao, C. C. Stoumpos, O. K. Farha, J. T. Hupp, M. G. Kanatzidis, J. Am. Chem. Soc. 2015, 137, 7843-7850, and N. Aristidou, I. Sanchez-Molina, T. Chotchuangchutchaval, M. Brown, L. Martinez, T. Rath, S. A. Hague, Angew. Chem. Int. Ed. 2015, 54, 8208-8212; Angew. Chem. 2015, 127, 8326-8330, each of which is incorporated by reference in its entirety. But these compounds still contain Pb²⁺, which is a toxic, bioavailable cation. See, Guidance Manual for the Integrated Exposure Uptake Biokinetic Model for Lead in Children”, United States Environmental Protection Agency, Research Triangle Park, NC, can be found under http://nepis.epa.gov/, 1994, which is incorporated by reference in its entirety. Lead-free hybrid perovskites based on methylammonium tin iodide have been developed, exhibiting initial efficiencies of up to 6.4%. But Sn²⁺ readily oxidizes to Sn⁴⁺, which results in poor stability. See, N. K. Noel, S. D. Stranks, A. Abate, C. Wehrenfennig, S. Guarnera, A.-A. Haghighirad, A. Sadhanala, G. E. Eperon, S. K. Pathak, M. B. Johnston, et al., Energy Environ. Sci. 2014, 7, 3061-3068, and F. Hao, C. C. Stoumpos, D. H. Cao, R. P. H. Chang, M. G. Kanatzidis, Nature Photon. 2014, 8, 489-494, each of which is incorporated by reference in its entirety. This is a challenge that may be difficult to solve by using alternative alkylammonium groups. Alternatively, the Sn²⁺ cation can be replaced with a non-toxic 6p-block element, for which relativistic effects lower the energy of the outer s orbital, leading to the outer lone pair of 6s² electrons having improved stability. See, U.S. Provisional Application No. 62/141,662, which is incorporated by reference in its entirety. Bi³⁺ is one such cation. See, L. M. Schoop, L. Müchler, C. Felser, R. J. Cava, Inorg. Chem. 2013, 52, 5479-5483, which is incorporated by reference in its entirety. An advantage of these lone-pair cations is that they tend to have high dielectric constants due to high Born effective charges. See, M. H. Du, D. J. Singh, Phys. Rev. B 2010, 82, 045203, which is incorporated by reference in its entirety. These increase the ability to screen charged defects within the materials. Thus, in the computational search disclosed herein, octahedrally-coordinated bismuth halides were predicted as one class of defect-tolerant materials. Defect-tolerant solar absorbers may exhibit longer charge carrier lifetimes by having lower intrinsic trap densities and defect states with lower capture cross-sections and shallower positions, which together lead to lower non-radiative recombination rates. Longer charge carrier lifetimes are necessary for elevated optoelectronic performance. But carrier lifetime has traditionally not been considered at the beginning of new solar absorber development. This may have led in part to many materials in past performing below their theoretical limits. See, V. Steinmann, R. E. Brandt, T. Buonassisi, Nature. Photon. 2015, 9, 355-357, and R. Jaramillo, M.-J. Sher, B. K. Ofori-Okai, V. Steinmann, C. Yang, K. Hartman, K. A. Nelson, A. M. Lindenberg, R. G. Gordon, arXiv:1511.07887 [cond-mat.mtrl-sci] 2015, Submitte, each of which is incorporated by reference in its entirety. A focus on fundamental materials properties, such as lifetime, in addition to traditional screening metrics (absorption coefficient and bandgap) (see L. Yu, A. Zunger, Phys. Rev. Lett. 2012, 108, 068701, which is incorporated by reference in its entirety) may offer a route to faster and more accurate feedback on the material's potential as a solar absorber, before undertaking a costly device fabrication effort.

Herein, methylammonium bismuth iodide (MBI) was experimentally evaluated as a candidate solar absorber, based on its bulk materials properties, including carrier lifetime. This material has previously received some attention from the ferroelectrics community. See, G. Bator, J. Baran, R. Jakubas, L. Sobczyk, J. Mol. Struct. 1998, 450, 89-100, G. Batora, R. Jakubasa, J. Baranb, H. Ratajczak, J. Mol. Struct. 1994, 325, 45-51, R. Jakubas, J. Zleski, L. Sobczyk, Ferroelectrics, 1990, 108, 109-114, and R. Jakubas, R. Decressain, J. Lefebvre, J. Phys. Chem. Solids 1992, 53, 755-759, each of which is incorporated by reference in its entirety. But it was not until very recently that MBI was explored for photovoltaics. See, B.-W. Park, B. Philippe, X. Zhang, H. Rensmo, G. Boschloo, E. M. J. Johansson, Adv. Mater. 2015, 9, 6806-6813, which is incorporated by reference in its entirety. A device efficiency of 0.12% was reported using solution-processing, but it is unclear whether this is limited by the fabrication method, possible phase impurities, or sub-optimal contacts. See, B.-W. Park, B. Philippe, X. Zhang, H. Rensmo, G. Boschloo, E. M. J. Johansson, Adv. Mater. 2015, 9, 6806-6813, which is incorporated by reference in its entirety. In this work, phase-pure MBI is synthesized by solution-processing and vapor-assisted techniques. The structure, stability and optoelectronic properties of MBI are analyzed through both experiment and theory to evaluate whether this material is promising as an absorber. The result shows that it does not degrade to BiI₃ in humid ambient air. By contrast, MAPbI₃ degrades to PbI₂ within days. MBI has an indirect bandgap of 2.04 eV, with optical absorption coefficients approaching 10⁵ cm⁻¹. These make it potentially suitable as the top absorber in tandem solar cells. MBI also luminesces at room temperature. As a result, thin films made by vapor-assisted conversion have superior photoluminescence (PL) decay times over solution-assisted conversion MBI. Other hybrid ternary bismuth halides share the features of MBI that are amenable to stability in air and long lifetimes. Through this work, an alternative material was identified to the hybrid lead perovskites that is promising for photovoltaics, air-stable, and lead-free.

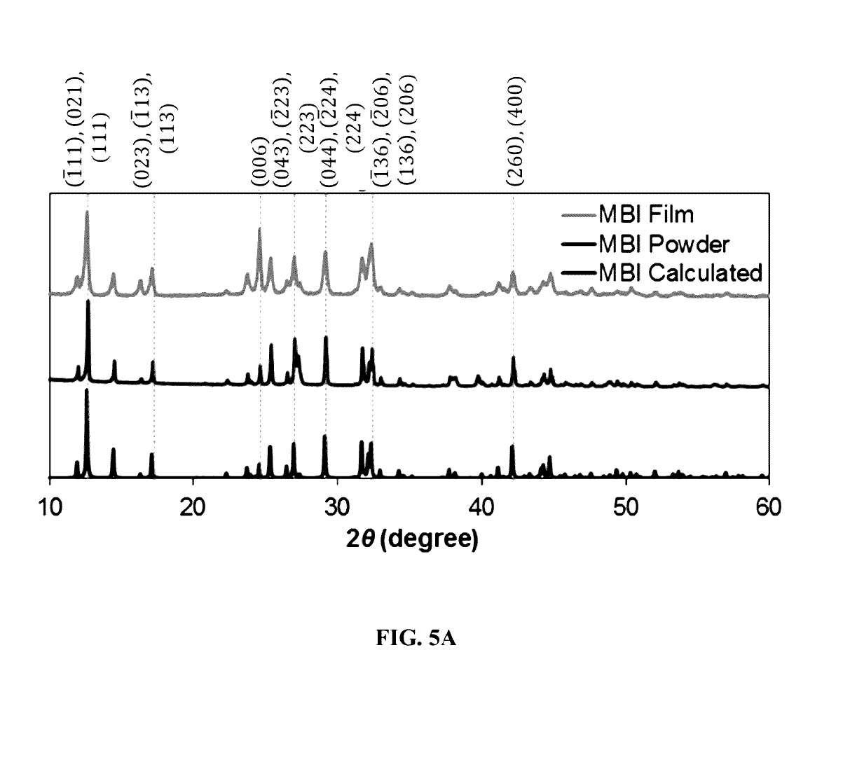

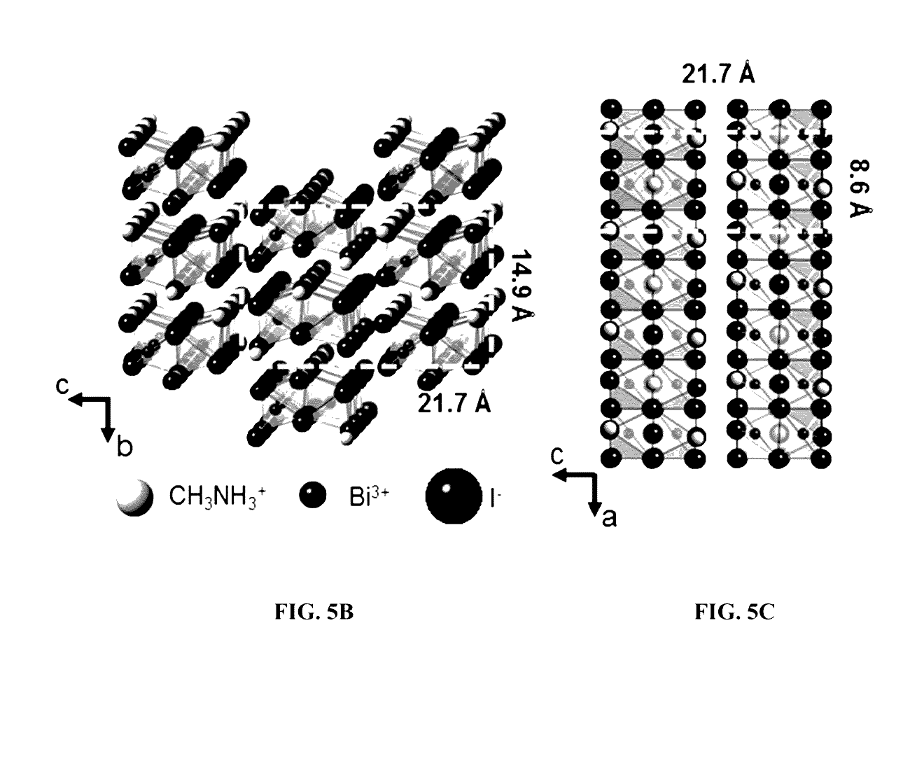

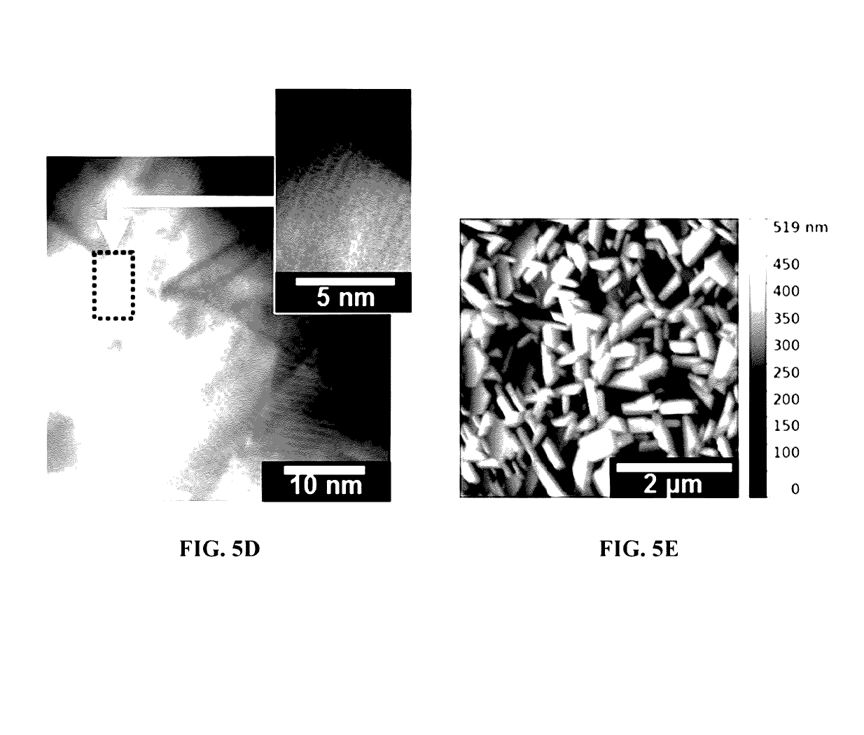

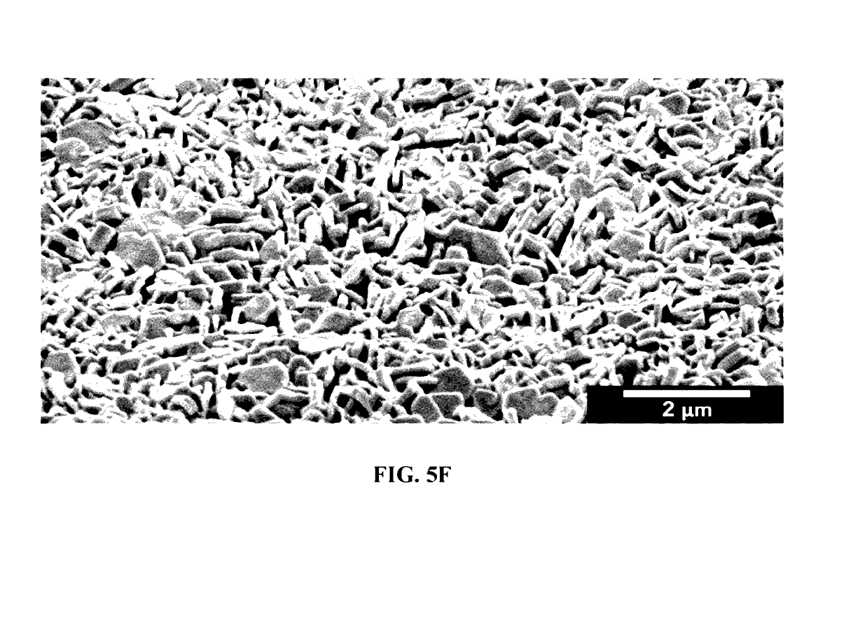

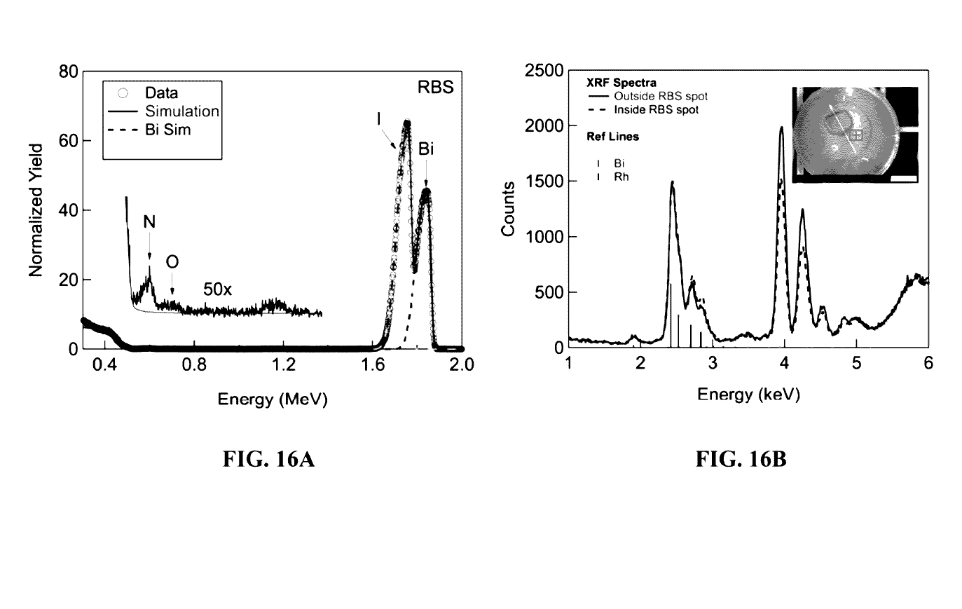

MBI thin films were initially synthesized by solution-assisted conversion. BiI₃ is reacted with methylammonium iodide solution and processed at up to 100° C. (see Experimental Section). FIGS. 5A-5F show structure of methylammonium bismuth iodide (MBI). The image shown has the contrast increased by 40% and brightness increased by 20% to improve clarity. The diffraction pattern of MBI thin films is shown in FIG. 5A. Miller indices of some of the main peaks are shown. The crystallographic information file is deposited with the Cambridge Crystallographic Data Centre (number: 1426733; see Table 2). To establish the crystallographic structure of MBI, Rietveld refinement of the powder X-ray diffraction (XRD) pattern was performed. The MBI consists of Bi₂I₉³⁻ groups alternating with CH₃NH₃⁺ cations (FIGS. 5B and 5C), with the overall chemical formula: (CH₃NH₃)₃Bi₂I₉. Rutherford Backscattering Spectroscopy shows that the main elements of MBI are Bi, I, C and N (FIG. 16), but beam damage prevents us from confirming the stoichiometry using this method.

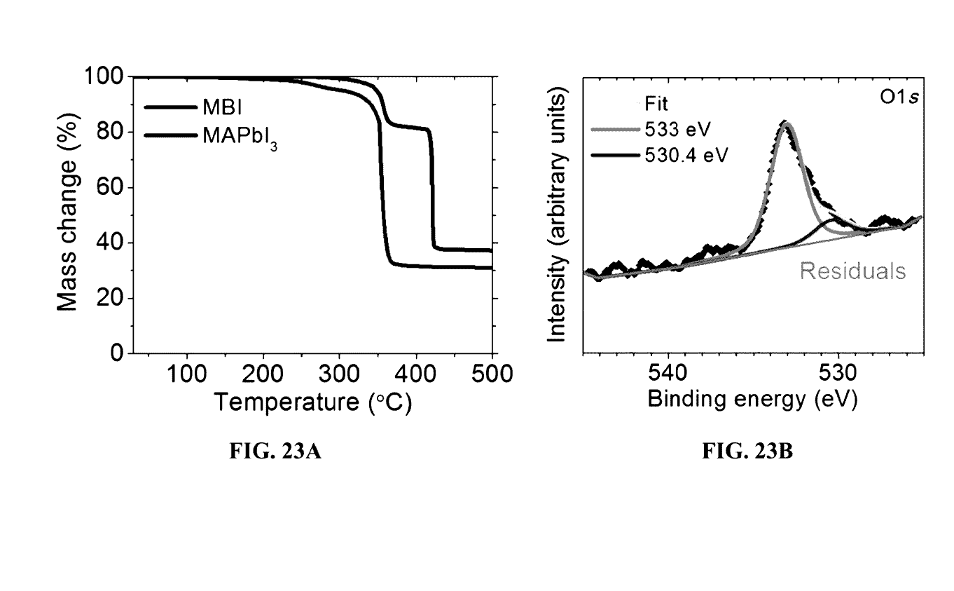

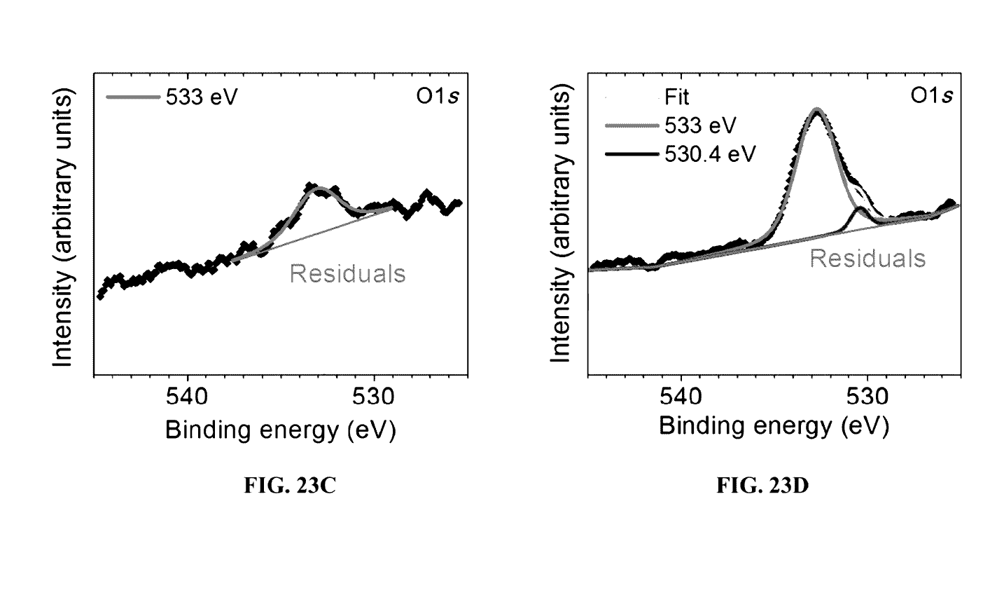

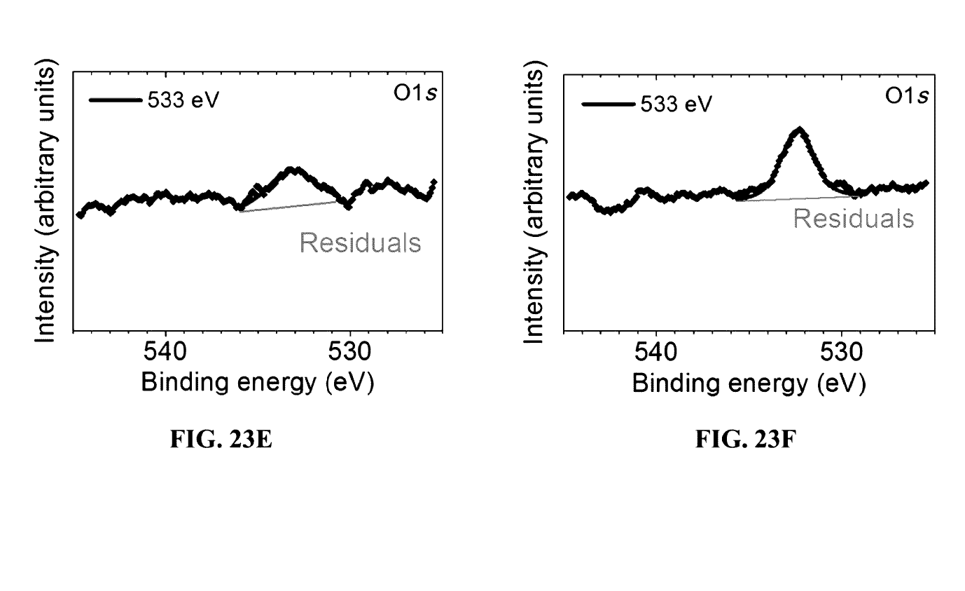

FIG. 16A shows RBS measurements of MBI thin films measured under a 2 MeV He⁺ ion beam in a nearly 180° backscattering geometry using a beam current of 20 nA and 40 μC accumulated charge. FIG. 16B shows X-ray fluorescence (XRF) measurements of the same sample comparing spectra from within the spot characterized by RBS and outside the measurement spot. Inset is a photograph of the RBS sample, clearly showing the measurement spot. The scale bar in the photograph is 3 mm. The XRF measurement beam diameter was 25 μm. The MBI thin films were deposited on vitreous carbon substrates to enable observation of the N signal. RBS measurements show that the main elements in the MBI film are Bi, I, C and N, with some O also present (O:Bi≈0.12:1). The samples were also exposed to air for a week prior to characterization by RBS, and XPS measurements (FIGS. 23A-23F) show that surface oxygen species form upon air exposure. The high energy edge of the carbon signal occurs at the expected ‘RBS front surface energy’ indicating that C is present in the film. The small peaks at ˜1.2 MeV likely arise from small quantities of impurities (likely P, S or Cl at ≦3% of the Bi content). The composition of the thin film cannot be accurately quantified through RBS measurements because of degradation upon exposure to the He ion beam. This has previously been observed with MAPbI₃. See, R. Gottesman, L. Gouda, B. S. Kalanoor, E. Haltzi, S. Tirosh, E. Rosh-Hodesh, Y. Tischler, A. Zaban, C. Quarti, E. Mosconi, et al., J. Phys. Chem. Lett. 2015, 6, 2332-2338, which is incorporated by reference in its entirety. The XRF measurements are consistent with MBI ion beam damage because it can be seen that the I content is lower inside the measurement spot. No change in the Bi content was observed in RBS spot compared to outside the measurement spot. The Rh peaks were due to the Rh X-ray source used for XRF measurements.

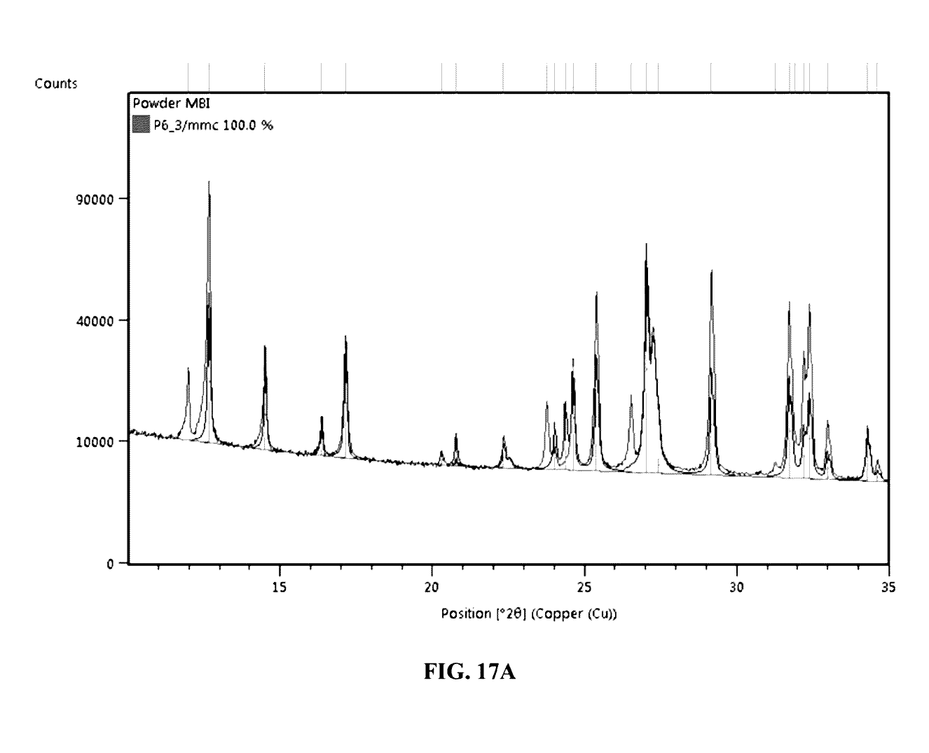

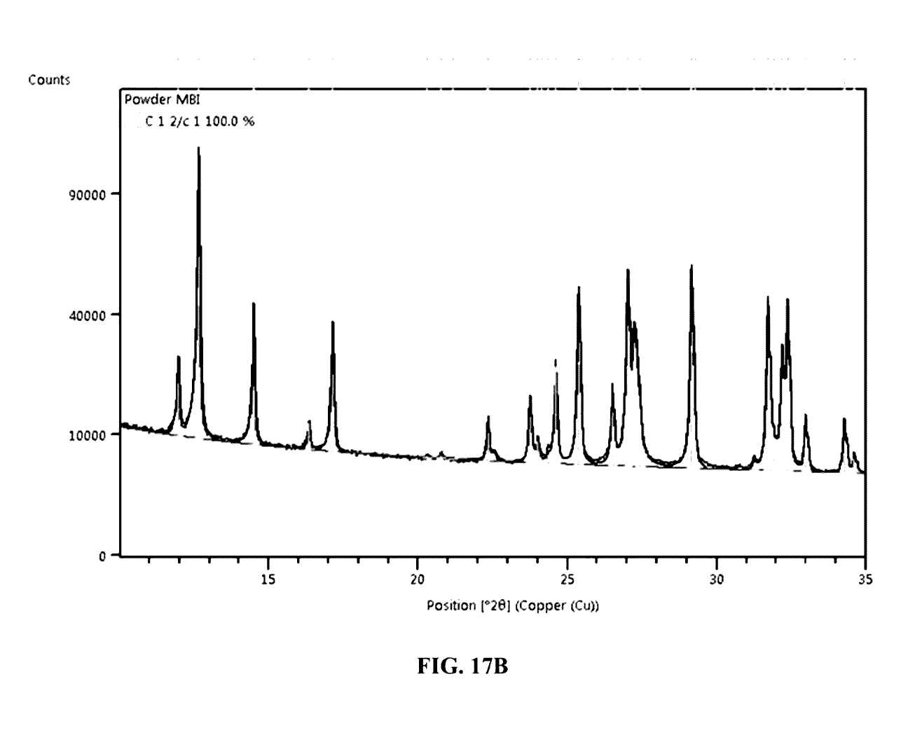

The arrangement of the Bi₂I₉³⁻ and CH₃NH₃⁺ groups is best fit with a monoclinic unit cell (space group of C 2/c, number 15, detailed in FIGS. 17A-17B) with lattice parameters of a=8.6 Å, b=14.9 Å and c=21.7 Å (FIGS. 5B and 5C). Previous measurements of the crystallographic structure of MBI by Weissenberg photographs and ferroelectricity measurements suggest a centrosymmetric hexagonal system, with P6₃/mmc as the suggested space group, similar to Cs₃Bi₂I₉. See, R. Jakubas, J. Zaleski, L. Sobczyk, Ferroelectrics 1990, 108, 109-114, G. Batora, R. Jakubasa, J. Baranb, H. Ratajczak, J. Mol. Struct. 1994, 325, 45-51, H. L. Wells, H. W. Foote, Am. Jour. Sci. 1897, 3, 461-465, and C. C. Meloche, P. V. Clark, J. Am. Chem. Soc. 1987, 52, 907-910, each of which is incorporated by reference in its entirety. However, Cs₃Bi₂I₉ has been reported to also exist as a monoclinic phase (space group C 2/c), which is also centrosymmetric. See, A. V. Arakcheeva, G. Chapuis, M. Meyer, Z. Kristallogr. 2001, 216, 199-205, and A. S. Eggeman, A. Sundaresan, C. N. R. Rao, P. A. Midgley, JPCS 2012, 371, 012033, each of which is incorporated by reference in its entirety. Both space groups were refined to the powder diffraction pattern of MBI and found that not all of the peak intensities match the P6₃/mmc space group, whereas the C 2/c space group fits all peaks. This indicates that the C 2/c space group better describes the atomic arrangement in the MBI. The parameters of the monoclinic space group fit are given in Table 2. The refined value of β is close to being 90°. Orthorhombic space groups were attempted to find with similar symmetry equivalent points but were unable to find one with a reasonable arrangement of atoms that could fit the powder diffraction pattern.

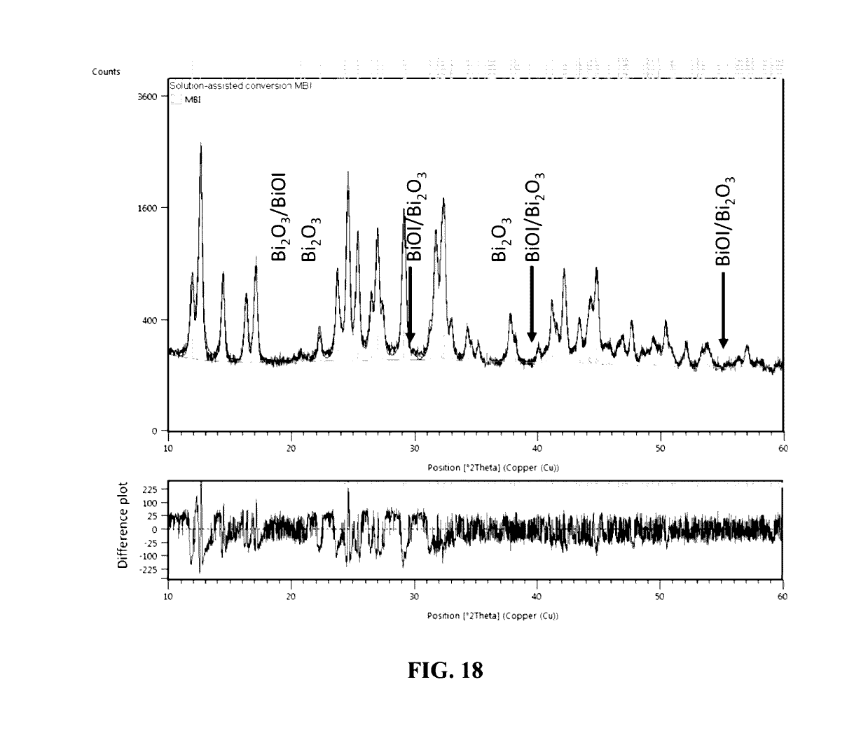

The calculated diffraction pattern matches very closely with the powder diffraction pattern (FIGS. 5A and 17B). The thin film MBI exhibits diffraction peaks corresponding to the pure MBI phase, as confirmed by the calculated XRD pattern (FIG. 5A). No secondary phases or amorphous material are detected by either XRD or TEM (FIGS. 5A, 5D and 18).

TABLE 2
Crystallographic data for methylammonium bismuth iodide^{a}

| Refined formula | C₃H₁₈N₃Bi₂I₉ |
|---|---|
| Formula weight (g · mol⁻¹) | 1638.15 |
| Crystal system | monoclinic |
| Space group, number | C 2/c, 15 |
| a (Å) | 8.572(1) |
| b (Å) | 14.861(7) |
| c (Å) | 21.745(9) |
| α (°) | 90.000 |
| β (°) | 90.040 |
| γ (°) | 90.000 |
| Volume (Å³) | 2770.427 |
| Number of formula units in unit cell, Z | 4 |
| Calculated density (g · cm⁻³) | 3.928 |
| Temperature (K) | 300 |
| Measurement range: 2θₘᵢₙ, 2θₘₐₓ (°) | 10.01, 99.98 |
| Number of peaks fit | 1469 |
| R_{profile}^{b}, % | 5.131(8) |
| Weighted R_{wprofile}^{b}, % | 5.993(0) |
| Goodness of fit (χ)^{b} | 3.027(4) |

^{a}Rietveld refinement was performed using Highscore Plus version 4. The crystallographic information file is deposited with CCDC, number: 1426733. Data collection methods are given in the Experimental Section.
^{b}In a good fit, the weighted R_{wprofile} should be less than 10% and the goodness of fit less than 4. See, S. A. Speakman, “Profile fitting for analysis of XRPD dta using HighScore Plus v3”, Massachusetts Institute of Technology, Cambridge MA, 2012, and R. Von Dreele, “Accuracy in Powder Diffraction “Are we there yet?””, NIST, Gaithersburg, MD, each of which is incorporated by reference in its entirety.
${R}_{profile} = \frac{\sum \vert {y}_{obs} - {y}_{calc} \vert}{\sum {y}_{obs}} , where {y}_{obs} is the measured intensity of reflec \text{-}$ tions and y_{calc} the calculated intensity. The weighted R_{wprofile} is
${R}_{wprofile} = {( \frac{\sum {{w}_{i} ( {y}_{obs} - {y}_{c alc} )}^{2}}{\sum {w}_{i} {y}_{obs}^{2}} )}^{1 / 2} and χ = {( \frac{\sum {{w}_{i} ( {y}_{obs} - {y}_{c alc} )}^{2}}{N - P} )}^{1 / 2}$ where, wᵢ is a weighting factor, N is the number of observations and P the number of lead-squares parameters being estimated.

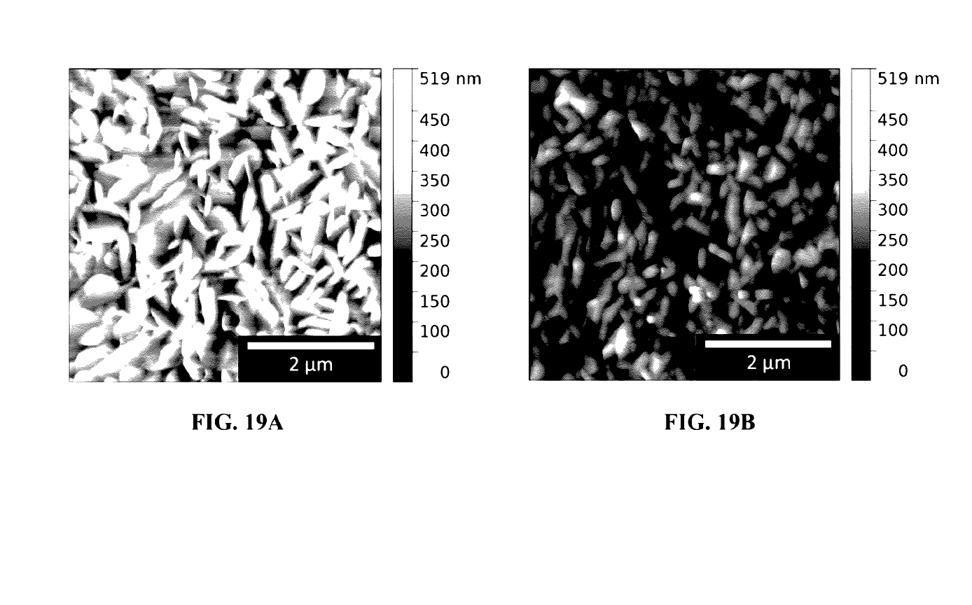

Additionally, the solution-assisted conversion method results in a microstructure as compact as those of some of the most efficient hybrid lead halide perovskites used in solar cells (FIGS. 5E and 5F). See, J.-H. Im, I.-H. Jang, N. Pellet, M. Gratzel, N.-G. Park, Nat. Nanotechnol. 2014, 9, 927-932, which is incorporated by reference in its entirety. The morphology is influenced by the concentration of the methylammonium iodide solution. Increasing the concentration from 6 mg·mL⁻¹ to 10 mg·mL⁻¹ to 40 mg·mL⁻¹ reduces the roughness from 76 nm rms (FIG. 5E) to 65 nm rms to 44 nm rms (FIGS. 19A-19B). Smoother films may be advantageous when using thin electron transport layers, such as <100 nm PCBM. But thick charge transport layers are often used in solar cells, especially perovskite solar cells, where MAPbI₃ with ˜720 nm cuboids have been used to achieve high efficiency. See, J.-H. Im, I.-H. Jang, N. Pellet, M. Gratzel, N.-G. Park, Nat. Nanotechnol. 2014, 9, 927-932, which is incorporated by reference in its entirety. Throughout the examples disclosed herein, MBI films synthesized with 6 mg·mL⁻¹ methylammonium iodide solution is consistently used.

In FIGS. 19A-19B, the resistivity values are comparable to those of intrinsic silicon and two orders of magnitude smaller than semi-insulating bulk GaAs at room temperature. See, M. Morvic, ASDAM 2000 Conf. Proceedings 2000, 327-330, which is incorporated by reference in its entirety. Hall effect measurements on the MBI yield a carrier concentration value on the order of 10¹⁰ cm⁻³, which is too low for accurate measurements with the system, but indicate that the films are either intrinsic (where the intrinsic carrier concentration (n) is calculated to be on the order of 10⁵ cm⁻³ for a 2 eV bandgap) or have a low carrier density. Intrinsic or low carrier concentration semiconductors are advantageous because they minimize recombination from doping states (see W. Shockley, W. T. Read, Phys. Rev. 1952, 87, 835-842, which is incorporated by reference in its entirety), and operating under high-injection maximizes the lifetime if recombination is defect-limited. It has been shown that silicon solar cells with lower doping levels can achieve higher efficiencies. See, D. Liu, T. L. Kelly, Nature Photon. 2013, 8, 133-138, which is incorporated by reference in its entirety. Low carrier concentration semiconductors can make efficient solar cells if the mobility and lifetime are sufficiently high to yield a long diffusion length exceeding the thickness of the active layer, such as the case with hybrid lead perovskites. See, S. D. Stranks, G. E. Eperon, G. Grancini, C. Menelaou, M. J. P. Alcocer, T. Leijtens, L. M. Herz, A. Petrozza, H. J. Snaith, Science 2013, 342, 341-345, which is incorporated by reference in its entirety. To perform the electrical measurements, MBI thin films were deposited on 15 mm by 15 mm glass substrates with a 7 nm MoOₓ and 100 nm Au contact at each corner. These were contacted by a gold probe each with an indium pad between the probe and contact. The probes were connected to a Keithley 4200 and measurements were performed in the Van der Pauw method. Hall effect measurements were performed with the sample held in a magnet with the field controllably varied from −1.5 T to 1.5 T.

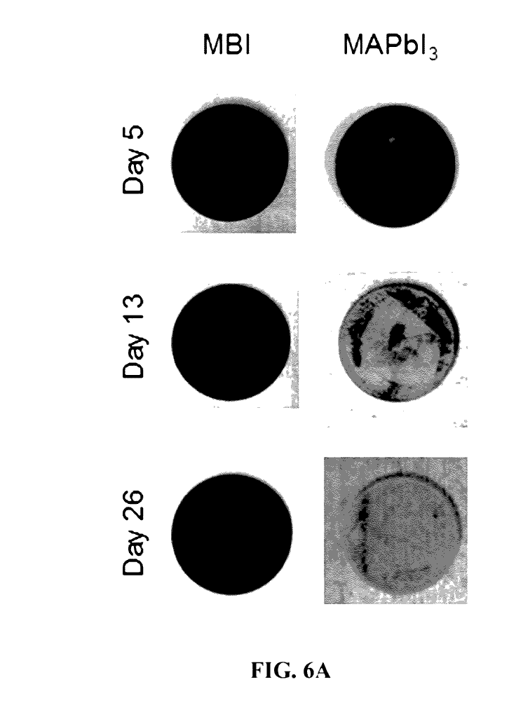

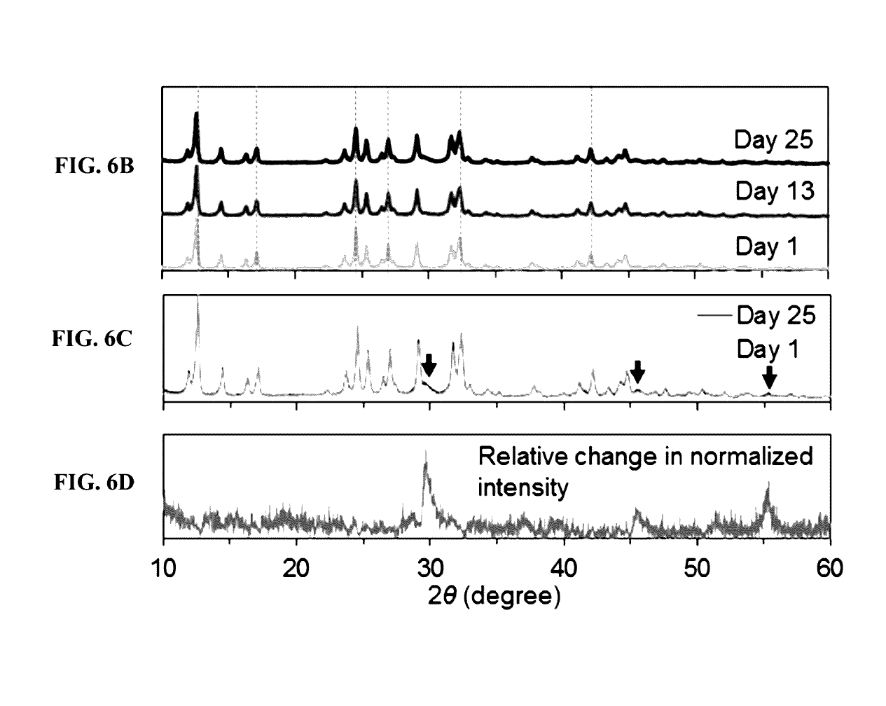

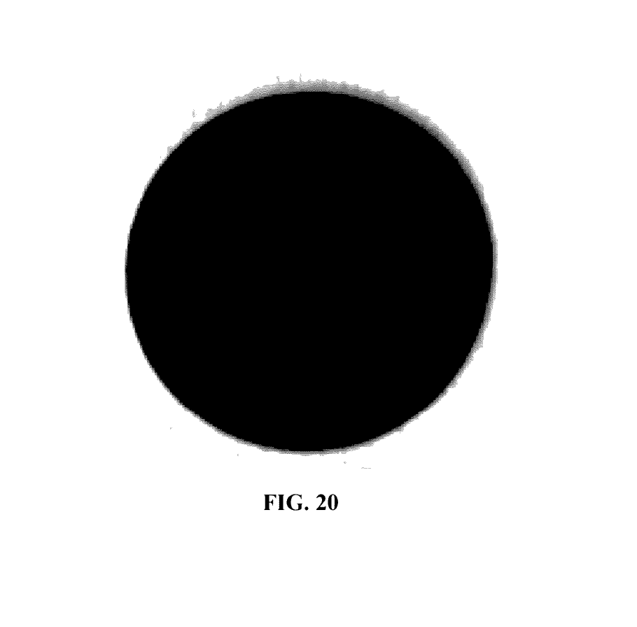

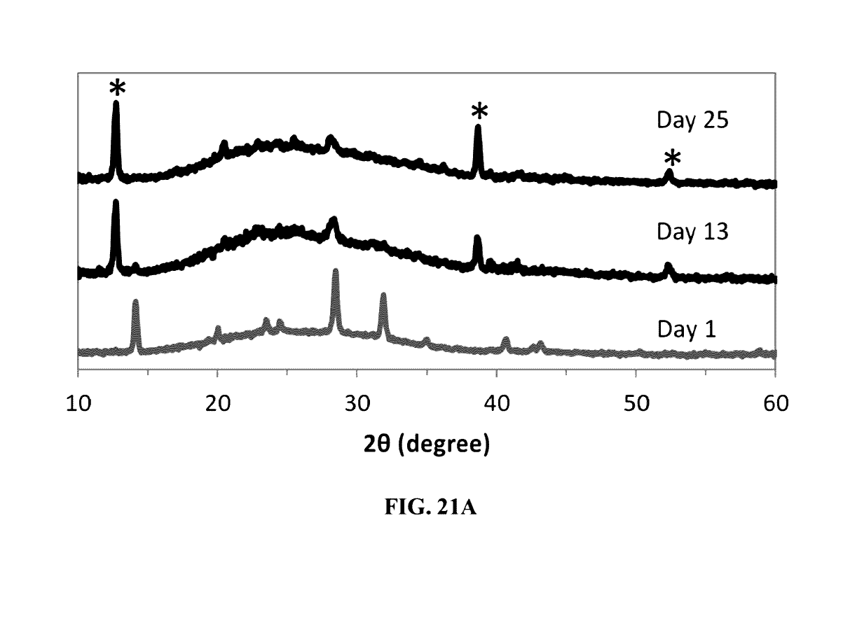

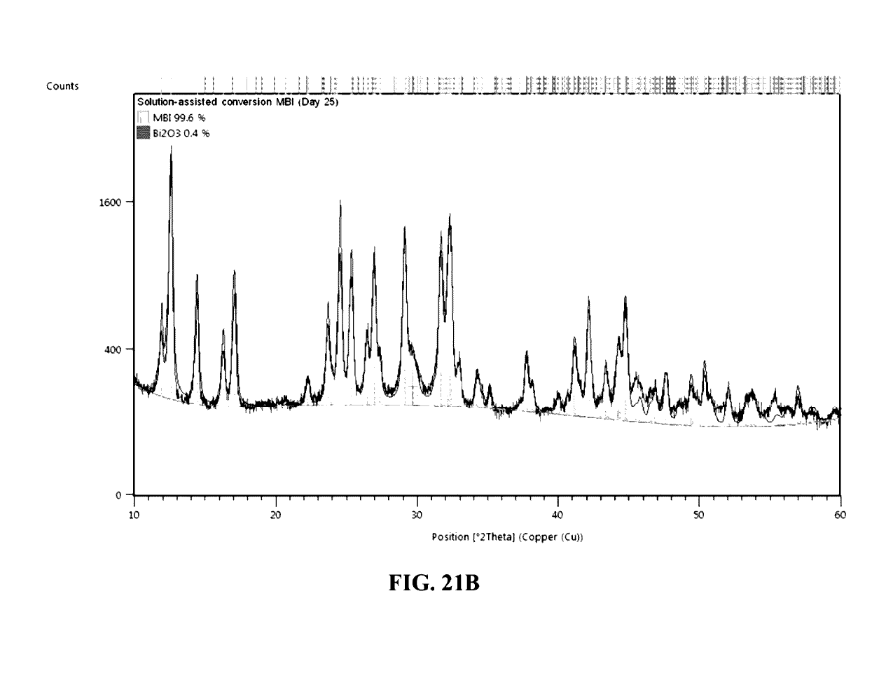

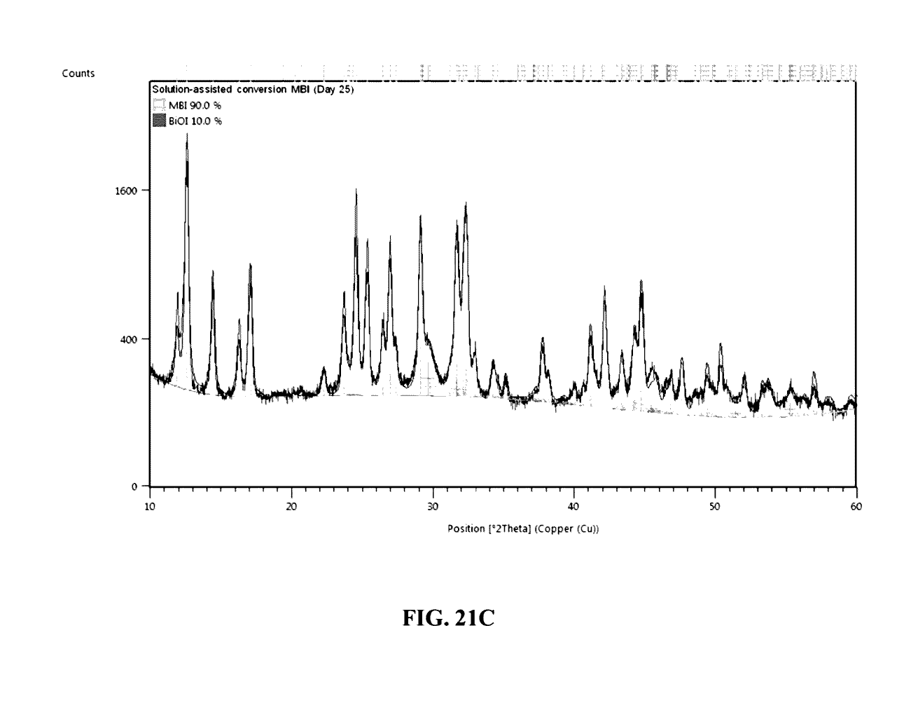

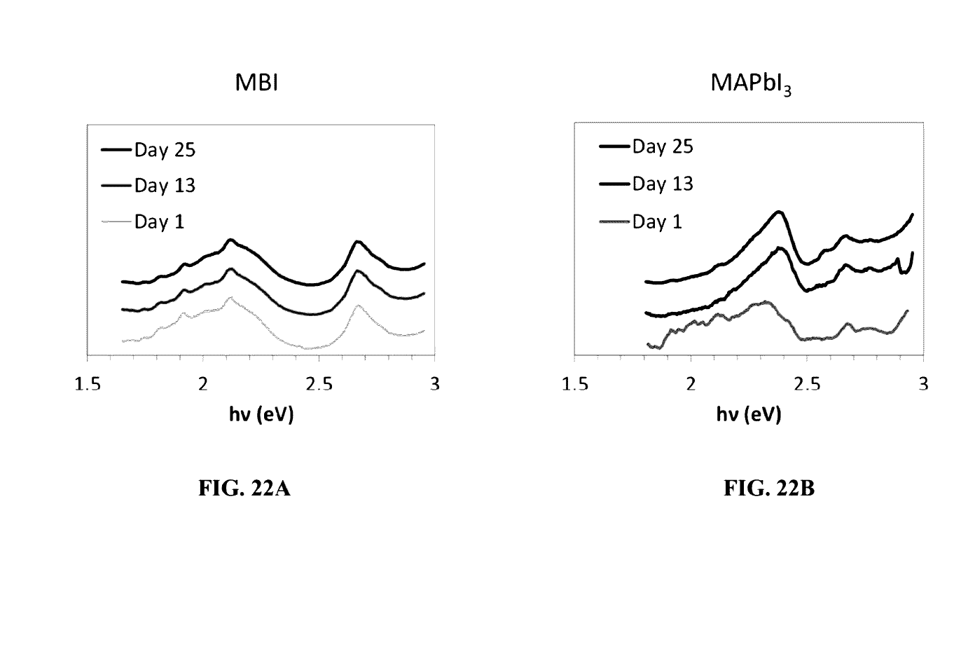

The air-stability of MBI was compared to MAPbI₃ by exposing both films to ambient air ((61±4)% relative humidity, and (21.8±0.7° C. temperature). MAPbI₃ changes from brown to yellow after 5 days (FIG. 6A). By contrast, MBI maintains the same visual appearance after 13 days (FIGS. 6A and 20), only becoming slightly brighter after 26 days. X-ray diffraction measurements (FIG. 6B) show that the diffraction pattern of MBI remains mostly unchanged. MAPbI₃, on the other hand, forms PbI₂ peaks that become more pronounced over time (FIG. 21A), in agreement with previous work. See, I. C. Smith, E. T. Hoke, D. Solis-Ibarra, M. D. McGehee, H. I. Karunadasa, Angew. Chem. Int. Ed. 2014, 53, 11232-11235; Angew. Chem. 2014, 126, 11414-11417, and D. H. Cao, C. C. Stoumpos, O. K. Farha, J. T. Hupp, M. G. Kanatzidis, J. Am. Chem. Soc. 2015, 137, 7843-7850, each of which is incorporated by reference in its entirety. The small changes to the diffraction pattern of MBI after 25 days of continuous air exposure are emphasized in FIGS. 6B-6D. These are most prominent next to the 29° 2θ peak. Through Rietveld refinement, these changes can be accounted for by the presence of a small quantity of either Bi₂O₃ or BiOI, which may form on the surface of MBI (FIGS. 21B and 21C). By contrast, most of the MAPbI₃ transforms to PbI₂ after 25 days, based on the intensity of the peaks from PbI₂ vs. MAPbI₃ in FIG. 21A. Rietveld refinement was used, but the diffraction patterns are obtained by grazing incidence XRD to avoid amorphous broadening from the substrate. Since the peak intensities are not the same as from a θ-2θ scan, the fits are reasonable. The extra diffraction peaks could be either accounted for by Bi₂O₃ (0.4%) or BiOI (10%), with the latter giving a better fit. These results suggest that MBI is more phase stable than MAPbI₃ under the testing conditions and forms a thin surface phase after air exposure instead of degrading to BiI₃. These are further supported by spectral PL measurements in FIGS. 22A-22B ((61±4)% relative humidity and (21.8±0.7° C. temperature). The measurements in FIGS. 22A-22B show that while MBI was unchanged over the measurement period, MAPbI₃ exhibited more pronounced emission and absorption at 2.4 eV, which corresponds to the bandgap of PbI₂. See, D. Liu, T. L. Kelly, Nature Photon. 2013, 8, 133-138, which is incorporated by reference in its entirety.

To investigate the cause of the higher ambient bulk stability of MBI, thermogravimetric analysis (TGA) was performed on MBI and MAPbI₃ powders in an inert atmosphere (FIG. 23A). From 250° C., MBI has a mass loss of 5 to 6%, which is accounted for by the vaporization of methylamine, which contributes to 5.6% of the mass of MBI. Another potential decomposition product is HI (see A. Dualeh, P. Gao, S. Il Seok, M. K. Nazeeruddin, M. Gratzel, Chem. Mater. 2014, 26, 6160-6164, which is incorporated by reference in its entirety), but this would only lead to a 23% mass loss. The large mass loss at 320° C. would therefore have partially been due to the vaporization of BiI₃, with there being negligible mass transfer resistance from the hole in the lid of the TGA crucible. There is an initial mass loss between 250° C. and 300° C., which is consistent with the vaporization of methylamine. There is a larger mass loss at 350° C. for MBI and 400° C. for MAPbI₃, which is unaccounted for by the vaporization of only HI (FIGS. 23A-23F). See, A. Dualeh, P. Gao, S. Il Seok, M. K. Nazeeruddin, M. Gratzel, Chem. Mater. 2014, 26, 6160-6164, which is incorporated by reference in its entirety. This suggests that BiI₃ and PbI₂ are being sublimed. BiI₃ has a higher sublimation vapor pressure than PbI₂ (2.1 kPa vs. ˜1 Pa at 350° C.) (see, J. H. Kim, S. Blairs, J. Chem. Thermodyn. 1990, 22, 803-814, and “Vapor Pressure Chart”, Luxel Corporation, can be found under http://luxel.com/, 2013, each of which is incorporated by reference in its entirety), in agreement with the second mass loss of MBI occurring at a lower temperature. MBI is therefore not more thermally stable than MAPbI₃ in an inert atmosphere. However, the temperatures at which these materials start to decompose are significantly higher than in standard testing of solar cells (85° C.). See, S. D. Stranks, H. J. Snaith, Nat. Nanotechnol. 2015, 10, 391-402, which is incorporated by reference in its entirety. Decomposition in a dry environment above 200° C. does not preclude the use of these materials in photovoltaics.

To reconcile the ambient and thermal phase stability measurements of MBI, X-ray photoelectron spectroscopy (XPS) measurements were performed (FIGS. 23B-23F). All O 1s is spectra of MBI and MAPbI₃ can be fit with a 533 eV binding energy peak, corresponding to adsorbed surface species. See, J. F. Moulder, W. F. Stickle, P. E. Sobol, K. D. Bomben, “Handbook of X-Ray Photoelectron Spectroscopy”, Perkin-Elmer Corporation, Minnesota, USA, 1992, which is incorporated by reference in its entirety. A peak at 530.5 eV, corresponding to O—Bi, can be fit to the surface O 1s is spectrum of MBI. This peak disappears after ion etching, indicating that O—Bi only occurred on the surface.

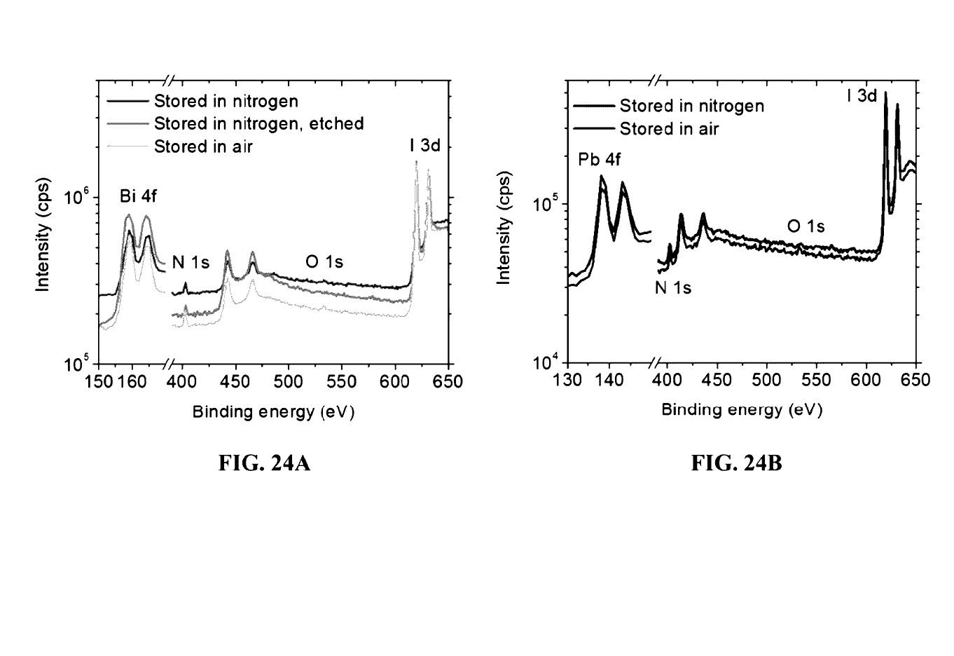

A comparison between films stored in nitrogen (and only exposed to air during transfer to the sample chamber) with films stored in air for a day is given in FIGS. 24A-24B. The solution-assisted conversion MBI film stored in nitrogen was also ion-etched by the XPS instrument to measure below the surface layer. The binding energy of the Bi 4f_{7/2} peak was 159 eV, which can be attributed to both Bi—O and Bi—I bonds.

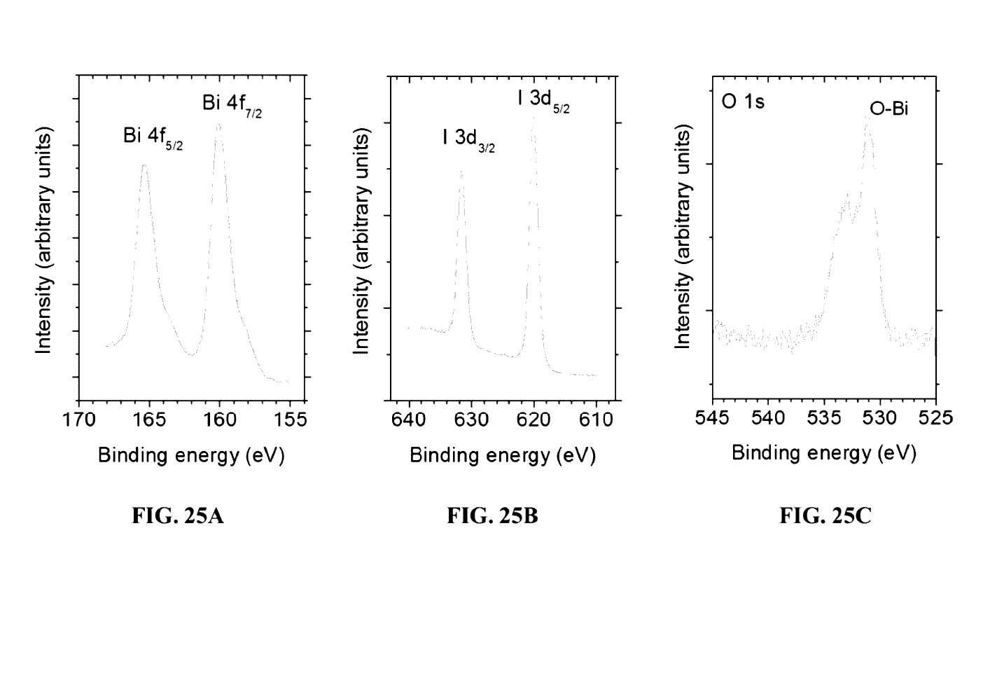

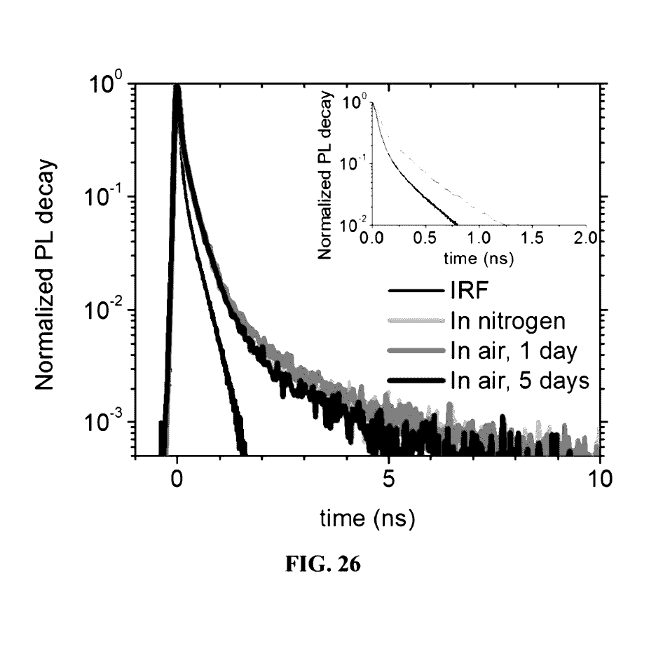

The surface O—Bi peak becomes more pronounced after a month of air exposure (FIG. 25C). In contrast to MBI exposed to air for a day or less, the lower binding energy O 1s is peak attributed to O—Bi has a higher intensity than the higher energy peak attributed to adsorbed surface species. XPS measurements therefore indicate that MBI forms a surface oxygen-based species, consistent with the XRD results. The MAPbI₃ O 1s is spectra exhibit no peak at ˜530 eV corresponding to lead oxides. By evaluating the Gibbs free energies of formation (Table 3), it was found that while the formation of Bi₂O₃ or BiOI are more favorable than BiI₃, the formation of PbO is not significantly more favorable than PbI₂. XPS measurements and thermodynamic considerations therefore indicate that MBI preferentially forms Bi₂O₃ or BiOI instead of degrading to BiI₃. By contrast, MAPbI₃ tends to decompose to PbI₂ rather than forming a protective oxide. PL decay measurements also indicate that the formation of the surface layer on MBI does not increase the surface recombination rate (FIG. 26). FIG. 26 inset magnifies the initial PL decay region of the three traces. The instrument response function (IRF) of the TCSPC system at 630 nm (obtained from the supplier) is also shown. 630 nm is the wavelength is closest to the emission from the sample around 600 nm.

TABLE 3
Gibbs free energies of formation (ΔG_{ƒ}⁰) of relevant species, normalized
to the molarity of the heavy metal cation (i.e., Bi³⁺ or Pb²⁺). *

| | ΔG_{ƒ}⁰ |
|---|---|
| Compound | ΔG_{f}⁰(kJ · mol⁻¹) |
| BiI₃ | −175.3 |
| ½ Bi₂O₃ | −246.9 |
| PbI₂ | −173.6 |
| PbO | −187.9 |

*The ΔG_{ƒ}⁰ ΔG_{f}⁰ of BiOI is not available from this reference. However, it is known that BiI₃ reacts with water to produce BiOI and HI (with kinetic constraints) (see, W. N. Haynes, T. J. Bruno, D. R. Lide, Eds., Handbook of chemistry and physics, CRC Press, Taylor And Francis, Boca Raton, FL, 2015, pp. 4-42, and P. Kwolek, K. Szacilowski, Electrochim. Acta 2013, 104, 448-453, each which is incorporated by reference in its entirety), which suggests that BiOI has a larger absolute Gibbs free energies of formation under the given reaction conditions than BiI₃.

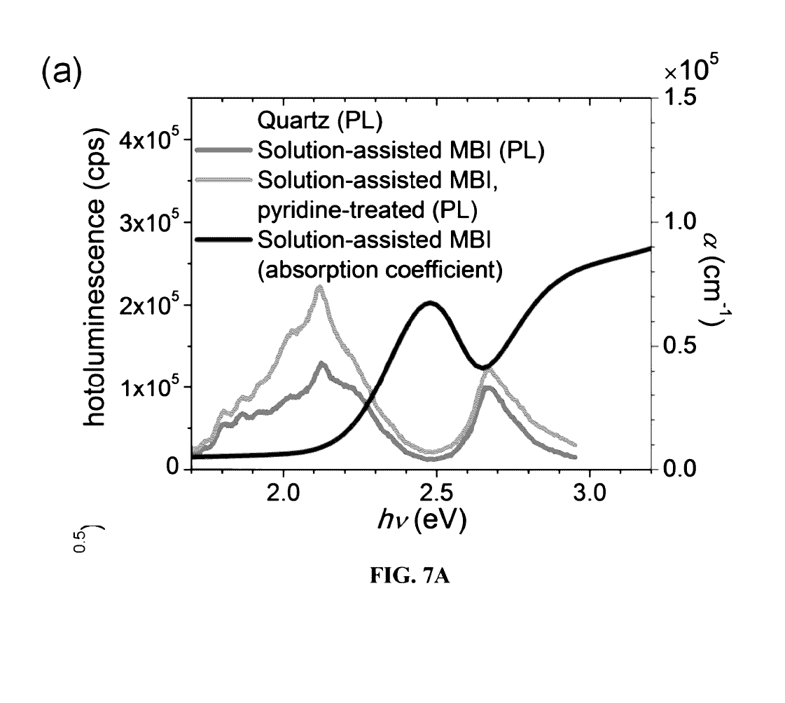

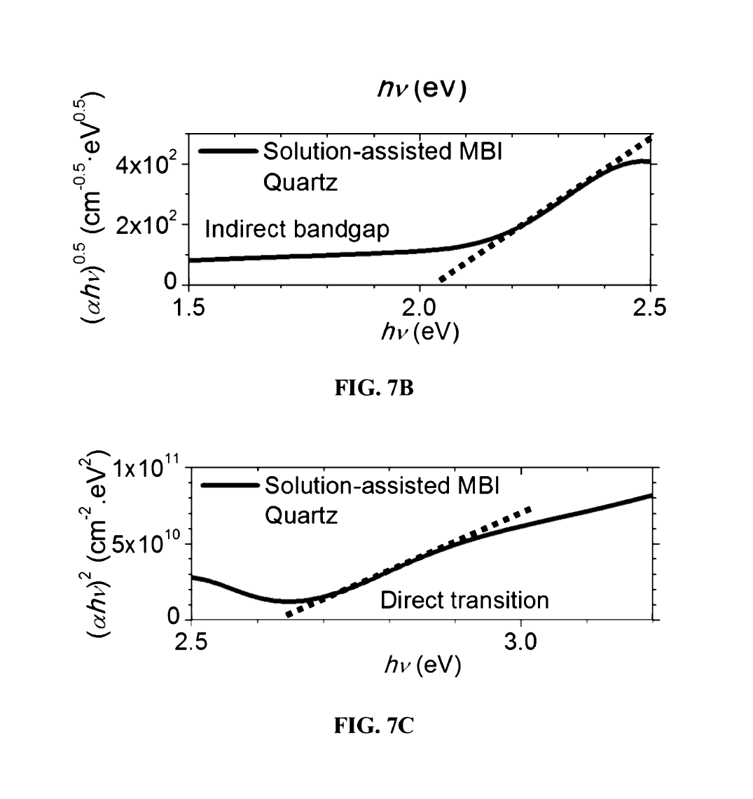

The potential of MBI was assessed as a photovoltaic absorber by analyzing its optoelectronic properties and lifetime. The absorption spectrum shows that MBI has two onsets of absorption (FIGS. 7A and 16A-16B). This is consistent with the split density of states in the conduction band found from density functional theory (DFT) calculations (FIG. 17A). DFT does not calculate the absolute band positions or bandgap. Instead it is useful to qualitatively determine the electronic structure and nature of band transitions. The DFT calculations show that the bandgap is indirect from the zero-dipole matrix element. Using this information, the indirect bandgap was measured to be 2.04 eV (FIG. 7B). An absorber with a bandgap of 2.04 eV and strong optical absorption coefficient above 1.1 eV is well-suited for the top cell of a tandem device. See, S. S. Wilson, J. P. Bosco, Y. Tolstova, D. O. Scanlon, G. W. Watson, H. A. Atwater, Energy Environ. Sci. 2014, 7, 3606-3610, which is incorporated by reference in its entirety. MBI has absorption coefficients approaching 10⁵ cm⁻¹ in the visible light range for the 485 nm thick films (FIG. 7A). This indicates that 99% light absorption can be achieved with <1 μm thick MBI for wavelengths 500 nm or shorter, which is suitable for a top tandem absorber material. In the optical measurements, light scattering was accounted for from the film by measuring the reflectance as well as the transmittance, and by performing all measurements inside an integrating sphere (see Experimental Section).

MBI exhibits PL at room temperature, as shown in FIG. 7A. This indicates that at least a fraction of charge carriers are recombining radiatively, which is essential for high open-circuit voltages and efficiencies. The PL spectrum shows a shoulder at 2 eV (corresponding to the indirect bandgap) and a more intense peak at 2.1 eV. DFT calculations show that MBI has a direct transition approximately 0.1 eV above the indirect bandgap. If the indirect bandgap is 2.04 eV, then the strong PL emission at 2.1 eV (FIG. 7A) corresponds to the direct transition. The PL spectrum also shows a peak at 2.67 eV. To determine the nature of this peak, a Tauc plot was constructed from the second onset of absorption of MBI. This transition may be direct and allowed. The corresponding Tauc plot yields a transition energy of 2.63 eV (FIG. 7C), which closely agrees with the value from the spectral PL measurements (FIG. 7A). This PL peak is deduced to correspond to radiative recombination from a higher-energy state in the conduction band. This transition is most likely from the higher-energy edge of the split conduction band density of states (FIGS. 7A-7C).

The PL decay was measured by time correlated single-photon counting (TCSPC) spectroscopy. The time for the PL to decay to e⁻¹ of the peak value can be taken as a characteristic PL decay time. See, S. D. Stranks, G. E. Eperon, G. Grancini, C. Menelaou, M. J. P. Alcocer, T. Leijtens, L. M. Herz, A. Petrozza, H. J. Snaith, Science 2013, 342, 341-345, which is incorporated by reference in its entirety. It cannot be categorically determined whether the PL decay at room temperature corresponds to an exciton or free charge carrier lifetime without knowing the exciton binding energy. This can be difficult to accurately measure. See, A. Miyata, A. Mitioglu, P. Plochocka, O. Portugall, J. T.-W. Wang, S. D. Stranks, H. J. Snaith, R. J. Nicholas, Nat. Phys. 2015, 11, 582-587, which is incorporated by reference in its entirety. Nevertheless, the PL decay provides a measure of the recombination time of the photo-excited species.

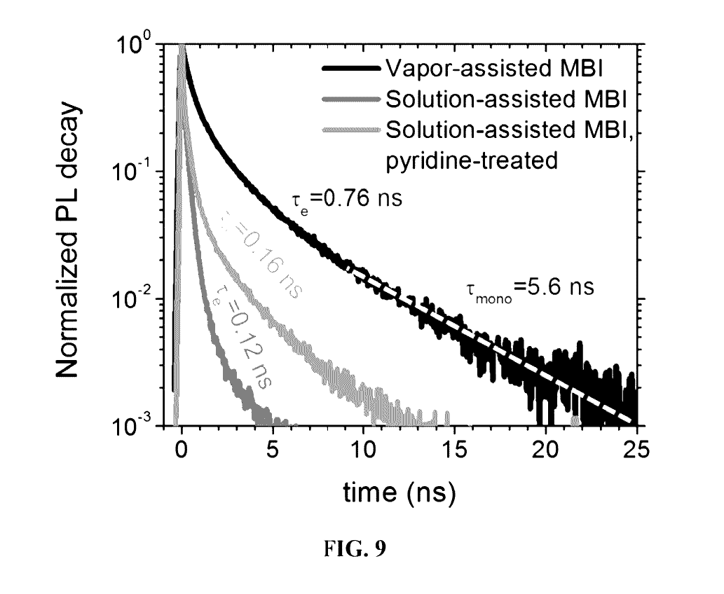

The PL decay time of solution-assisted conversion MBI can be increased by treating it with pyridine vapor (FIG. 9). Pyridine treatment has been shown to increase the lifetime of hybrid lead perovskites and it is thought that this occurs due to the lone electron pair on the nitrogen atom in pyridine passivating under-coordinated Pb²⁺ in the perovskite. See, N. K. Noel, A. Abate, S. D. Stranks, E. S. Parrott, V. M. Burlakov, A. Goriely, H. J. Snaith, ACS Nano 2014, 8, 9815-9821, which is incorporated by reference in its entirety. A similar process may occur with under-coordinated bismuth ions on the surface of MBI.

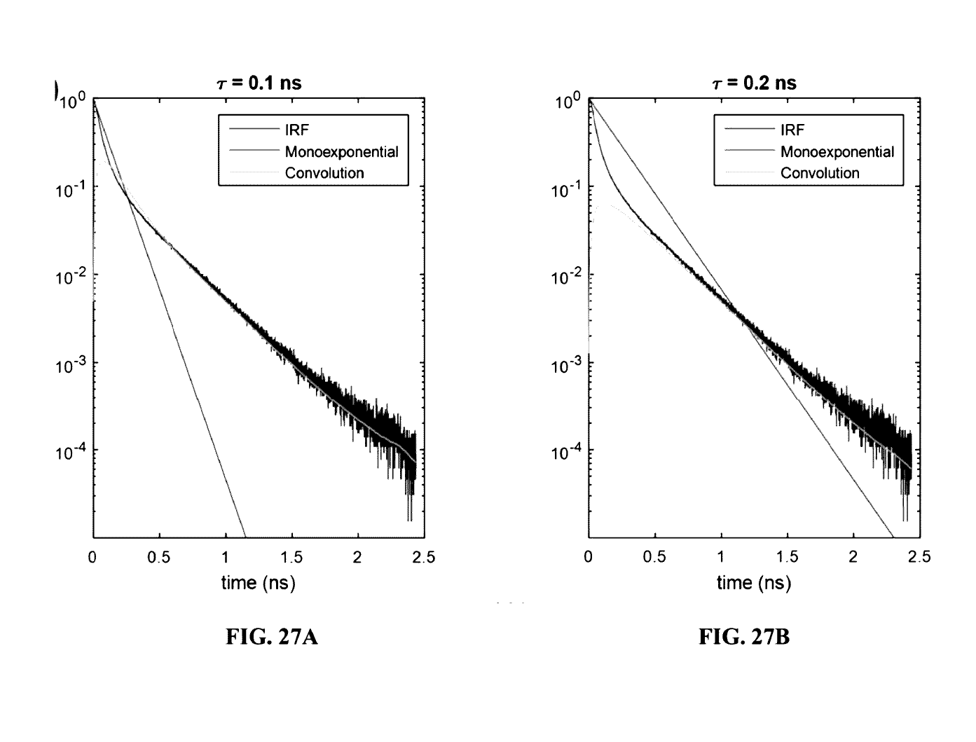

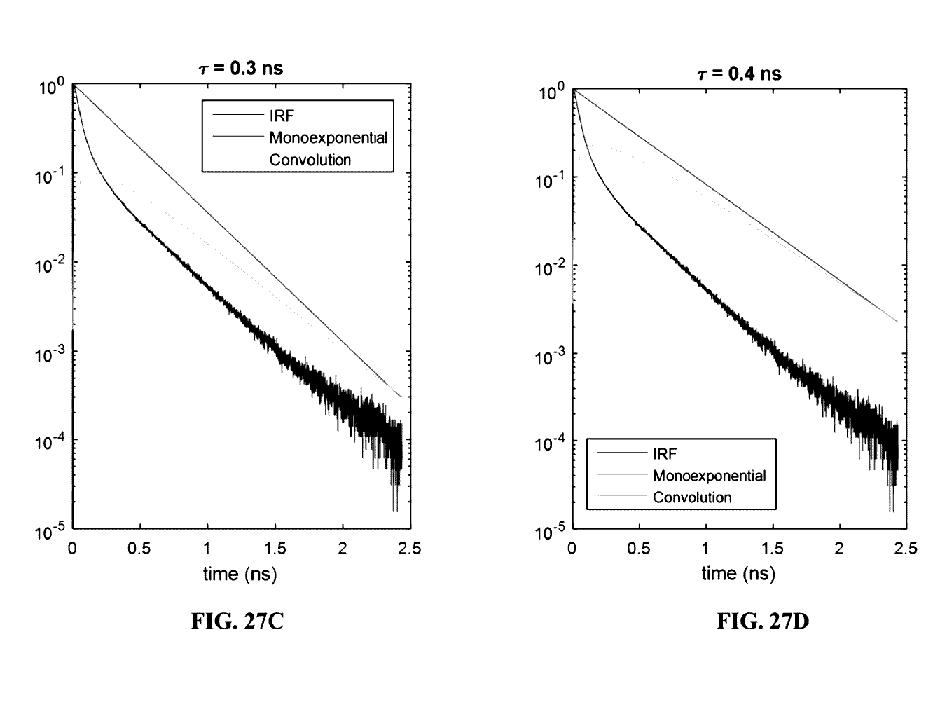

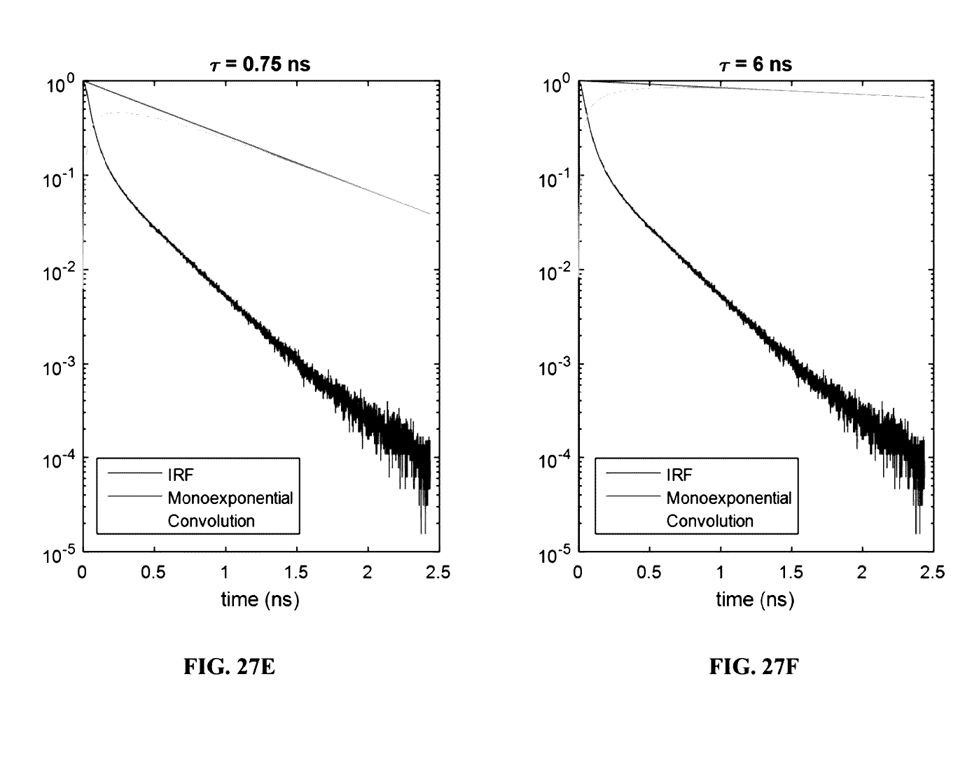

Further modifications to the fabrication of MBI thin films lead to increases in the PL decay time. By spin-casting the MBI at 150° C. instead of room temperature and by introducing methylammonium iodide as a vapor at 150° C. instead of via solution, the PL decay time increases to 760 ps (FIG. 9). This lifetime is sufficiently long to not be significantly affected by the instrument response function (FIGS. 27A-27F). The convolution plots (FIGS. 27A-27F) show that the tail in the IRF dominates the measured response when the monoexponential decay time constant is below 0.3 ns. However, for decays with time constants longer than 0.4 ns, the convolved function matches that of the monoexponential decay after 0.75 to 2 ns. The initial decay of the IRF is fast and the τₑ value is 80 ps. Thus, although the solution-assisted conversion films have τₑ values <0.3 ns, their PL decays are longer than the IRF. This can be seen from FIG. 26.

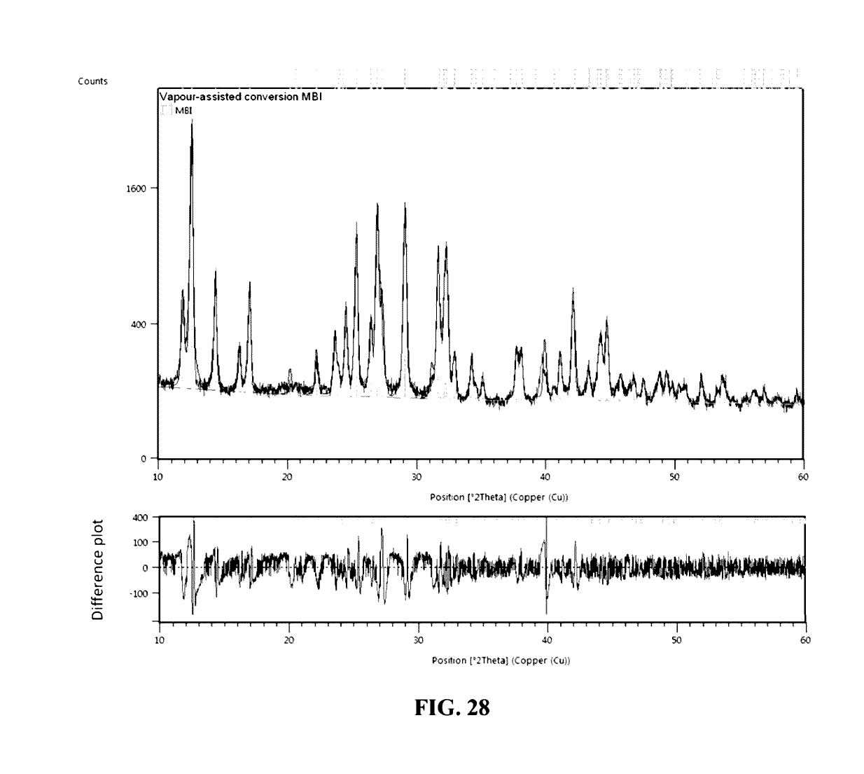

This method is termed vapor-assisted conversion, and XRD measurements show that the full width half maximum (FWHM) of the fitted diffraction peaks is ˜20% smaller than that of solution-assisted conversion MBI (FIGS. 18 and 28). This indicates that larger crystallites are present. No secondary phases or amorphous material was found in the vapor-assisted conversion MBI thin films from XRD (FIG. 28). In FIG. 28, the FWHM of the fitted peaks is 0.232°. This vapor-assisted conversion method is related to the vapor-assisted solution-processing and hot-casting methods reported for hybrid lead perovskites. See, Q. Chen, H. Zhou, Z. Hong, S. Luo, H.-S. Duan, H.-H. Wang, Y. Liu, G. Li, Y. Yang, J. Am. Chem. Soc. 2013, 136, 622-625; b) R. Sheng, A. Ho-Baillie, S. Huang, S. Chen, X. Wen, X. Hao, M. A. Green, J. Phys. Chem. C 2015, 119, 3545-3549; c) W. Nie, H. Tsai, R. Asadpour, J.-C. Blancon, A. J. Neukirch, G. Gupta, J. J. Crochet, M. Chhowalla, S. Tretiak, M. A. Alam, H.-L. Wang, A. D. Mohite, Science 2015, 347, 522-525, each of which is incorporated by reference in its entirety.

Some of the most efficient thin film solar absorbers have lifetimes approaching 1 μs. See, S. D. Stranks, H. J. Snaith, Nat. Nanotechnol. 2015, 10, 391-402, which is incorporated by reference in its entirety. But even lifetimes measured to be <1 ns have been reported to yield efficiencies close to 10% (see B. Shin, K. Wang, O. Gunawan, K. B. Reuter, S. J. Chey, N. a Bojarczuk, T. Todorov, B. Mitzi, S. Guha, Proc. 37th IEEE Photovolt. Spec. Conf. 2011, 2510-2514, L. Kranz, C. Gretener, J. Perrenoud, D. Jaeger, S. S. A. Gerstl, R. Schmitt, S. Buecheler, A. N. Tiwari, Adv. Energy Mater. 2014, 4, 1301400, and H. R. Mountinho, R. G. Dhere, M. M. Al-Jassim, C. Bailif, D. H. Levi, A. B. Swartzlander, M. R. Y. Houng, L. L. Kazmerski, Proc. 28th IEEE Photovolt. Spec. Conf. 2000, 28, 646-649, each of which is incorporated by reference in its entirety), which has proven to be a benchmark minimum efficiency for new solar absorbers to gain widespread attention. See, J. Turner, in Carbon Management: Implications for R&D in the Chemical Sciences and Technology (A Workshop Report to the Chemical Sciences Roundtable), National Academy of Sciences, Washington, D C, 2001, pp. 111-126, which is incorporated by reference in its entirety. It has also traditionally been challenging to achieve charge carrier lifetimes above 0.5 ns during the early stages of development for new thin film solar absorbers before giving exhaustive consideration to the passivation steps to mitigate the presence of non-radiative decay pathways. See, N. Mangan, R. E. Brandt, V. Steinmann, R. Jaramillo, C. Yang, J. R. Poindexter, R. Chakraborty, H. H. Park, X. Zhao, R. G. Gordon, T. Buonassisi, J. Appl. Phys. 2015, 118, 115102, M. Buffière, G. Brammertz, A.-A. El Mel, N. Lenaers, Y. Ren, A. E. Zaghi, Y. Mols, C. Koeble, J. Vleugels, M. Meuris, J. Poortmans, Proc. 30th IEEE Photovolt. Spec. Conf. 2013, 1941-1944, and A. Paracchino, J. C. Brauer, J. E. Moser, E. Thimsen, M. Graetzel, J. Phys. Chem. C 2012, 116, 7341-7350, each of which is incorporated by reference in its entirety. For example, Cu₂ZnSnSe₄ took a decade to increase from lifetimes of ˜100 ps to above 1 ns. See, D. B. Mitzi, O. Gunawan, T. K. Todorov, K. Wang, S. Guha, Sol. Energy Mater. Sol. Cells 2011, 95, 1421-1436, which is incorporated by reference in its entirety. Similarly, SnS solar cells have reached 4.38% efficiency (certified), but the lifetime has recently been estimated as only ˜100 ps. See, N. Mangan, R. E. Brandt, V. Steinmann, R. Jaramillo, C. Yang, J. R. Poindexter, R. Chakraborty, H. H. Park, X. Zhao, R. G. Gordon, T. Buonassisi, J. Appl. Phys. 2015, 118, 115102, which is incorporate by reference in its entirety. For the purposes of evaluating a new solar absorber, 1 ns can be considered as a first-pass threshold lifetime for determining whether the material is worth further exploration.

Demonstrating a PL decay time of >0.5 ns for MBI is a significant first step for a material newly investigated for photovoltaic applications. But the PL decay of vapor-assisted conversion MBI initially deviates from a monoexponential (FIG. 9), which may be due to the signal being dominated by surface recombination. This may result from the shallow absorption depth (115 nm) in the >400 nm thick film. Similarly, in CdTe, which also has a high absorption coefficient, it has been found that the PL decay is dominated by surface recombination, resulting in a measured lifetime two orders of magnitude shorter than the bulk lifetime. See, J. Ma, D. Kuciauskas, D. Albin, R. Bhattacharya, M. Reese, T. Barnes, J. V. Li, T. Gessert, S. H. Wei, Phys. Rev. Lett. 2013, 111, 067402, which is incorporated by reference in its entirety. For the vapor-assisted conversion MBI films, the PL decay tends towards a monoexponential after 10 ns, with a time constant of 5.6 ns (FIG. 9). Detailed and careful studies are needed to model the PL decay of MBI in order to decouple the influence of surface recombination and establish the mechanisms for recombination. But these are beyond the scope of this work. While the characteristic PL decay time of vapor-assisted conversion MBI is 0.76 ns, the bulk lifetime may be closer to 5.6 ns.

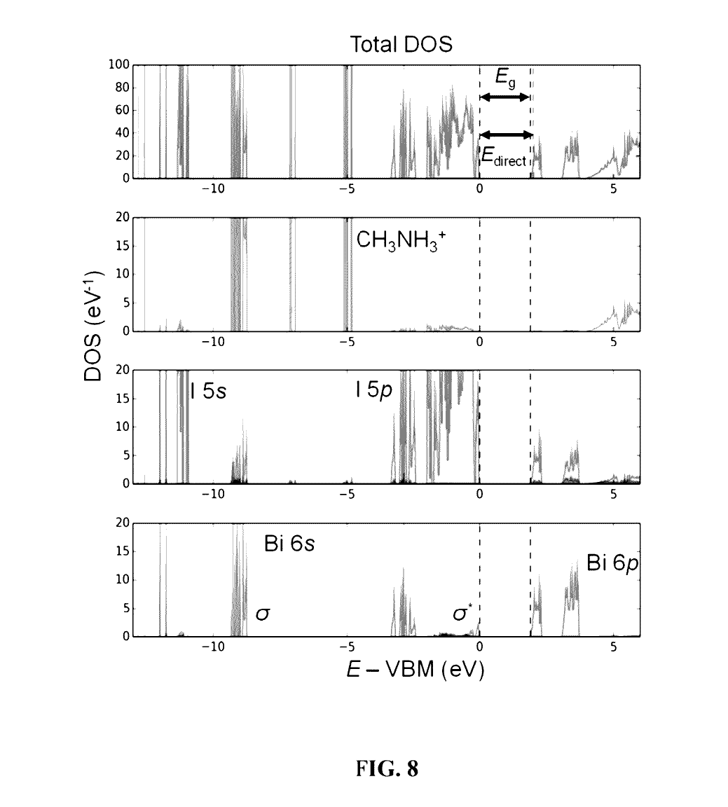

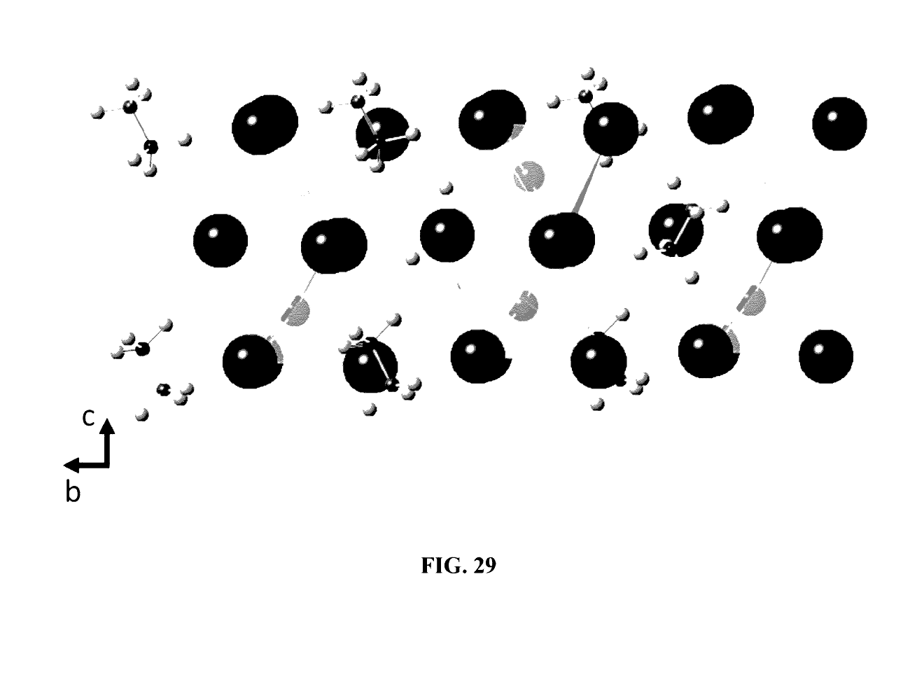

MBI has several features amenable to long charge carrier lifetimes that may be shared with other hybrid ternary bismuth halides. It contains the stable Bi³⁺ cation, which can lead to high dielectric constants due to a high Born effective charge and more disperse conduction band due to spin-orbit coupling. See, U.S. Provisional Application No. 62/141,662, and A. J. Lehner, D. H. Fabini, H. A. Evans, C.-A. Hébert, S. R. Smock, J. Hu, H. Wang, J. W. Zwanziger, M. L. Chabinyc, R. Seshadri, Chem. Mater. 2015, 9, 7137-7148, each of which is incorporated by reference in its entirety. MBI has partial antibonding orbital character at its valence band maximum (FIG. 8) due to interactions between the Bi 6s and I 5p orbitals, similar to the hybrid lead perovskites. See, U.S. Provisional Application No. 62/141,662, which is incorporated by reference in its entirety. Both a disperse conduction band and antibonding orbital contributions to the valence band maximum can improve the tolerance to intrinsic defects by leading to shallow point-defect states. See, U.S. Provisional Application No. 62/141,662, which is incorporated by reference in its entirety. MBI has adequate space for methylammonium cations to rotate within their Bi₂I₉³⁻ cages (FIG. 5B). From DFT calculations, it was found that the relaxed orientation of methylammonium cations is off-axis (FIG. 29). In FIG. 29, DFT calculations were used to consider all possible orientations of the methylammonium cations and construct full atomic relaxations. In the lowest energy orientation, the methylammonium cation is angled to the corners of the Bi₂I₉³⁻ cages, which is similar to that reported for MAPbI₃. See, A. M. A. Leguy, J. M. Frost, A. P. McMahon, V. G. Sakai, W. Kochelmann, C. Law, X. Li, F. Foglia, A. Walsh, B. C. O'Regan, J. Nelson, J. T. Cabral, P. R. F. Barnes, Nat. Commun. 2015, 6, 7124, which is incorporated by reference in its entirety. The results are verified by using the local density approximation to DFT, which provides a better description of the crystal structure of layered systems. The red ions are Bi³⁺, purple ions F, black atoms C, green atoms N and pink atoms H.

The energy of different configurations falls within ˜70 meV per methylammonium cation, which is relatively low. These suggest that the methylammonium cations may freely reorient themselves, similar to the MAPbI₃ system, where reorientation has been found to lead to electrostatic potential fluctuations that prolong charge carrier lifetimes. See, J. Ma, L. Wang, Nano Lett. 2015, 15, 248-253, which is incorporated by reference in its entirety. A heavy metal cation, orbital overlap between the Bi³⁺ and halide anion, and short alkylammonium cations arranged in Bi₂X₉³⁻ cages (where X⁻=halide anion) are common to other ternary hybrid bismuth halides. Compounds with iodide anions at least are expected to share the air-stability of MBI because the slow formation of a surface species is thermodynamically more favorable than decomposition to BiI₃. Many of these hybrid ternary bismuth halide compounds have not yet been explored for photovoltaic applications and these results suggest such investigations may be fruitful.

However, opportunities remain for further improvements with MBI. The PL quantum efficiency (PLQE) is measured up to 0.4% (vapor-assisted conversion film). While this PLQE is larger than the PLQE of some other indirect bandgap semiconductors (silicon has a PLQE of 0.004%) (see M. A. Green, J. Zhao, A. Wang, P. J. Reece, M. Gal, Nature 2001, 412, 805-808, which is incorporated by reference in its entirety), this suggests that non-radiative recombination pathways limit the lifetime of MBI. Identification and elimination of lifetime-limiting defects, such as impurities, has been shown to improve the carrier lifetime in other materials. See, K. Hitomi, T. Shoji, K. Ishii, J. Cryst. Growth 2013, 379, 93-98, and B. Saparov, F. Hong, J.-P. Sun, H.-S. Duan, W. Meng, S. Cameron, I. G. Hill, Y. Yan, D. B. Mitzi, Chem. Mater. 2015, 27, 5622-5632, each of which is incorporated by reference in its entirety.

In summary, guided by the method disclosed herein, MBI can be a photovoltaic absorber, as MBI merits show experimentally. MBI is lead-free and has higher air-stability than MAPbI₃, and as such overcomes the two main limitations of hybrid lead perovskites. Vapor processing, rather than solution processing, is shown to be the method that currently achieves longer PL decay times. Characteristic PL decay times was measured of at least 760 ps, with the bulk lifetime possibly closer to 5.6 ns. This work shows MBI to have promising materials properties for solar absorbers, and strongly motivates photovoltaic development.

### Experimental Section

### Thin Film Deposition

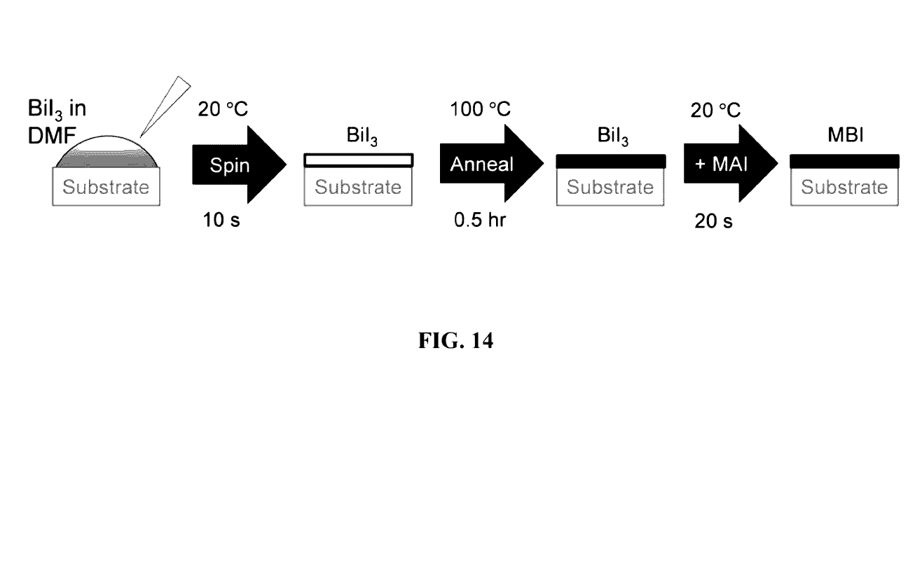

Solution-assisted conversion MBI was deposited onto both borosilicate glass and quartz (ESCO Optics) substrates. These substrates were sequentially cleaned ultrasonically in deionized water, acetone, ethanol and isopropanol for 5 min at 50° C. They were subsequently oxygen plasma cleaned for 10 min at −90 kPa (gauge). The solution of BiI₃ was prepared by dissolving 200 mg BiI₃ powder (99.999% purity from Alfa Aesar) in 0.5 mL N,N-Dimethylformamide (DMF, from Sigma-Aldrich). This was mixed ultrasonically for 1 hr before being filtered through a 0.2 μm PTFE syringe filter. Inside a nitrogen-filled glovebox, 10 μL of the filtered solution was spread over the substrate and spin-cast at 3000 rpm for 5 s, followed by 6000 rpm for 5 s. The BiI₃ film was dried for 30 min before being annealed at 100° C. for 30 min. Methylammonium iodide (from Luminescence Technology Corp.) was dissolved in anhydrous isopropanol (Sigma-Aldrich) with a concentration of 6 mg·mL⁻¹. 200 μL of methylammonium iodide solution was deposited onto the BiI₃ film for 60 s before spinning at 4000 rpm for 20 s. The MBI film was annealed at 100° C. for 1 hr. The synthesis steps are illustrated in FIG. 14.

To pyridine-treat MBI, anhydrous pyridine was dissolved in anhydrous chlorobenzene (both from Sigma-Aldrich) with a concentration of 10 vol. %. 1 mL of this solution was dispensed into a petri dish in air and the MBI sample suspended over the solution for 10 min.

For vapor-assisted conversion MBI, the substrates were the same as for solution-assisted conversion MBI and cleaned in the same way. These were heated at 150° C. for 15 min inside a nitrogen-filled glovebox. 20 μL BiI₃ solution, prepared in the same way as for solution-assisted conversion MBI, was heated above the 150° C. hotplate for 30 s before being dispensed to the substrate, which was immediately spun at 4000 rpm for 10 s. The hot-cast BiI₃ film was annealed at 100° C. The film was suspended over methylammonium iodide powder and heated at 150° C. for 4 hr under vacuum (−100 kPa gauge pressure). This was cooled to room temperature before taking out of the oven and cleaning with anhydrous isopropanol. The MBI film was annealed at 100° C. for 1 hr inside a nitrogen-filled glovebox.

Thin films of MAPbI₃ were prepared using the solvent engineering method described in detail elsewhere. See, M. Xiao, F. Huang, W. Huang, Y. Dkhissi, Y. Zhu, J. Etheridge, A. Gray-Weale, U. Bach, Y. B. Cheng, L. Spiccia, Angew. Chem. Int. Ed. 2014, 53, 9898-9903; Angew. Chem. 2014, 126, 10056-10061, and N. J. Jeon, J. H. Noh, Y. C. Kim, W. S. Yang, S. Ryu, S. Il Seok, Nat. Mater. 2014, 13, 897-903, each of which is incorporated by reference in its entirety. In brief, methylammonium iodide was synthesized and purified as described elsewhere. See, S. D. Stranks, G. E. Eperon, G. Grancini, C. Menelaou, M. J. P. Alcocer, T. Leijtens, L. M. Herz, A. Petrozza, H. J. Snaith, Science 2013, 342, 341-345, which is incorporated by reference in its entirety. Equimolar (0.75 M) solutions of methylammonium iodide and PbI₂ (Alfa Aesar, 99.9985% purity) were prepared in DMF and spin-cast at 5000 rpm for 35 s. After 6 s, 150 μL chlorobenzene was deposited on the spinning sample in order to induce rapid crystallization. After spinning, the samples were immediately heated at 100° C. for 10 minutes.

### Powder Fabrication

BiI₃ powder (10 mg) was dispensed onto a small petri dish and 1 mg of methylammonium iodide powder was dispensed around it. This was covered with a petri dish and heated under vacuum (−100 kPa gauge pressure) at 150° C. for 4 hr.

### Characterization

Powder X-ray diffraction was performed with a PANanalytical X'Pert PRO XRPD instrument using Cu K_{α} radiation (1.5406 Å wavelength). The powder sample was mounted onto off-cut silicon (PANanlytical, miscut from (510) plane), which introduces no background to the diffraction pattern. X-ray diffraction of MBI was performed by grazing incident X-ray diffraction (GIXD) using a Rigaku SmartLab using Cu K_{α} radiation (1.5406 Å wavelength) and an incident angle of 0.5°. The methylammonium lead iodide perovskite was characterized by X-ray diffraction using a General Area Detector Diffraction System using Cu K_{α} radiation (1.5406 Å wavelength) and a two-dimensional area detector, which was integrated to give a θ-2θ scan.

Atomic force microscopy was performed using an Agilent 5500 scanning probe microscope. The tip used was composed of Sb-doped Si with a resonant frequency of 319-378 kHz (Bruker). Scanning electron microscopy was performed using a Zeiss NVision 40, operated at 2 kV and using a tilt angle of 54°. The MBI thin film was coated with approximately 5 nm of sputtered Au to avoid charging during imaging. Absorption measurements were performed using a PerkinElmer Lambda 950 UV-VIS-NIR spectrophotometer. The samples were mounted on the wall of an integrating sphere and the instrument was calibrated with 0% and 100% reflectance (R) and transmittance (T) before measuring the samples. The absorption coefficient (α) of MBI was calculated from transmittance, reflectance and film thickness (d) using the following equation,

$$α = \frac{- ln ( \frac{T}{1 - R} )}{d} \qquad ( S1 )$$

ransmission electron microscopy specimens were fabricated via Focused Ion Beam (FIB) liftout of cross-sections from a thin film. Specimens were first protected from ion bombardment by deposition of a 30 nm thick layer of gold using an EMS 300T Dual-Head sputter coater. A Zeiss NVision 40 Dual Beam FIB/SEM using Ga ions with an acceleration voltage of 30 kV and equipped with an OmniProbe micromanipulator was used to extract cross-sectional lamellae from the film. These lamellae were then reduced to a thickness of ˜50 nm using the FIB. Specimens were imaged on a JEOL 2010F Analytical TEM in bright field mode, with an acceleration voltage of 200 kV.

Steady-state photoluminescence (PL) spectra were acquired using a FluoroMax-3 (Horiba Scientific), using an excitation wavelength of 360 nm, and a slit size of 5 nm for the incident beam and detector. 400 nm and 420 nm wavelength Schott glass longpass filters were added in series front of the detector to suppress higher-order diffraction peaks from the excitation beam. Time correlated single photon counting (TCSPC) measurements were performed with a 405 nm wavelength excitation laser (PicoQuant Pulsed Diode Laser, part number: LDG-P-C-405, ˜100 μm diameter spot size, ˜60 ps FWHM pulses at 10 MHz) and single photon counting avalanche photodiode (Micro Photon Devices $PD-100-C0C, ˜50 ps timing resolution). A PicoQuant PicoHarp 300 was used to record the arrival time of photons. A dielectric bandpass filter centered at 405 nm wavelength (Thorlabs FBH405-10) was placed in the optical path of the incident beam. 420 nm and 600 nm wavelength longpass dielectric filters (Chroma Technology Corp.) were used in series in front of the detector.

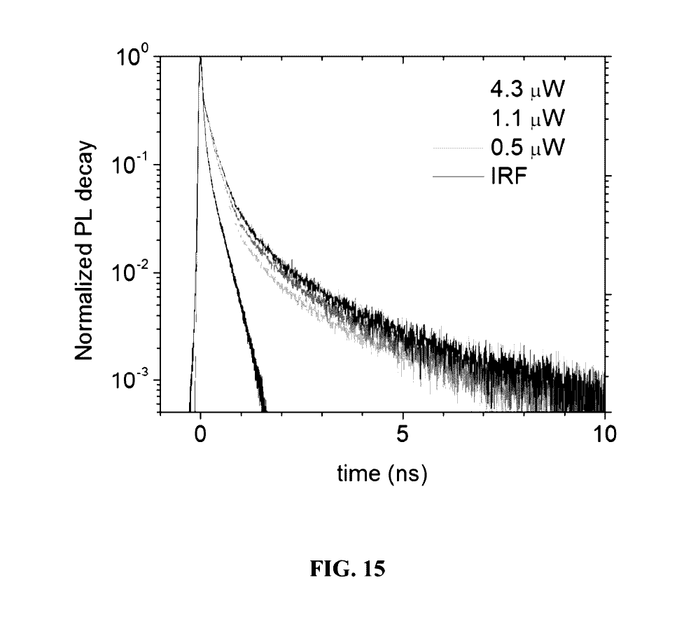

The temporal instrument response function (IRF) of this system has a FWHM of ˜80 ps, as expected from the addition of the detector response and laser pulse duration in quadrature. However, the IRF has a somewhat longer tail, as can be seen from the measured IRF for 635 nm excitation obtained from the supplier (FIG. 15). In FIG. 15, time-correlated single photon counting spectroscopy was performed using 0.5 μW to 4.3 μW power excitation with a 405 nm wavelength laser. No significant change in the PL decay time was found over this intensity range. The instrument response function (IRF) was obtained from the supplier. See, “Photon Counting Detectors,” can be found under www.picoquant.com/products/category/photon-counting-detectors/pdm-series-single-photon-avalanche-diodes#custom1, 2015, which is incorporated by reference in its entirety. PL quantum efficiency measurements were performed using an integrating sphere (Labsphere RTC-060-SF). A 405 nm wavelength diode laser was used as the excitation source with a 535 nm longpass Schott glass filter. The fluorescence from the filter itself was measured and subtracted. The system IRF was unable to be measured directly from laser scatter, as the detector has a significantly slower (˜215 ps) response at the 405 nm excitation wavelength. However, the IRF is largely wavelength-independent between excitation wavelengths of 470 and 630 nm, so the manufacturer's IRF is considered to accurately reflect the performance at the expected emission wavelengths (around 600 nm). A comparison between the measured dynamics and this IRF is shown in FIG. 15.

Lastly, except where noted explicitly, the laser power used was between 1 μW and 5 μW for all experiments. Fluence-dependent measurements of MBI in FIG. 15 show that there is little change in the PL decay dynamics in this regime.

PL quantum efficiency measurements were performed using an integrating sphere (Labsphere RTC-060-SF). A 405 nm wavelength diode laser was used as the excitation source with a 535 nm longpass Schott glass filter. The fluorescence from the filter itself was measured and subtracted.

Photographs of the samples were obtained using a video graphics array camera positioned 30 cm over the substrates. All photographs were obtained under standard laboratory lighting. Thermogravimetric analysis was performed using a Discovery TGA (TA Instrument). The powder samples were prepared and ˜10 mg added to pre-weighed A1 crucibles (Tzero pan, TA instruments) inside a nitrogen-filled glovebox. The samples (inside the A1 crucibles) were loaded into the instrument in air, before closing the instrument and flowing a nitrogen purging gas flow of 25 mL·min⁻¹. Each temperature sweep involved maintaining 25° C. for 15 min before increasing to 500° C. (MBI) or 600° C. (MAPbI₃) at a ramp rate of 5° C.·min⁻¹, followed by maintaining at the final temperature for 30 min.

X-ray photoelectron spectroscopy (XPS) was conducted using a Thermo Scientific K-Alpha XPS with a monochromatic A1 X-ray source (excitation energy 1486.6 eV). Data were collected under a base pressure of 8×10⁻⁸ mbar at a photoelectron take-off angle of 90°. Energy calibration was performed using the position of the primary C is peak at 284.80 eV. Relative atomic ratios were calculated using the ratio of integrated spectral areas for each element from high resolution scans and the relative sensitivity factors inherent to the instrument.

### Density Functional Theory Calculations

All DFT calculations were performed using a computational approach similar the one employed in U.S. Provisional Application No. 62/141,662 filed on Apr. 1, 2015, which is incorporated by reference in its entirety, with the exchange-correlation functional using the generalized gradient approximation (GGA) in the functional form within the projector-augmented wave (PAW) formalism, as implemented in the VASP computer code. See, J. P. Perdew, K. Burke, M. Ernzerhof, Phys. Rev. Lett. 1996, 77, 3865-3868, P. E. Blöchl, Phys. Rev. B 1994, 50, 17953-17979, and G. Kresse, Phys. Rev. B 1996, 54, 11169-11186, each of which is incorporated by reference in its entirety. Full atomic, volume and cell shape relaxations were performed at the GGA-PBE level using the numerical setup, including k-point sampling and various cutoffs. See, V. Stevanović, S. Lany, X. Zhang, A. Zunger, Phys. Rev. B 2012, 85, 115104, which is incorporated by reference in its entirety. After structural relaxations, the final electronic structure was calculated with spin-orbit (SO) interactions included.

### Investigation of Bismuth Triiodide (BiI₃) for Photovoltaic Applications

Guided by the method presented herein, bismuth triiodide (BiI₃) was investigated as a candidate thin-film photovoltaic (PV) absorber. BiI₃ was chosen for its optical properties and the potential for “defect-tolerant” charge transport properties, which was tested experimentally by measuring optical absorption and recombination lifetimes. Phase-pure BiI₃ thin films was synthesized by physical vapor transport and solution processing, and single-crystals by an electrodynamic gradient vertical Bridgman method. The bandgap of these materials is approximately 1.8 eV, and they demonstrate room-temperature band-edge photoluminescence. Mmonoexponential recombination lifetimes were measured in the range of 180-240 ps for thin films, and longer, multiexponential dynamics for single crystals, with time constants up to 1.3-1.5 ns.

For many electronic devices, there is a need to accelerate the development of new materials with improved properties, unique functionality, and lower cost. In the field of photovoltaics (PV), there is a special need for accelerated materials development given the time pressure of climate change compared to the historically slow progress of novel materials improvement. See, Unold, T.; Schock, H. W. Nonconventional (Non-Silicon-Based) Photovoltaic Materials. Annu. Rev. Mater. Res. 2011, 41, 297-321, and Steinmann, V.; Brandt, R. E.; Buonassisi, T. Photovoltaics: Non-Cubic Solar Cell Materials. Nat. Photonics 2015, 9, 355-357, each of which is incorporated by reference in its entirety. Many of these materials significantly underperform relative to their theoretical limits, and one of the most critical limitations is the minority carrier lifetime, given its effect on both the achievable photocurrent and operating voltage of a solar cell. See, U.S. Provisional Application No. 62/141,662, which is incorporated by reference in its entirety. Thus, it is critical to discover materials with the potential for higher minority-carrier lifetimes. Focusing on achieving high minority-carrier lifetime offers a new theoretical approach, as well as a more accurate experimental approach—by measuring lifetime, one may directly assess the potential PV performance without the convoluting performance losses that arise from sub-optimal contacts, parasitic absorption, and series/shunt resistance. To demonstrate this approach, the potential of bismuth triiodide (BiI₃) was investigated as a photovoltaic absorber, through both theory and experiment.

BiI₃ has a long history of study in X-ray detectors, given its high density and high atomic number of constituent elements, few competing phases in the Bi—I system, wide bandgap of 1.67 eV, large static dielectric constant (albeit anisotropic), and an electron mobility that has been measured as high as 260±50 cm²/(V·s) or 1000±200 cm²/(V·s) with Sb-doping. See, Lintereur, A. T.; Qiu, W.; Nino, J. C.; Baciak, J. Characterization of Bismuth Tri-Iodide Single Crystals for Wide Band-Gap Semiconductor Radiation Detectors. Nucl. Instrum. Methods Phys. Res. Sect. A 2011, 652, 166-169, Fornaro, L.; Saucedo, E.; Mussio, L.; Gancharov, A.; Cuna, A. Bismuth Tri-Iodide Polycrystalline Films for Digital X-Ray Radiography Applications. In 2002 IEEE Nuclear Science Symposium Conference Record; 2002; Vol. 1, pp 33-37, Garg, A.; Tomar, M.; Gupta, V. Synthesis and Characterisation of Thin Films of Bismuth Triiodide for Semiconductor Radiation Detectors. In Conference Papers in Science; Hindawi: Dehradun, India, 2014; Vol. 2014, p 370436, Sellin, P. J. Thick Film Compound Semiconductors for X-Ray Imaging Applications. Nucl. Instrum. Methods Phys. Res. Sect. A 2006, 563, 1-8 Podraza, N. J.; Qiu, W.; Hinojosa, B. B.; Xu, H.; Motyka, M. A.; Phillpot, S. R.; Baciak, J. E.; Trolier-McKinstry, S.; Nino, J. C. Band Gap and Structure of Single Crystal BiI₃: Resolving Discrepancies in Literature. J. Appl. Phys. 2013, 114, 033110, Du, M.-H.; Singh, D. J. Enhanced Born Charges in III-VII, IV-VII₁, and V-VII₃ Compounds. Phys. Rev. B 2010, 82, 045203, and Han, H.; Hong, M.; Gokhale, S. S.; Sinnott, S. B.; Jordan, K.; Baciak, J. E.; Nino, J. C. Defect Engineering of BiI₃ Single Crystals: Enhanced Electrical and Radiation Performance for Room Temperature Gamma-Ray Detection. J. Phys. Chem. C 2014, 118, 3244-3250, each of which is incorporated by reference in its entirety.

The hole mobility is expected to be much lower due to the difference in carrier effective masses. The hole and electron effective masses in the BiI₃ R3̅ phase were calculated to be 10.39 and 1.85, respectively. See, U.S. Provisional Application No. 62/141,662, which is incorporated by reference in its entirety. Electron mobility-lifetime products of 1.4×10⁻⁶ cm²/V and 9.5×10⁻⁶ cm²/V have been reported, corresponding to electron diffusion lengths of 1.9 μm or 4.9 μm, respectively. See, Fornaro, L.; Saucedo, E.; Mussio, L.; Gancharov, A.; Cuna, A. Bismuth Tri-Iodide Polycrystalline Films for Digital X-Ray Radiography Applications. In 2002 IEEE Nuclear Science Symposium Conference Record; 2002; Vol. 1, pp 33-37, and Dmitriyev, Y. N.; Bennett, P. R.; Cirignano, L. J.; Klugerman, M. B.; Shah, K. S. Bismuth Iodide Crystals as a Detector Material: Some Optical and Electrical Properties; 1999; Vol. 3768, pp 521-529, each of which is incorporated by reference in its entirety. These diffusion lengths are on the order of the thickness of typical thin-film solar cells, suggesting that the electronic properties of BiI₃ may enable PV performance. A high resistivity up to 10⁸-10⁹ Ω-cm suggests that the material may require extrinsic doping or a high photo-induced carrier concentration (high injection) to achieve reasonable conductivity and low series resistance.

BiI₃ was recently one of a set of materials predicted as a potentially interesting photovoltaic material by an “inverse design” search. See, U.S. Provisional Application No. 62/141,662, which is incorporated by reference in its entirety. The design criteria were established based on the recent success of methylammonium lead iodide (MAPbI₃) as a PV material, and in particular the exceptional transport properties of MAPbI₃ despite the presence of defects. Its “defect-tolerance” is thought to arise from the partially oxidized Pb²⁺ cation, which retains a lone pair of 6s² electrons. Compounds with similar partially oxidized p-block cations such as In⁺, Sn²⁺, Sb³⁺, Tl⁺, Pb²⁺, and Bi³⁺ all retain a lone pair of electrons around the cation, which produces a large ionic radius and gives the valence band maximum s-orbital character. See, U.S. Provisional Application No. 62/141,662, which is incorporated by reference in its entirety. This electronic configuration leads to a more disperse valence band, shallow intrinsic point defects, a high Born-effective charge and a high dielectric constant, all of which are beneficial for defect-tolerance. See, U.S. Provisional Application No. 62/141,662, Du, M.-H. Density Functional Calculations of Native Defects in CH₃NH₃PbI₃: Effects of Spin-Orbit Coupling and Self-Interaction Error. J. Phys. Chem. Lett. 2015, 6, 1461-1466, Shi, H.; Du, M.-H. Shallow Halogen Vacancies in Halide Optoelectronic Materials. Phys. Rev. B 2014, 90, 174103, and Yin, W.-J.; Shi, T.; Yan, Y. Unique Properties of Halide Perovskites as Possible Origins of the Superior Solar Cell Performance. Adv. Mater. 2014, 26, 4653-4658, each of which is incorporated by reference in its entirety. BiI₃ exhibits a partially oxidized 6p cation, Bi³⁺, and therefore may share some of these beneficial electronic properties. In the present work, this hypothesis was tested by exploring its optoelectronic properties to try to understand how more “perovskite-like” semiconductors may be discovered.

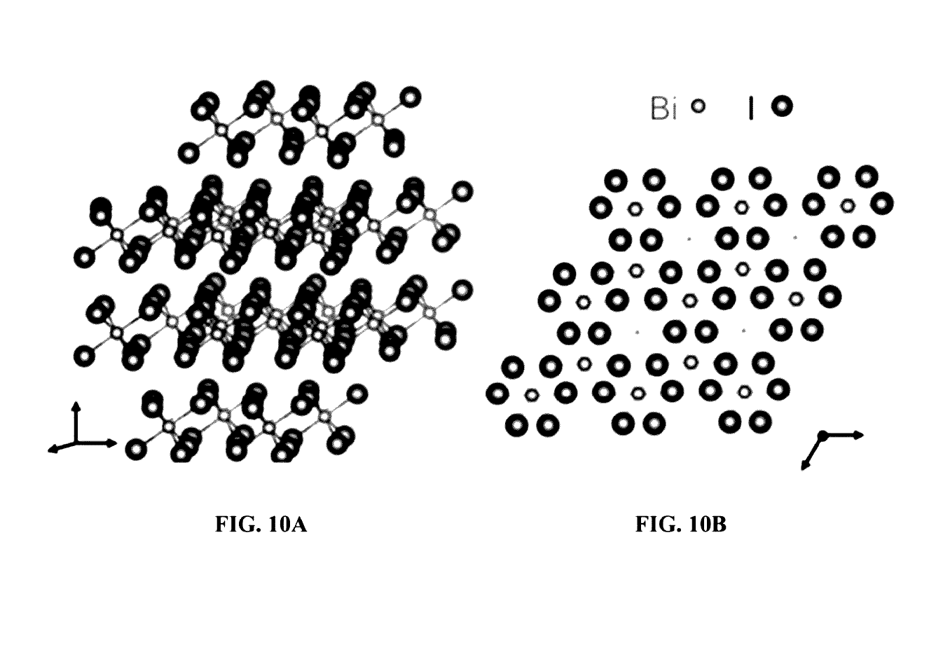

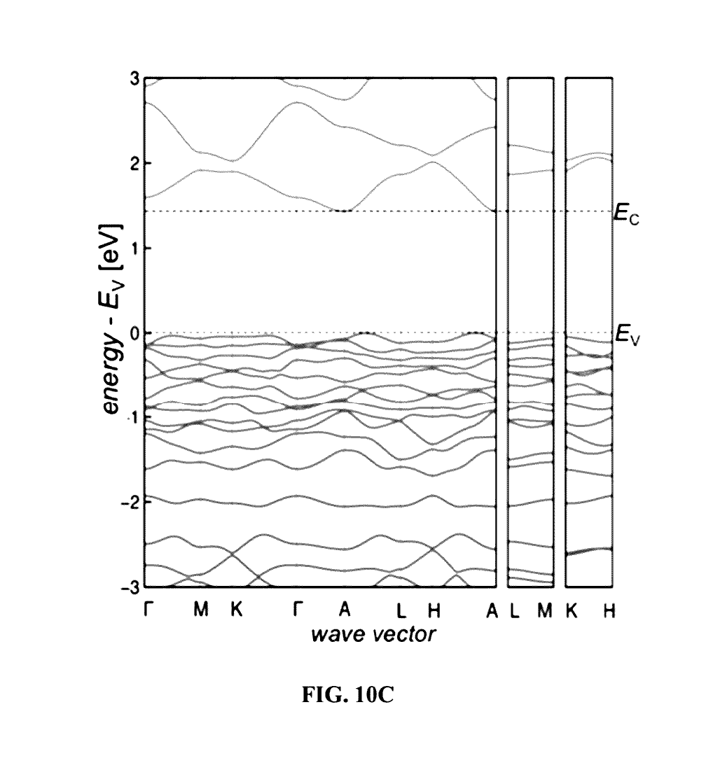

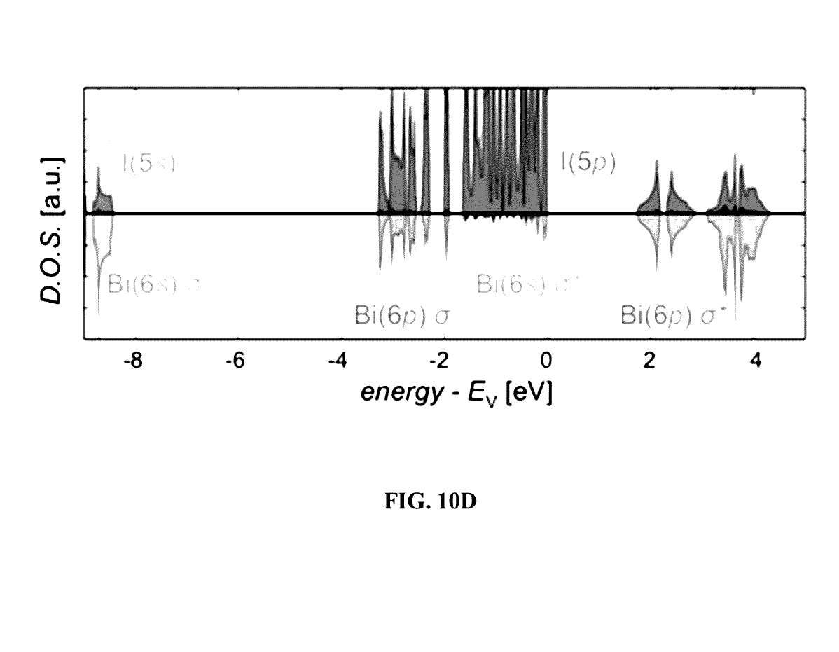

The crystal structure of BiI₃ is a layered, 2D structure built from BiI₆ octahedra and related to the CdI₂ crystal structure with ⅔ of cation sites occupied. As a result, the central Bi atoms are symmetrically coordinated by six iodine atoms, and the lone pair of electrons on the Bi³⁺ cation are not stereochemically active. The crystal structure (space group R3̅) is shown in FIG. 10A, demonstrating the stacked layer planes. In FIG. 10B, a single layer plane is shown, highlighting the vacant cation sites.

The electronic structure of BiI₃ in this phase is calculated from first principles using density functional theory (DFT). Incorporating spin-orbit coupling, the indirect bandgap of BiI₃ (R3̅) is computed to be 1.73 eV (2.51 eV without spin-orbit interactions), which agrees well with earlier DFT results. See, Podraza, N. J.; Qiu, W.; Hinojosa, B. B.; Xu, H.; Motyka, M. A.; Phillpot, S. R.; Baciak, J. E.; Trolier-McKinstry, S.; Nino, J. C. Band Gap and Structure of Single Crystal BiI₃: Resolving Discrepancies in Literature. J. Appl. Phys. 2013, 114, 033110, which is incorporated by reference in its entirety. The fractional density of states was determined in the valence and conduction bands, separated by atomic and orbital contributions. In FIG. 10D, these contributions are plotted together, with the anion contributions and cation contributions on the positive and negative y-axes, respectively. Similar to MAPbI₃, the partially oxidized Bi³⁺ cation contributes antibonding 6s character to the top of the valence band. In addition, spin-orbit coupling along with the large atomic weight of the Bi³⁺ cation leads to a more disperse conduction band and lower electron effective mass, as compared to DFT calculations minus spin-orbit coupling, or as compared to the isostructural, lighter SbI₃ compound. The computed dispersion relation for this material is plotted in FIG. 10C, showing the indirect bandgap with a direct optical transition slightly higher in energy.

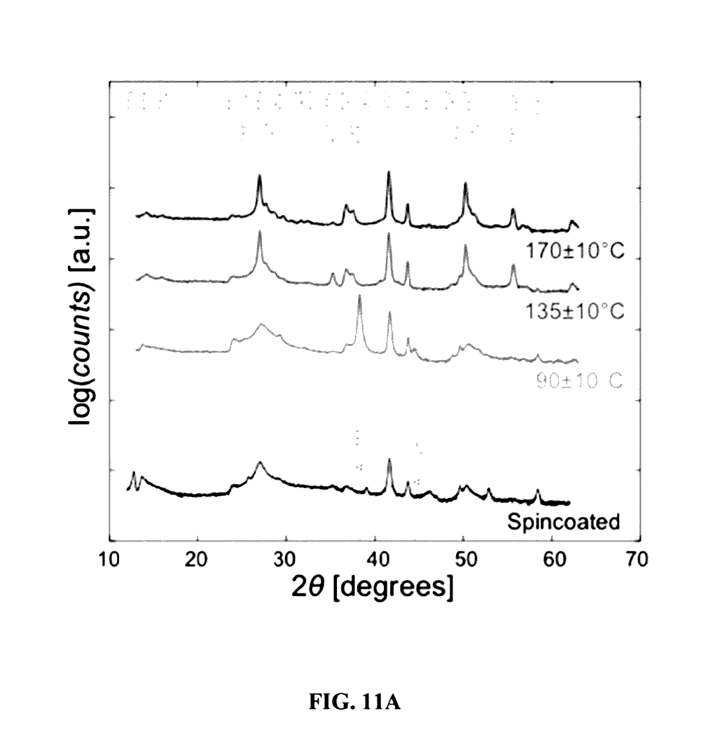

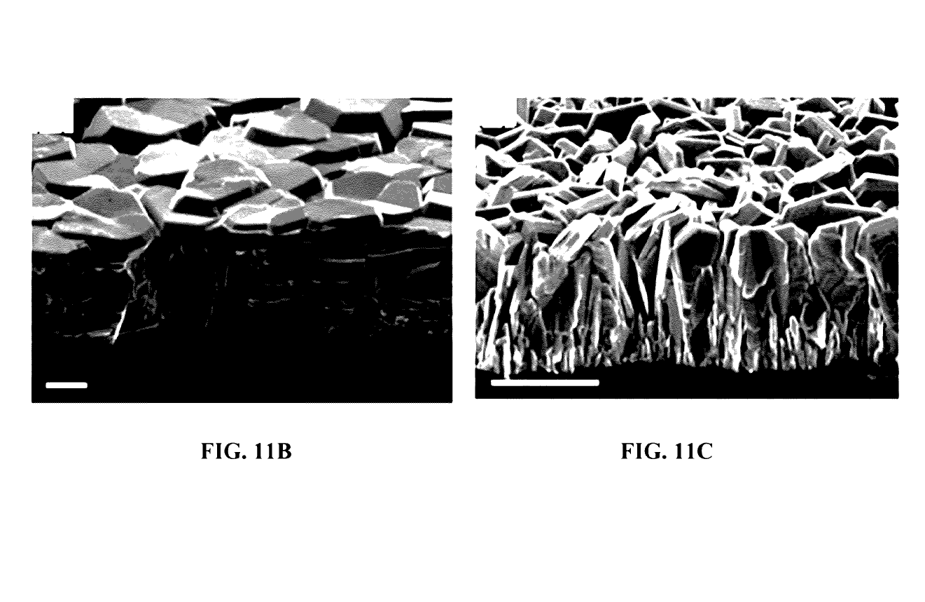

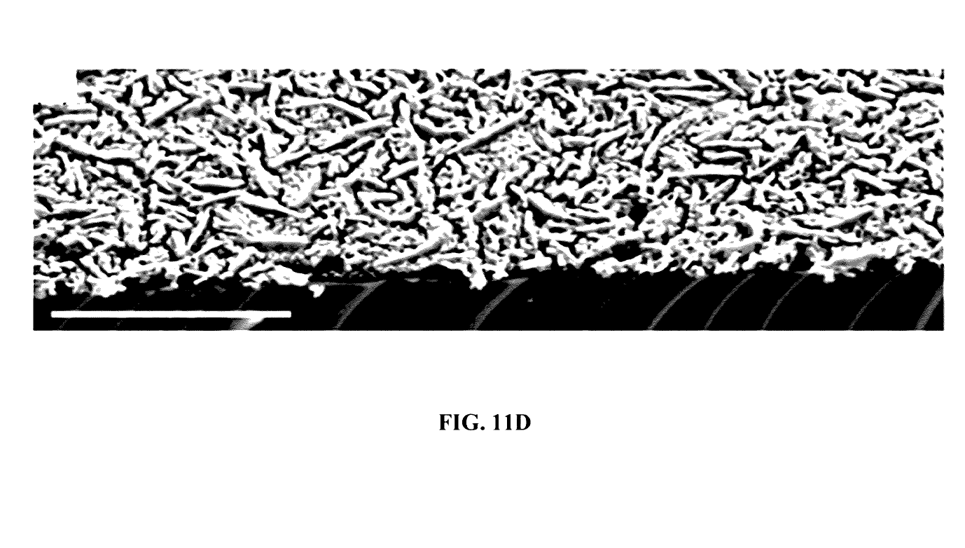

To evaluate the potential of BiI₃ as a photovoltaic absorber, it is critical to grow a phase-pure material. Thin films were grown using an open-flow physical vapor transport (PVT) or sublimation furnace (see, Fornaro, L.; Saucedo, E.; Mussio, L.; Gancharov, A.; Cuna, A. Bismuth Tri-Iodide Polycrystalline Films for Digital X-Ray Radiography Applications. In 2002 IEEE Nuclear Science Symposium Conference Record; 2002; Vol. 1, pp 33-37, Garg, A.; Tomar, M.; Gupta, V. Synthesis and Characterisation of Thin Films of Bismuth Triiodide for Semiconductor Radiation Detectors. In Conference Papers in Science; Hindawi: Dehradun, India, 2014; Vol. 2014, p 370436, and Curia, A.; Aguiar, I.; Gancharov, A.; Perez, M.; Fornaro, L. Correlation between Growth Orientation and Growth Temperature for Bismuth Tri-Iodide Films. Cryst. Res. Technol. 2004, 39, 899-905, each of which is incorporated by reference in its entirety) over a range of substrate temperatures, and by solution processing via spin-coating (see Experimental Methods). Single crystals were grown by a modified vertical Bridgman method using electrodynamic gradient techniques. See, Han, H.; Hong, M.; Gokhale, S. S.; Sinnott, S. B.; Jordan, K.; Baciak, J. E.; Nino, J. C. Defect Engineering of BiI₃ Single Crystals: Enhanced Electrical and Radiation Performance for Room Temperature Gamma-Ray Detection. J. Phys. Chem. C 2014, 118, 3244-3250, which is incorporated by reference in its entirety. Then the phase and morphology of the films were verified through X-ray diffraction (XRD) and micrographs. Substrate growth temperature has a strong effect on the orientation and morphology of PVT BiI₃. In FIGS. 11A-11D, the XRD spectra are plotted for PVT and solution processed films (grown on gold to avoid amorphous background and overlapping crystalline peaks), as well as micrographs shown for different regions. As the substrate temperature of PVT BiI₃ increases, the preferred orientation of the BiI₃ layer planes moves from perpendicular to parallel to the substrate, resulting in a different morphology (as noted previously in Curia, A.; Aguiar, I.; Gancharov, A.; Perez, M.; Fornaro, L. Correlation between Growth Orientation and Growth Temperature for Bismuth Tri-Iodide Films. Cryst. Res. Technol. 2004, 39, 899-905, which is incorporated by reference in its entirety). At the lowest PVT substrate temperature, the film is very thin (due to the single zone furnace design, in which growth occurs via a thermal gradient) and shows minimal long-range order, hence its XRD pattern is dominated by the peaks of the Au substrate. The morphology of films on Au or glass substrates are very similar.

The optical properties of BiI₃ are promising for photovoltaic applications. Previous reports estimate an indirect bandgap of 1.67 eV and a direct bandgap of 1.96 eV. See, Podraza, N. J.; Qiu, W.; Hinojosa, B. B.; Xu, H.; Motyka, M. A.; Phillpot, S. R.; Baciak, J. E.; Trolier-McKinstry, S.; Nino, J. C. Band Gap and Structure of Single Crystal BiI₃: Resolving Discrepancies in Literature. J. Appl. Phys. 2013, 114, 033110, which is incorporated by reference in its entirety. To verify this, UV-visible spectrophotometry was performed on thin films deposited on quartz substrates. The absorption coefficient (α) was computed from transmittance T, reflectance R, and sample thickness d as:

$$α = \frac{- ln ( T \text{/} ( 1 - R ) )}{d} . \qquad ( 1 )$$

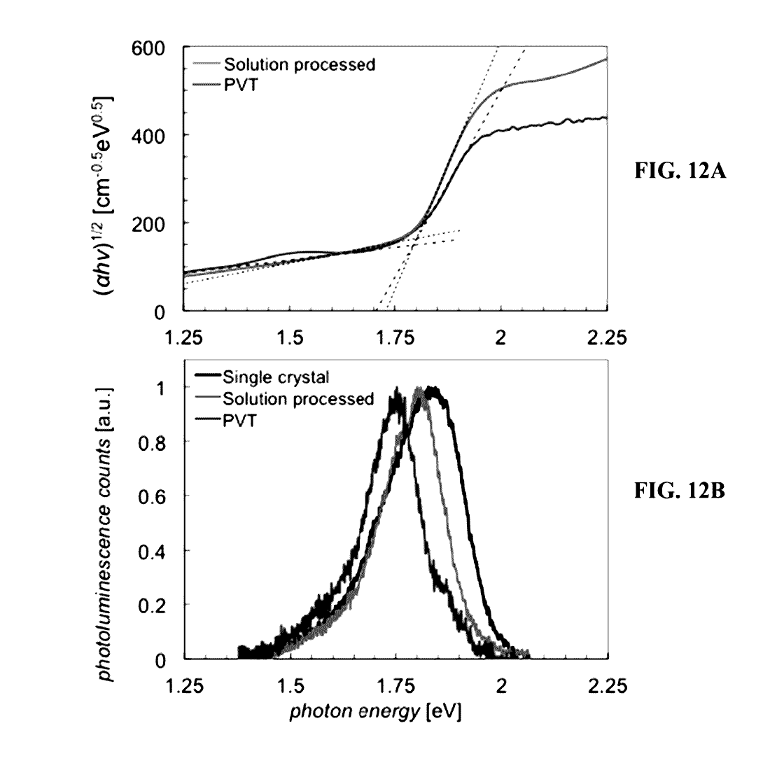

Assuming an indirect bandgap, in FIG. 12A the Tauc method was applied to fit a linear absorption edge in a plot of (ahv)^{1/2} vs. hv. See, Tauc, J.; Grigorovici, R.; Vancu, A. Optical Properties and Electronic Structure of Amorphous Germanium. Phys. Status Solidi 1966, 15, 627, which is incorporated by reference in its entirety. Finding the intersection of this edge with sub-bandgap absorption (see Chen, Z.; Jaramillo, T. F.; Deutsch, T. G.; Kleiman-Shwarsctein, A.; Forman, A. J.; Gaillard, N.; Garland, R.; Takanabe, K.; Heske, C.; Sunkara, M.; et al. Accelerating Materials Development for Photoelectrochemical Hydrogen Production: Standards for Methods, Definitions, and Reporting Protocols. J. Mater. Res. 2010, 25, 3-16, which is incorporated by reference in its entirety), the bandgap is determined to be 1.79±0.05 eV and 1.80±0.05 eV for the PVT and solution-processed films respectively. Given the high absorption of BiI₃ above 2 eV, the absorption saturates and results in an underestimate of the absorption coefficient. However prior literature suggests that it exceeds 10⁵ cm⁻¹ above 2 eV.⁸ Use of a thinner film or spectroscopic ellipsometry would allow for a more accurate determination of α. In addition, the high absorption below the bandgap suggests that the present material can have a secondary phase (e.g., Bi metal) resulting in broadband sub-bandgap absorption. The non-monotonic rise in sub-bandgap absorption is a result of optical interference fringes.

Next, room-temperature spectrally-resolved photoluminescence (PL) was performed, and find that BiI₃ thin films and single crystals luminesce at room temperature. Using a pump wavelength of 532 nm, PL peaks was centered between 1.76-1.83 eV. This data is plotted in FIG. 12. PVT films measured here were deposited at a substrate temperature of 110±10° C., though the bandgap is found to be independent of growth temperature. The samples show a clear PL peak above the substrate emission and above background, suggesting that time-resolved PL can be used to quantify the recombination kinetics.

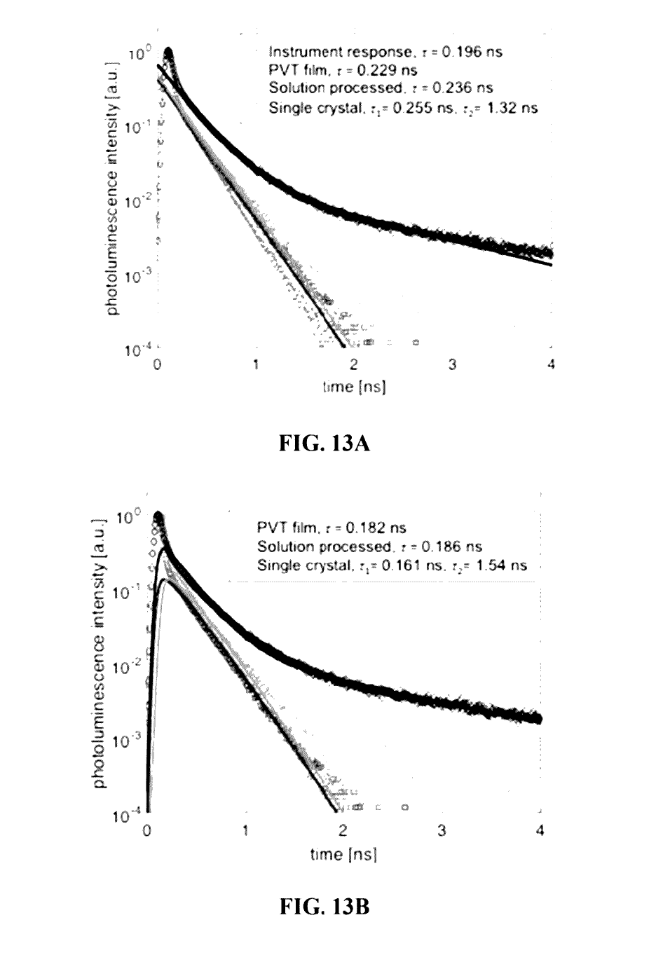

Finally, the carrier recombination lifetime is estimated by measuring time-resolved photoluminescence using a time-correlated single photon counting (TCSPC) setup. A 532 nm wavelength laser was used to excite the sample, and a single photon avalanche diode (SPAD) to detect photoemission, plotted in FIG. 13. Because the instrument response function (IRF) of the TCSPC technique is on the same timescale as the time-resolved photoluminescence decay, the former must be decoupled from the latter to extract a carrier lifetime. See, O'Connor, D. V.; Ware, W. R.; Andre, J. C. Deconvolution of Fluorescence Decay Curves. A Critical Comparison of Techniques. J. Phys. Chem. 1979, 83, 1333-1343, and O'Connor, D. V.; Phillips, D. Data Analysis. In Time-Correlated Single Photon Counting; O'Connor, D. V, Phillips, D., Eds.; Academic Press, 1984; pp 158-210, each of which is incorporated by reference in its entirety. First, the IRF is convolved with a monoexponential decay function. Then, this function was fitted by a least-squares method to the TCSPC data. The effective lifetimes was estimated to be within the range of 180-230 ps and 190-240 ps for the PVT and solution-processed films, respectively. The single crystal sample shows biexponential decay with time scales of 160-260 ps and 1.3-1.5 ns. Given the fact that BiI₃ is reported to be intrinsic (majority carrier type unknown), this recombination lifetime may reflect the sum of electron and hole lifetimes. The monoexponential decay times of the thin films may be strongly limited by surface recombination, so these bare considered to be lower bounds on the bulk Shockley-Read-Hall lifetime.

BiI₃ appears to offer several compelling properties for PV applications. First, its bandgap of approximately 1.8 eV is well positioned for use as a top cell material in a multi junction solar cell, as this represents a near-ideal bandgap to be paired with silicon as the bottom cell. See, Geisz, J. F.; Friedman, D. J. III-N-V Semiconductors for Solar Photovoltaic Applications. Semicond. Sci. Technol. 2002, 17, 769, which is incorporated by reference in its entirety. Furthermore, BiI₃ demonstrates an absorption coefficient >10⁵ cm⁻¹ in the visible region of the solar spectrum, suggesting the possibility to obtain high photocurrents with a film <1 μm thick, even without light-trapping designs.

However, not all of its properties are compelling for PV applications. Some of these may be resolved through further materials development, and some may be intrinsic to BiI₃. First, at present, the carrier lifetime of thin films is too short to produce high-performance PV devices. Other thin-film devices based on CdTe and Cu₂ZnSnSe₄, with comparable PL decay lifetimes (between 100-200 ps) have produced efficiencies of 8-9%, and <1% respectively. See Moutinho, H. R.; Dhere, R. G.; Al-Jassim, M. M.; Ballif, C.; Levi, D. H.; Swartzlander, A. B.; Young, M. R.; Kazmerski, L. L. Study of CdTe/CdS Solar Cells Using CSS CdTe Deposited at Low Temperature. In Photovoltaic Specialist Conference (PVSC), 2000 IEEE 28th; 2000; pp 646-649, and Buffiere, M.; Brammertz, G.; Mel, A.-A. E.; Lenaers, N.; Ren, Y.; Zaghi, A. E.; Mols, Y.; Koeble, C.; Vleugels, J.; Meuris, M.; et al. Recombination Stability in Polycrystalline Cu2ZnSnSe4 Thin Films; IEEE, 2013; pp 1941-1944, which is incorporated by reference in its entirety. Critically, highly resistive materials such as methylammonium lead halide and BiI₃ require high lifetimes to achieve reasonable fill factors, because the series resistance is governed by the photoexcited carrier concentration, which is proportional to carrier lifetime. The prospects to improve lifetime in BiI₃ are suggested by the lifetime difference between single crystal and polycrystalline thin film materials (FIG. 13). Likely, improved controls of phase purity, elemental purity (i.e., controlling contamination), and intragranular structural defect (i.e., dislocation, stacking fault) density will prove essential to increasing lifetime.

Concerning phase purity, several authors have argued that BiI₃ begins to dissociate as the melting point is approached. This dissociation in the window of 250-300° C. may result in an off-stoichiometry of several percent. This may result in small quantities of Bi metal, which can be consistent with the strong sub-bandgap absorption visible in FIG. 12. Note that Bi metal XRD peaks overlap with BiI₃, and would thus be indistinguishable. Regarding extrinsic contaminants and intragranular structural defects, Du and Singh have suggested that the anisotropic crystal structure in BiI₃ may be partially responsible for its lower μτ product, as it may be more likely to form structural defects, and should exhibit anisotropy in dielectric screening. See, Du, M.-H.; Singh, D. J. Enhanced Born Charges in III-VII, IV-VII₁, and V-VII₃ Compounds. Phys. Rev. B 2010, 82, 045203, which is incorporated by reference in its entirety. However, they do not rule out the possibility that impurities may limit the transport properties. In other halide materials such as TlBr, extensive purification efforts through zone refining have resulted in over two orders of magnitude improvement in mobility lifetime products, which mirrors the pioneering success in purifying crystalline silicon. See, Hitomi, K.; Shoji, T.; Ishii, K. Advances in TlBr Detector Development. J. Cryst. Growth 2013, 379, 93-98, and Davis, Jr., J. R.; Rohatgi, A.; Hopkins, R. H.; Blais, P. D.; Rai-Choudhury, P.; McCormick, J. R.; Mollenkopf, H. C. Impurities in Silicon Solar Cells. IEEE Trans. Electron Devices 1980, 27, 677-687, each of which is incorporated by reference in its entreity.

The measurement of lower lifetimes than those achieved in MAPbX₃ may lead to further insights on its defect tolerance. Firstly, despite Bi³⁺ being isoelectronic with Pb²⁺, its larger atomic mass leads to deeper 6s orbitals and less of a contribution to the valence band. That, in addition to its anisotropic crystal structure, leads to a much higher hole effective mass in BiI₃. This is distinct from some other post transition metal halides such as MAPbI₃ and TlBr,⁹ which are symmetric crystal structures and demonstrate isotropic electronic properties as well as low hole effective masses. Recent DFT results have also suggested that, while the V₁ defect is shallow (as in MAPbI₃), V_{Bi} lies deeper in the gap (see Han, H.; Hong, M.; Gokhale, S. S.; Sinnott, S. B.; Jordan, K.; Baciak, J. E.; Nino, J. C. Defect Engineering of BiI₃ Single Crystals: Enhanced Electrical and Radiation Performance for Room Temperature Gamma-Ray Detection. J. Phys. Chem. C 2014, 118, 3244-3250, which is incorporated by reference in its entirety), perhaps related to the less disperse valence band maximum. These results re-emphasize the strategies for achieving defect-tolerant transport properties such as those in MAPbI₃.

Lastly, BiI₃ is a very soft material with a Vickers Hardness of 12-15. See, Baciak, J. E.; Nino, J. C.; Qiu, W.; Lintereur, A. Single-Crystal Bismuth Iodide Gamma-Ray Spectrometers; DTRA-TR-12-70; DTIC Document, 2013, which is incorporated by reference in its entirety. The ease with which one may scratch the material is a liability for shunting and catastrophic failure in thin-film PV cells. In addition, one must evaluate the effect of this softness and the crystal structure's anisotropy when the material is heated and cooled in traction with its substrate, in relation to dislocation generation (plastic deformation), cracks, and pinholes, all of which can reduce device performance.

In summary, BiI₃ was investigated as a photovoltaic material based on the inverse-design approach based on its electronic structure, and formed thin films through physical vapor transport and solution processing, as well as single crystal specimens. The optical absorption and bandgap are suitable for PV applications, and the observation of room-temperature photoluminescence is a promising first step towards optoelectronic devices. Transient photoluminescence measurements indicate that the carrier lifetime is 180-240 ps for both thin films, and longer for single crystals (parametrized as a biexponential decay with τ₁=160-260 ps and τ₂=1.3-1.5 ns). These results suggest that the electrical properties of these thin films should be improved, potentially by eliminating extrinsic impurities, competing phases, and/or intragranular structural defects. In addition, the mechanical softness presents challenges to device fabrication, and the and high intrinsic electrical resistivity implies that high injection levels are needed for efficient devices. This approach of identifying a compound through search criteria and focusing on measurement of the carrier lifetime can be applied to a broader range of compounds promising for PV applications.

Experimental Section

Theory

DFT calculations are performed with the VASP computer code. See, Kresse, G.; Furthmüller, J. Efficient Iterative Schemes for Ab Initio Total-Energy Calculations Using a Plane-Wave Basis Set. Phys. Rev. B 1996, 54, 11169-11186, which is incorporated by reference in its entirety. The Perdew-Burke-Ernzerhof (PBE) functional form of the generalized gradient approximation and the projector-augmented wave formalism are used. See, U.S. Provisional Application No. 62/141,662, Perdew, J. P.; Burke, K.; Ernzerhof, M. Generalized Gradient Approximation Made Simple. Phys. Rev. Lett. 1996, 77, 3865-3868, and Blöchl, P. E. Projector Augmented-Wave Method. Phys. Rev. B 1994, 50, 17953-17979, each of which is incorporated by reference in its entirety.

Synthesis

For PVT, BiI₃ powder (Alfa Aesar, 99.999% metals basis) is placed in a quartz crucible at the center of the hot zone of a quartz tube furnace. The hot zone is a 12″ section of a 2″-diameter quartz tube. The furnace is evacuated to a base pressure of <10 mTorr. During deposition, inert nitrogen gas flows through the furnace at a flow rate of 10 mL/min, resulting in an operating pressure of 1.3-1.7 Torr. Substrates are placed downstream in the tube furnace at the end of the single hot zone; for the source temperature of 280° C. used here, substrate temperatures range from 60-200° C. Films are deposited on bare quartz, soda lime glass, or on glass coated with a 200 nm of Au, with similar morphologies achieved for each. The leading edge of the substrates experiences both the highest temperature and fastest growth rate, thus the films are thicker for hotter substrate temperatures, while the coolest substrate region produces very thin films. For solution-processed films, 100 mg of BiI₃ is dissolved in 0.25 mL of anhydrous dimethylformamide (DMF). The solution is filtered through 0.45 μm PTFE filters, and 10 μL of the saturated solution are spun onto glass or quartz substrates in a N₂ glove box at room temperature. After spinning at 3500 RPM for 35 seconds, the films are dried at room temperature for over an hour.

The BiI₃ single crystals are grown using a modified vertical Bridgman method as has been described in detail elsewhere.⁸ In summary, a custom made Pyrex glass ampoule (Southern Scientific, Inc.) with an inner diameter of 0.75 in, tip length of ˜5 cm and tip angle of ˜70° is used for crystal growth. Prior to growth, the ampoule is cleaned using Decon Contrad® ˜70 cleaning solution, then rinsed ten times with DI water and finally dried at 120° C. in an oven. A neck area is created in the middle of the ampoule using a propane torch to facilitate later sealing. BiI₃ powder (Strem Chemicals, 99.999% PURATEM™) is placed in the ampoule. The ampoule is vacuumed to 4×10⁻² mbar using a roughing pump and further evacuated to 1×10⁻⁴ mbar with a molecular turbo-pump. This ampoule is then sealed manually under vacuum by heating with a propane torch until the glass softens with the neck reducing to a fine tip and separating from the rest of the ampoule. This ampoule loaded with BiI₃ powder is then mounted vertically on a steel frame in a programmable 12 or 24-zone vertical heating furnace (EDG-13 or -11, Mellen Company). All zones of the furnace are heated to a temperature of 460° C. to melt the BiI₃ and then progressively cooled from the bottom to the top by changing the temperatures of the different zones in the furnace using a pre-programmed temperature profile. The programmed profile is equivalent to a conventional Bridgman growth with cooling gradient at the growth interface is 10° C./cm and the displacement rate of 0.05 mm/h. After the growth a polycrystal with a few large grains is obtained which is easily cut using a wire saw into smaller single crystals along the [001] direction. The top surface layers are easily removed using adhesive tape to expose fresh glossy surfaces.

Characterization

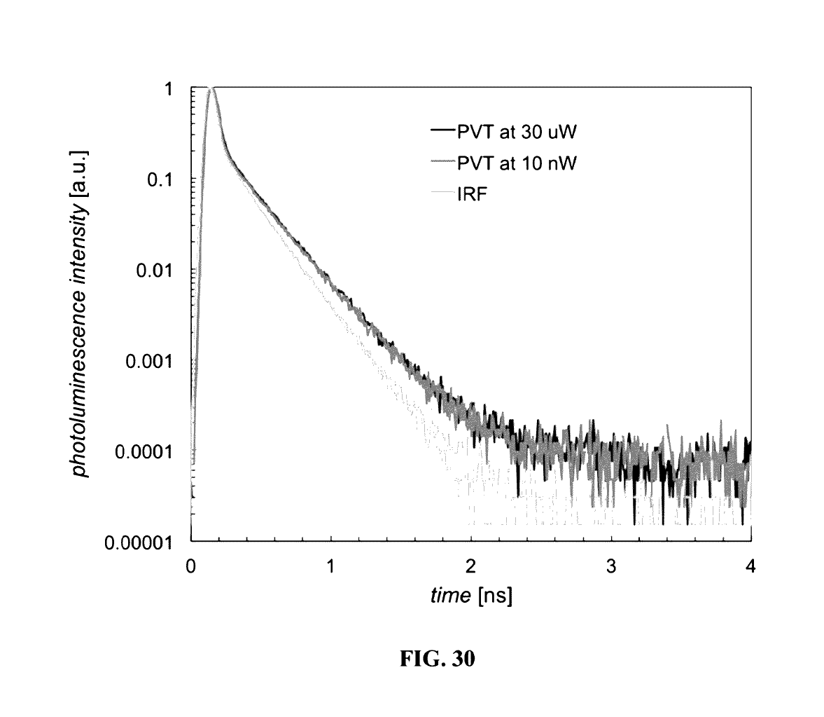

XRD is performed with a Bruker GADDS and Rigaku SmartLab for grazing incidence XRD at an incident angle of 0.5°, and micrographs are performed with a Zeiss ORION He-ion microscope and a Zeiss SUPRA 55VP Scanning Electron Microscope (SEM). Spectral PL is performed with a Horiba LabRAIVI HR Evolution Raman spectrometer using a 532 nm wavelength excitation laser with an intensity of 20 μW. For TCSPC, a 532 nm wavelength laser (PicoQuant LDH-P-FA-530B) was used to generate a train of excitation pulses at 2.5 MHz, each with a FWHM of ˜80 ps, but a longer exponential tail (˜200 ps). The incident power was 25-30 μW, over a 200 μm spot size, which corresponds to a photon fluence of 2×10¹¹ photons/cm²/pulse. Intensity-dependent data may be found in FIGS. 29-30. The emission from the film was collected using reflective optics and directed to a single-photon-sensitive avalanche photodiode with ˜30 ps time resolution. (Micro Photon Devices $PD-100-C0C) Dielectric filters (Chroma Technology Corp., ThorLabs) were used to remove scattered excitation light. Photon arrivals were correlated with the excitation pulse using a PicoQuant PicoHarp 300. To avoid inaccuracies due to pile-up, the excitation intensity was varied as necessary to ensure that the probability of detecting a photon during a single excitation cycle was below five percent.

### Fluence-Dependence of TCSPC Data

All photoluminescence data was taken over a range of incident powers to determine the effect of injection level on the transient behavior. The time-averaged laser power was adjusted from 10 nW to 30 μW. At a laser pulse rate of 2.5 MHz and pulse width of ˜80 ps, this corresponds to a much larger instantaneous power input. For a photon energy of 2.33 eV and spot size of 200 microns in diameter, the pulse photon fluence is estimated ranged from 8×10⁷-2.4×10¹¹ photons/cm²/pulse over the range of incident power tested.

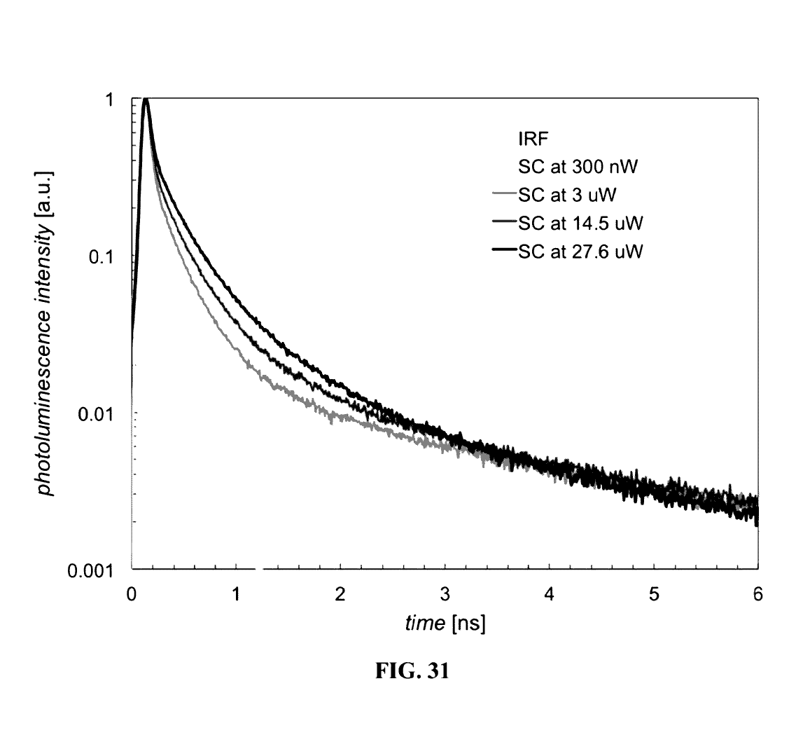

Both thin film samples (PVT and solution processed) showed no dependence on the input laser power, suggesting that the dynamics observed extend to 1-sun injection levels under normal operation. The single crystal samples, however, did demonstrate an intensity-dependence to their photoluminescence dynamics. For a 300 nW incident power, there was a ˜25% shorter decay time (τ₁) than for 28 μW incident power, but a similar “slow” decay time constant (τ₂) at longer time scales for all incident powers. These traces are plotted here in FIGS. 30-31. The decay dynamics appear to be unaffected by the incident laser power (FIG. 30). FIG. 31 shows that the decay dynamics at longer time periods are independent of the incident laser power, but the initial fast decay shows a dependence on incident power.

Other embodiments are within the scope of the following claims.

What is claimed is:

1. An optoelectronic device comprising:
an absorber layer comprising a composition including a partially oxidized cation containing a lone 6s² or 5s² pair of electrons; and a halide anion or chalcogenide anion or combination thereof.

2. The device of claim 1, wherein the partially oxidized cation is at least one of In⁺, Sn²⁺, Sb³⁺, Pb²⁺, Tl⁺ or Bi³⁺.

3. The device of claim 1, wherein the halide anion or chalcogenide anion is at least one of I⁻, Br⁻, Se²⁻, or S²⁻.

4. The device of claim 1, wherein the composition is a ternary bismuth halide.

5. The device of claim 1, wherein the composition further includes an additional cation comprising at least one of ammonium, methylammonium, formamidimium, or phosphonium.

6. The device of claim 1, wherein the composition is a bismuth halide.

7. The device of claim 6, wherein the bismuth halide is bismuth triiodide.

8. The device of claim 1, further comprising an alloy including an alkali metal halide.

9. The device of claim 1, wherein the composition is a binary halide.

10. The device of claim 1, wherein the composition is a ternary alkali bismuth chalcogenide, a ternary alkali antimony chalcogenide, a ternary alkali antimony halide, a ternary indium halide, a ternary tin halide or a ternary alkali bismuth halide.

11. The device of claim 1, wherein the composition includes methylammonium bismuth iodide, BiI₃, SbI₃, SnI₂, InI, LiBiS₂, NaBiS₂, KBiS₂, CsBiS₂, NaBiSe₂, In₃SnI₅, InAlI₄, CdInBr₃, or CaInBr₃, Cs₃Bi₂I₉, Rb₃Bi₂I₉, or K₃Bi₂I₉, or a Cs₃Sb₂I₉.

12. The device of claim 1, wherein the composition is a hybrid inorganic-organic bismuth halide, a hybrid inorganic-organic antimony halide, or a hybrid inorganic-organic indium halide.

13. The device of claim 12, wherein the composition further includes ammonium, methylammonium, formamidimium, or phosphonium.

14. The device of claim 1, wherein the composition includes an octahedral halide.

15. The device of claim 1, wherein the composition further includes an alloy including an alkali metal halide.

16. The device of claim 15, wherein the alkali metal halide is NaI, KI, or CsI.

17. The device of claim 1, further comprising an electron transport layer.

18. The device of claim 17, wherein the electron transport layer comprises phenyl-C61-butyric acid methyl ester (PCBM).

19. The device of claim 1, further comprising a substrate layer.

20. The device of claim 19, wherein the substrate layer comprises at least one of glass, quartz, gold, or molybdenum oxide.

21. A composition for an absorber in a device comprising:
a partially oxidized cation containing a lone 6s² or 5s² pair of electrons; and a halide anion or chalcogenide anion or combination thereof.

22. The composition of claim 21, wherein the partially oxidized cation is at least one of In⁺, Sn²⁺, Sb³⁺, Pb²⁺, Tl⁺ or Bi³⁺.

23. The composition of claim 21, wherein the halide or chalcogenide anion is at least one of I⁻, Br⁻, Se²⁻ or S²⁻.

24. The composition of claim 21, wherein the composition is a ternary bismuth halide, a bismuth halide, a binary halide, a binary chalcogenide, a ternary alkali bismuth chalcogenide, a ternary alkali antimony chalcogenides, a ternary indium halide, a ternary tin halide, a ternary alkali bismuth halide, or a ternary alkali antimony halide.

25. The composition of claim 21, wherein the composition further includes an additional comprising at least one of ammonium, methylammonium, formamidimium, or phosphonium.

26. The composition of claim 21, wherein the composition is methylammonium bismuth iodide, bismuth triiodide, BiI₃, SbI₃, SnI₂, InI, Bi₂S₃, Sb₂S₃, Sb₂Se₃, LiBiS₂, NaBiS₂, KBiS₂, CsBiS₂, or NaBiSe₂, In₃SnI₅, InAlI₄, CdInBr₃, or CaInBr₃. Cs₃Bi₂I₉, Rb₃Bi₂I₉, K₃Bi₂I₉, or Cs₃Sb₂I₉.

27. The composition of claim 21, further comprising an alloy including an alkali metal halide.

28. The composition of claim 21, wherein the composition is a hybrid inorganic-organic bismuth halide, a hybrid inorganic-organic antimony halide, or a hybrid inorganic-organic indium halide.

29. The composition of claim 21, wherein the composition further includes ammonium, methylammonium, formamidimium, or phosphonium.

30. The composition of claim 21, wherein the composition includes an octahedral halide.

31. The composition of claim 30, wherein the composition further includes an alloy including an alkali metal halide.

32. The composition of claim 31, wherein the alkali metal halide is NaI, KI, or CsI.

33. A method of identifying a material for an optoelectric device comprising:
selecting a partially oxidized cation containing a lone 6s² or 5s² pair of electrons; and
combining the cation with a halide salt to form an absorber material.
